(19) United States
(12) Patent Application Publication
(10) Pub. No.: US 2025/0242424 A1
(43) Pub. Date: Jul. 31, 2025

(54) SELECTIVELY VAPOR-PERMEABLE MEMBRANE HEAT SINKS COMPRISING A TUNGSTEN-CONTAINING CONTACT PLATE AND METHODS FOR MANUFACTURING AND USING THE SAME

(71) Applicant: University of Florida Research Foundation, Incorporated, Gainesville, FL (US)

(72) Inventor: Saeed Moghaddam, Gainesville, FL (US)

(21) Appl. No.: 19/041,234

(22) Filed: Jan. 30, 2025

Related U.S. Application Data
(60) Provisional application No. 63/627,182, filed on Jan. 31, 2024.

(51) Int. Cl. B23K 1/00; B23K 101/14; B23K 103/12; C22C 9/00; F28F 13/00; F28F 21/08; H05K 7/20

(52) U.S. Cl. CPC B23K 1/0012; F28F 21/085; B23K 2101/14; B23K 2103/12; C22C 9/00; F28F 2013/001; F28F 2275/04; H05K 7/20309

(57) ABSTRACT

Disclosed are dual-phase heat sinks using vapor-permeable membrane(s) to reach unprecedented heat transfer coefficient and waste heat temperature recovery levels. A vapor-permeable membrane is sealed between a liquid region and a vapor region to allow only vapor-phase heat exchange fluid to pass from liquid region to vapor region. Vapor-permeable membranes can function as a mass controller, permitting the entry of liquid phase heat exchange fluid into heat sink in equilibrium with vapor phase heat exchange fluid being communicated through the vapor-permeable membrane. Reduced pressure drop across heat sink enables operation under hydrostatic pressure. A heat sink can comprise a thin tungsten-containing base between a contact surface and a heat source (e.g., chip) that improves stress distribution through heat sink and chip package, reduces mechanical strain from thermal stress, and increases durability of the assembly.

### CROSS-REFERENCE TO RELATED APPLICATIONS

The present application claims the benefit of priority to U.S. Provisional Patent Application Ser. No. 63/627,182, filed Jan. 31, 2024 and entitled “Manufacturing and Direct Die Attachment of Membrane Heat Sinks,” the entire disclosure of which are hereby incorporated herein by reference in its entirety for all purposes.

The present disclosure is also related to the subject matter disclosed in U.S. Provisional Patent Application Ser. No. 63/619,996, filed Jan. 11, 2024 and entitled “Method of Implementing Membrane Heat Sinks in Computer Servers Rack,” the entire disclosure of which is hereby incorporated herein by reference in its entirety for all purposes. The present disclosure is further related to the subject matter disclosed in U.S. Non-Provisional patent application Ser. No. 16/598,176, filed Oct. 10, 2019 and entitled “Hierarchical Hydrophilic/Hydrophobic Micro/Nanostructures for Pushing the Limits of Critical Heat Flux,” which is a continuation of U.S. Non-Provisional patent application Ser. No. 15/185,766, filed Jun. 17, 2016 and entitled “Hierarchical Hydrophilic/Hydrophobic Micro/Nanostructures for Pushing the Limits of Critical Heat Flux,” which is a continuation-in-part of International Patent Application Serial No. PCT/US2014/070903, filed Dec. 17, 2014, which claims priority to U.S. Provisional Application Ser. No. 61/917,177, filed Dec. 17, 2013, the entire disclosures of each of which are hereby incorporated herein by reference in their entireties for all purposes.

### GOVERNMENT SUPPORT STATEMENT

This invention was made with government support under DE-AR-0001756, awarded by US DEPT OF ENERGY ADVANCED RESEARCH PROJECTS AGENCY. The government has certain rights in the invention.

### FIELD

The present disclosure relates, generally, to membrane heat sinks, and in particular dual-phase membrane heat sinks.

### BACKGROUND

As data centers and server facilities continue to evolve, the demand for efficient heat dissipation mechanisms becomes increasingly critical, to both enable higher compute capability and mitigate the rapidly rising electricity demand for cooling. High-performance computing (HPC) devices generate substantial heat during operation, necessitating innovative solutions to remove this heat effectively. Existing systems rely on air or single-phase liquid cooling. However, rapid advancements of electronics, particularly AI microchips, demands that temperature of the liquid delivered to the microchips be lowered, resulting in greater chiller systems energy consumption.

Continuous advancement in microchips technology, driven by rapidly rising need for compute power is surpassing the capability of single-phase liquid heat sinks. As a result, introduction of innovative thermal management methods is desired to address demands of future electronic devices. Phase change heat sinks wherein boiling of a liquid is carried out has the ability to dissipate large quantities of heat from a microchip since it relies on the liquid latent heat of vaporization. Hence, cooling with phase change process can take place at a relatively small temperature difference between the microchip and the boiling liquid. As such, phase change heat transfer is considered the next step in advancing the data center cooling technology, and extensive research in being conducted to achieve performance levels exceeding those of the single-phase heat sinks and to address operational issues associated with a phase-change system.

Research on flow boiling in microchannel heat sinks has focused on enhancing heat transfer while reducing pressure drop and flow instabilities. In a conventional microchannel, liquid enters the channel while both liquid and vapor exit as a mixture. Heat transfer coefficient is a function of flow regime within the channel. There are three prominent flow regimes in microchannels including: 1) bubbly flow in which discrete bubbles are dispersed within the liquid, 2) elongated bubbles where in bubbles grow large enough to occupy the channel cross section, and 3) annular flow in which a thin liquid layer flows with a vapor core along the channel length. Efforts on heat transfer enhancement are focused on disruption of the thermal boundary layer and evaporation of the thin liquid layers formed on the microchannel wall surfaces.

Flow instabilities are complex and could greatly diminish microchannel heat sinks' performance, resulting in significant reduction in their cooling capacity. Four instability mechanisms relevant to the present investigation are the Rapid Bubble Growth (RBG), Ledinegg, Parallel Channel Flow (PCF), and the Critical Heat Flux (CHF) condition. These mechanisms are coupled. For instance, flow oscillations due to RBG instability can cause CHF or can trigger the PCF instability. RBG arises when bubbles grow explosively pushing the liquid upstream and into neighboring channels. Various techniques have been pursued to avoid high pressure drops or pressure fluctuations. These techniques include artificial nucleation sites, inlet restrictors, different inlet/outlet configurations, and various channel geometries.

Although improvements in performance characteristics of phase-change heat sinks have been extensively pursued, a breakthrough that could address shortcomings of phase change heat sinks, in relation to implementation in a computer server rack has not emerged. Regardless of whether individual heat sinks experience instability or not, development of a system consisting of numerous heat sinks within a rack operating reliably under highly dynamic conditions (due to continuous changes in processors power i.e., heat sink heat input) has been the primary challenge. This challenge arises from the fact that the pressure drop of the phase-change heat sinks is strongly affected by rapid growth of bubbles and the volume of vapor generated within the heat sink. Consequently, the heat sink pressure drop is a function of the microchip power. In a system with many heat sinks, this inherent characteristic of conventional heat sinks results in flow maldistribution, requiring flow control equipment to balance liquid delivery to servers and individual heat sinks based on their thermal load.

As such, there remains a great need for heat sinks that can handle high heat loads and variable heat loads across electrical devices and systems, and heat sinks that can operate at high heat transfer coefficients, achieve a high vapor outlet quality, and which requires minimal pumping power requirement.

### BRIEF SUMMARY

Disclosed are dual-phase heat sinks that use vapor-permeable membrane(s) to reach unprecedented heat transfer coefficient and waste heat temperature recovery levels. Vapor-permeable membranes function as a mass controller, permitting the entry of liquid phase heat exchange fluid into heat sink in equilibrium with the amount of vapor phase heat exchange fluid that is communicated through the vapor-permeable membrane. Reduced pressure drop across heat sink enables operation under hydrostatic pressure. Heat sinks comprise a thin tungsten-containing base between heat sink and a heat emitting chip that improves stress distribution on the chip, reducing mechanical strain from thermal stresses, and increasing durability of chip-heat sink integrated package while minimizing impact on thermal performance due to lower thermal conductivity of tungsten-containing base material relative to heat sink materials. The membrane is scaled to allow for inflow of liquid phase fluid to heat sink but only allow for vapor-phase outflow from heat sink.

Embodiments of the invention are directed to heat sinks that have a liquid fluid entrance but a vapor fluid exit, where the vapor quality is 100%. The heat sink employs a hydrophobic porous membrane through which vapor readily passes but liquid cannot. As a growing bubble touches the membrane, the liquid-vapor contact line formed between the bubble and membrane recedes exerting a net force on the bubble pulling it away from the hot surface. This phenomenon fundamentally changes the physics of fluid flow near the surface since removing bubbles allows the liquid to rapidly rewet and cool the surface, resulting in major increase in the rate of heat transfer and maintaining a low surface temperature.

In the systems and devices of the current disclosure, bubble density is on the order of 1,000 times lower than the liquid. Hence, vaporization of a small amount of liquid results in generation of a bubble 1,000 times larger in volume. The membrane discharges bubbles from the liquid pool immediately as they form hence preventing high fluid velocities and associated excessive pressure drop within the liquid pool. Hence, the heat sink has substantially lower pressure drop relative to conventional heat sinks.

The device may comprise trenches configured and dimensioned to evenly supply coolant liquid to finned microstructured regions, which may increase the heat transfer area and enhance liquid wickability. This design facilitates evaporation and ensures vapor exits to a condenser. The liquid introduction rate is balanced with vapor exit, enabling effective operation across a wide range of heat loads. The membrane retains liquid within the fins, ensuring full evaporation before additional liquid enters. By leveraging phase change over predefined surface structures, the evaporated liquid exits directly from above the fins, preventing pressure buildup and bubble kickback, thereby promoting efficient cooling and mitigating flow instabilities.

The device may employ trenches that supply liquid to an active area where fins support the membrane from which refrigerant exits as a vapor to a condenser. The rate of liquid introduction is readily balanced with the vapor exit to be of service over an extremely wide range of heat loads. The heat sink utilizes micro-engineered structures to enhance the overall heat sink heat transfer area and hence heat transfer coefficient. This configuration maintains the liquid constrained over the surface while only allowing the vapor exit to the vapor space.

According to an embodiment, a method for forming/manufacturing a device or apparatus, such as a heat sink device or the like, can be carried out. The method can comprise: coupling a top surface surrounding a liquid region to a portion of a bottom surface of a vapor-permeable membrane, coupling a bottom surface surrounding a vapor region to a portion of a top surface of the vapor-permeable membrane such that the vapor-permeable membrane is interposed between the liquid region and the vapor region to form a membrane heat sink, and coupling a top surface of a contact portion to a bottom surface of the liquid region. In some embodiments, the contact portion comprises a tungsten-containing material having a coefficient of thermal expansion below a predetermined threshold. In some embodiments, the liquid region comprises an inlet port configured to communicate a liquid phase heat exchange fluid into the liquid region. In some embodiments, the vapor region comprises an outlet port configured to communicate a vapor phase heat exchange fluid out of the membrane heat sink. In some embodiments, the vapor-permeable membrane is configured to allow communication therethrough of the vapor phase heat exchange fluid and disallow communication therethrough of the liquid phase heat exchange fluid.

In some embodiments, a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region. In some embodiments, a rate of communication of the liquid phase heat exchange fluid through the inlet port and into the liquid region is based on the rate of communication of the vapor phase heat exchange fluid through vapor-permeable membrane from the liquid region to the vapor region. In some embodiments, the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid. In some embodiments, the rate at which the liquid phase heat exchange fluid undergoes the phase change to the vapor phase heat exchange fluid is based upon a quantity of the heat absorbed by the liquid phase heat exchange fluid.

In some embodiments, the quantity of the heat absorbed by the liquid phase heat exchange fluid is based upon a quantity of heat communicated through the contact portion. In some embodiments, the membrane heat sink is further configured, during a first time, to absorb a first quantity of heat emitted by a collocated heat source, causing the liquid phase heat exchange fluid in the liquid region to undergo a phase change to the vapor phase heat exchange fluid at a first rate. In some embodiments, the volume of the liquid phase heat exchange fluid that undergoes the phase change to the vapor phase heat exchange fluid during the first time is based upon a first quantity of the heat absorbed by the liquid phase heat exchange fluid during the first time.

In some embodiments, the membrane heat sink is further configured, during a second time, to absorb a second quantity of heat emitted by the collocated heat source, causing the liquid phase heat exchange fluid in the liquid region to undergo the phase change to the vapor phase heat exchange fluid at a second rate. In some embodiments, the volume of the liquid phase heat exchange fluid that undergoes the phase change to the vapor phase heat exchange fluid during the second time is based upon a second quantity of the heat absorbed by the liquid phase heat exchange fluid during the second time.

In some embodiments, the tungsten-containing material comprises a copper-tungsten alloy. In some embodiments, one or more of: the liquid region, the vapor region, or the vapor-permeable membrane comprises a copper-based material. In some embodiments, the predetermined threshold for the coefficient of thermal expansion of the tungsten-containing material is between about 4.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

In some embodiments, the method can further comprise: disposing a volume of a fluidic solder between a bottom surface of the contact portion and a top portion of the collocated heat source and allowing the fluidic solder to cool and harden to couple the contact portion to the collocated heat source. In some embodiments, the collocated heat source comprises one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the liquid phase heat exchange fluid comprises one or more of: water, a fluorocarbon, or a hydrofluorocarbon. In some embodiments, the vapor-permeable membrane is microporous or nanoporous.

In some embodiments, the vapor permeable membrane comprises a mesh formed from a hydrophobic material. In some embodiments, the hydrophobic material comprises one of: polytetrafluoroethylene (PTFE), polyvinylidene fluoride (PVDF), other such polymeric materials, a hydrophobic treated metal material, such as copper or nickel coated with a hydrophobic material, copper treated with a material/chemical so as to be hydrophobic, any other suitable materials, or combinations thereof. In some embodiments, one or more materials for the vapor permeable membrane is chosen based on what material or combination of materials achieves a water contact angle of greater than about 90 degrees. In some embodiments, the liquid chamber comprises a plurality of structures that stand proud of a top surface of the liquid chamber, wherein one or more of the plurality of structures are configured to support the vapor permeable membrane at one or more locations across a bottom surface of the vapor permeable membrane. In some embodiments, the vapor chamber comprises a second plurality of structures that stand proud of a bottom surface of the vapor chamber, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

According to another embodiment, an apparatus or device can be provided that comprises: a contact portion comprising a tungsten-containing material having a coefficient of thermal expansion below a predetermined threshold, and a membrane heat sink joined to a top surface of the contact portion. In some embodiments, the membrane heat sink can comprise: a liquid region comprising an inlet port configured to communicate a liquid phase heat exchange fluid into the liquid region, a bottom surface of the liquid region being adjacent to the top surface of the contact portion, a vapor region comprising an outlet port configured to communicate a vapor phase heat exchange fluid out of the membrane heat sink, and a vapor-permeable membrane disposed between the liquid region and the vapor region.

In some embodiments, the vapor-permeable membrane is configured to allow communication therethrough of the vapor phase heat exchange fluid and disallow communication therethrough of the liquid phase heat exchange fluid. In some embodiments, a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region. In some embodiments, a rate of communication of the liquid phase heat exchange fluid through the inlet port and into the liquid region is based on the rate of communication of the vapor phase heat exchange fluid through vapor-permeable membrane from the liquid region to the vapor region. In some embodiments, the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid. In some embodiments, the rate at which the liquid phase heat exchange fluid undergoes the phase change to the vapor phase heat exchange fluid is based upon a quantity of the heat absorbed by the liquid phase heat exchange fluid. In some embodiments, the quantity of the heat absorbed by the liquid phase heat exchange fluid is based upon a quantity of heat communicated through the contact portion.

In some embodiments, the membrane heat sink is further configured, during a first time, to absorb a first quantity of heat emitted by a collocated heat source, causing the liquid phase heat exchange fluid in the liquid region to undergo a phase change to the vapor phase heat exchange fluid at a first rate. In some embodiments, the volume of the liquid phase heat exchange fluid that undergoes the phase change to the vapor phase heat exchange fluid during the first time is based upon a first quantity of the heat absorbed by the liquid phase heat exchange fluid during the first time. In some embodiments, the membrane heat sink is further configured, during a second time, to absorb a second quantity of heat emitted by the collocated heat source, causing the liquid phase heat exchange fluid in the liquid region to undergo the phase change to the vapor phase heat exchange fluid at a second rate. In some embodiments, the volume of the liquid phase heat exchange fluid that undergoes the phase change to the vapor phase heat exchange fluid during the second time is based upon a second quantity of the heat absorbed by the liquid phase heat exchange fluid during the second time. In some embodiments, the liquid phase heat exchange fluid comprises one or more of: water, a fluorocarbon, or a hydrofluorocarbon. In some embodiments, the vapor-permeable membrane is microporous or nanoporous.

In some embodiments, the tungsten-containing material comprises a copper-tungsten alloy. In some embodiments, one or more of: the liquid region, the vapor region, or the vapor-permeable membrane comprises a copper-based material.

In some embodiments, the collocated heat source comprises one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit.

In some embodiments, the apparatus/device can further comprise: a solder interface joining a bottom surface of the contact portion to a top portion of the collocated heat source.

In some embodiments, a thickness of the membrane heat sink is less than a thickness of the contact portion. In some embodiments, a thickness of the contact portion is greater than a thickness of the collocated heat source. In some embodiments, a thickness of the contact portion is between about 50 μm and about 500 μm. In some embodiments, a thickness of the overlay portion or the bottom portion of the overlay portion is between about 50 μm and about 500 μm. In some embodiments, the thickness of the contact portion is about 450 μm and the thickness of the bottom portion of the overlay portion is about 50 μm.

In some embodiments, the predetermined threshold for the coefficient of thermal expansion of the tungsten-containing material is between about 4.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

In some embodiments, the vapor permeable membrane comprises a mesh formed from a hydrophobic material. In some embodiments, the hydrophobic material comprises one of: polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, the liquid chamber comprises a plurality of structures that stand proud of a top surface of the liquid chamber, wherein one or more of the plurality of structures are configured to support the vapor permeable membrane at one or more locations across a bottom surface of the vapor permeable membrane. In some embodiments, the vapor chamber comprises a second plurality of structures that stand proud of a bottom surface of the vapor chamber, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

According to another embodiment, a membrane heat sink can be provided that comprises: a contact portion formed from a tungsten-containing material having a coefficient of thermal expansion below a predetermined threshold; an overlay portion comprising a bottom portion and a top portion, wherein the bottom portion of the overlay portion is disposed onto a top surface of the contact portion, the overlay portion defining a first inner volume within the bottom portion, a liquid inlet into the first inner volume in the bottom portion, a second inner volume within the top portion, and a vapor outlet out of the second inner volume, wherein the first inner volume of the overlay portion is configured to conduct heat from a collocated heat generating device into a heat exchange fluid disposed within the first inner volume of the overlay portion of the membrane heat sink, thereby causing a phase change of the heat exchange fluid from a liquid phase to a vapor phase; and a vapor permeable membrane disposed between the first inner volume and the second inner volume of the overlay portion, the vapor permeable membrane being configured to allow communication of the heat exchange fluid in the vapor phase from the first inner volume through the vapor permeable membrane and into the second inner volume, the vapor permeable membrane being further configured to disallow communication of the heat exchange fluid in the liquid phase from the first inner volume through the vapor permeable membrane and into the second inner volume.

In some embodiments, the tungsten-containing material comprises a copper-tungsten alloy. In some embodiments, the overlay portion comprises a copper-based material. In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the membrane heat sink further comprises: a solder interface joining a bottom surface of the contact portion to a top portion of the heat generating element. In some embodiments, a thickness of the overlay portion is less than a thickness of the contact portion. In some embodiments, a thickness of the contact portion is greater than a thickness of the heat generating element.

In some embodiments, a thickness of the contact portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 80 μm, less than about 60 μm, less than about 40 μm, less than about 20 μm, less than about 10 μm, or less than about 5 μm, inclusive of all values and ranges therebetween.

In some embodiments, a thickness of the bottom portion of the overlay portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 90 μm, less than about 80 μm, less than about 70 μm, less than about 60 μm, less than about 50 μm, less than about 40 μm, less than about 30 μm, less than about 20 μm, greater than about 20 μm, greater than about 40 μm, greater than about 60 μm, greater than about 80 μm, greater than about 100 μm, greater than about 200 μm, greater than about 300 μm, greater than about 400 μm, greater than about 500 μm, greater than about 600 μm, greater than about 700 μm, greater than about 800 μm, greater than about 900 μm, or greater than about 1.00 μm, inclusive of all values and ranges therebetween.

In some embodiments, the thickness of the contact portion is between about 50 μm and about 500 μm and the thickness of the bottom portion of the overlay portion is between about 50 μm and about 500 μm.

In some embodiments, the predetermined threshold for the coefficient of thermal expansion of the tungsten-containing material is between about 4.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %. In some embodiments, a copper concentration of the tungsten-containing material is between about 50 wt. % and about 99 wt. %.

In some embodiments, the coefficient of thermal expansion of the bottom portion of the overlay portion is between about 10×10⁻⁶ K⁻¹ and about 25×10⁻⁶ K⁻¹. In some embodiments, a density of the bottom portion of the overlay portion is between about 5,000 kg/m³ and about 10,000 kg/m³. In some embodiments, a Young's modulus of the bottom portion of the overlay portion is between about 75 GPa and about 150 GPa. In some embodiments, a thermal conductivity of the bottom portion of the overlay portion is between about 300 W/m·K and about 500 W/m·K. In some embodiments, a specific heat capacity of the bottom portion of the overlay portion is between about 300 J/kg·K and about 500 J/kg·K. In some embodiments, a copper concentration of the bottom portion of the overlay portion is between about 50 wt. % and about 99 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic. In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

According to another embodiment, a method for forming a membrane heat sink, such as described above or elsewhere herein can be carried out, the method comprising: providing a bottom portion of an overlay portion comprising a metal-based material, the bottom portion comprising a first aperture therethrough defining a liquid inlet, the first aperture being configured to allow for communication of a heat exchange fluid in a liquid phase through the liquid inlet and into an inner volume of the bottom portion of the overlay portion of the membrane heat sink; providing a top portion of the overlay portion of the membrane heat sink comprising the metal-based material, the top portion comprising a second aperture therethrough defining a vapor outlet, the second aperture being configured to allow for communication of the heat exchange fluid in a vapor phase out of an inner volume of the top portion of the overlay portion of the membrane heat sink through the vapor outlet; providing a vapor permeable membrane comprising a hydrophobic material, the vapor permeable membrane being dimensioned and configured to allow communication of the heat exchange fluid in the vapor phase from the inner volume of the bottom portion through the vapor permeable membrane and into the inner volume of the top portion, the vapor permeable membrane being further configured to disallow communication of the heat exchange fluid in the liquid phase from the inner volume of the bottom portion through the vapor permeable membrane and into the inner volume of the top portion; disposing the vapor permeable membrane between the top portion and the bottom portion to form an overlay portion of the membrane heat sink, thereby encapsulating at least a portion of the vapor permeable membrane within an inner volume of the overlay portion, forming a first inner volume between a bottom surface of the vapor permeable membrane and a top surface of the bottom portion of the overlay portion, and forming a second inner volume between a top surface of the vapor permeable membrane and a bottom surface of the top portion of the overlay portion; providing a contact portion comprising a tungsten-containing material; and joining a top surface of the contact portion to a bottom surface of the bottom portion of the overlay portion.

In some embodiments, the method can further comprise: forming the bottom portion of the overlay portion comprising the metal-based material. In some embodiments, this can be carried out by die pressing, additive metal manufacturing, casting, electrodeposition, or any other suitable approach. The first aperture defining the liquid inlet can be formed during casting by way of mold configuration or the like, additive manufacturing, or can be formed by material removal according to various techniques. The method can further comprise: forming the top portion of the overlay portion of the membrane heat sink comprising the metal-based material. This can also be carried out by die pressing, additive metal manufacturing, casting, or the like. The second aperture defining the vapor outlet can also be formed during manufacturing or by material removal afterwards. The bottom and/or top portion(s), forming the overlay portion of the membrane heat sink can comprise a copper-containing material or a copper-based material.

The method can further comprise: forming the vapor permeable membrane comprising the hydrophobic material. This can be carried out by forming a sheet of metal-containing material, removing portions of that material from the sheet to form a mesh having an average aperture density and an average mesh size/diameter as needed. The mesh can then be treated with (e.g., sprayed, dipped, or otherwise exposed to) a hydrophobic material to form a hydrophobic surface coating on at least a portion of the mesh. Conversely, the sheet can initially be treated with a hydrophobic material to form a hydrophobic surface coating on the sheet before material is removed to form the mesh. Either way, the mesh can be formed and can comprise a hydrophobic surface coating that makes the mesh impermeable to a desired heat exchange fluid when that heat exchange fluid is in a liquid phase, while being permeable (e.g., via vapor wicking) to the desired heat exchange fluid when that heat exchange fluid is in a vapor phase.

In some embodiments, said disposing the vapor permeable membrane between the top portion and the bottom portion to form the overlay portion of the membrane heat sink can be carried out by joining a first side (e.g., along two or more edges) of the vapor permeable membrane to the top portion or the bottom portion of the overlay portion, and then joining the other of the top portion or the bottom portion of the overlay portion to a second side (e.g., along two or more edges) of the vapor permeable membrane, thereby encapsulating at least a portion of the vapor permeable membrane within the inner volume of the overlay portion.

In some embodiments, the method can further comprise forming the contact portion comprising the tungsten-containing material. This can be carried out by mixing tungsten with one or more other materials, such as metals or the like (e.g., copper), and then casting, smelting, rolling, milling, and/or sintering processes are used to form a thin sheet of the tungsten-containing material. In some embodiments, the tungsten-containing material is a sheet comprising a tungsten-copper alloy that is formed by mixing tungsten powder and copper powder in suitable mass or volume concentrations until mechanically alloyed and sintered, then annealing/sintering the alloyed material, then rolling the alloy into a sheet/roll having the desired thickness, and cutting out a portion of that sheet suitable for the contact portion of the membrane heat sink.

In some embodiments, said joining the top surface of the contact portion to the bottom surface of the bottom portion of the overlay portion can be carried out by any suitable thermal approach, chemical approach, radiative approach, and/or combinations thereof. For example, welding, brazing, friction bonding, and/or soldering can be used to join the contact portion to the overlay portion to form the membrane heat sink.

In some embodiments, the tungsten-containing material has a coefficient of thermal expansion below a predetermined threshold. In some embodiments, the tungsten-containing material comprises a copper-tungsten alloy. In some embodiments, the overlay portion comprises a copper-based material.

In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the method further comprises: providing the heat generating element; and soldering a bottom surface of the contact portion of the membrane heat sink to a top portion of the heat generating element.

In some embodiments, a thickness of the overlay portion is less than a thickness of the contact portion. In some embodiments, a thickness of the contact portion is greater than a thickness of the heat generating element. In some embodiments, a thickness of the contact portion is between about 50 μm and about 500 μm. In some embodiments, a thickness of the bottom portion of the overlay portion is between about 50 μm and about 500 μm. In some embodiments, the thickness of the contact portion is about 450 μm and the thickness of the bottom portion of the overlay portion is about 50 μm.

In some embodiments, a thickness of the contact portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 80 μm, less than about 60 μm, less than about 40 μm, less than about 20 μm, less than about 10 μm, or less than about 5 μm, inclusive of all values and ranges therebetween.

In some embodiments, a thickness of the overlay portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 90 μm, less than about 80 μm, less than about 70 μm, less than about 60 μm, less than about 50 μm, less than about 40 μm, less than about 30 μm, less than about 20 μm, greater than about 20 μm, greater than about 40 μm, greater than about 60 μm, greater than about 80 μm, greater than about 100 μm, greater than about 200 μm, greater than about 300 μm, greater than about 400 μm, greater than about 500 μm, greater than about 600 μm, greater than about 700 μm, greater than about 800 μm, greater than about 900 μm, or greater than about 1.00 μm, inclusive of all values and ranges therebetween.

In some embodiments, the thickness of the contact portion is between about 50 μm and about 500 μm and the thickness of the overlay portion is between about 50 μm and about 500 μm.

In some embodiments, the predetermined threshold for the coefficient of thermal expansion of the tungsten-containing material can be between about 4.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %. In some embodiments, a copper concentration of the tungsten-containing material is between about 50 wt. % and about 99 wt. %.

In some embodiments, the coefficient of thermal expansion of the bottom portion of the overlay portion is between about 10×10⁻⁶ K⁻¹ and about 25×10⁻⁶ K⁻¹. In some embodiments, a density of the bottom portion of the overlay portion is between about 5,000 kg/m³ and about 10,000 kg/m³. In some embodiments, a Young's modulus of the bottom portion of the overlay portion is between about 75 GPa and about 150 GPa. In some embodiments, a thermal conductivity of the bottom portion of the overlay portion is between about 300 W/m·K and about 500 W/m·K. In some embodiments, a specific heat capacity of the bottom portion of the overlay portion is between about 300 J/kg·K and about 500 J/kg·K. In some embodiments, a copper concentration of the bottom portion of the overlay portion is between about 50 wt. % and about 99 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

Also described herein are membrane-based heat sinks and membrane-based heat exchangers, as well as servers, server racks, server arrays, and data centers using the same to cool collocated computing devices therein/thereof. For example, a dual-phase membrane heat sink system can comprise a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of a plurality of computing devices. In some embodiments, each of the plurality of membrane heat sinks comprise: a bottom structure defining a first portion of an inner volume of the membrane heat sink, the bottom structure comprising a liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure.

In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes phase change of an amount equal to the volume of the incoming heat exchange fluid from the liquid phase to a vapor phase. In some embodiments, the vapor-permeable membrane is configured to allow the portion of the volume of the heat exchange fluid that changes phase from the liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the dual-phase membrane heat sink system further comprises: a heat exchange fluid recovery unit configured to cause a second phase change of the volume of the heat exchange fluid in the vapor phase back to the liquid phase. In some embodiments, the dual-phase membrane heat sink system further comprises: a heat exchange fluid distribution system in fluidic communication with the heat exchange fluid reservoir and the plurality of membrane heat sinks.

In some embodiments, the heat exchange fluid distribution system is configured to maintain the heat exchange fluid within the heat exchange fluid distribution system at a hydrostatic pressure within a predetermined range.

According to another embodiment, a server cluster can be provided that is configured for data processing and/or storage in a data center, the server cluster comprising: a plurality of computing devices arranged in a plurality of server racks, each server rack of the plurality of server racks comprising two or more of the plurality of computing devices; a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of the plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that changes phase from liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the server cluster further comprises: a heat exchange fluid recovery unit configured to cause a second phase change of the volume of the heat exchange fluid in the vapor phase back to the liquid phase. In some embodiments, the server cluster further comprises: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydrostatic pressure within a predetermined range. In some embodiments, the heat exchange fluid reservoir is further configured to cause a second phase change of the volume of the heat exchange fluid in the vapor phase back to the liquid phase. In some embodiments, heat removed from the heat exchange fluid reservoir is transferred to a server cluster primary loop of the data center and heat exchange fluid converted back to the liquid phase is transferred back to a primary liquid cooling loop of the data center.

According to another embodiment, a heat sink array can be provided that is configured for cooling a server cluster comprising a plurality of server racks, the heat sink array being configured to be collocated with the server cluster, the heat sink array comprising: a heat exchange fluid reservoir configured to store a supply of a heat exchange fluid in a liquid phase; a plurality of heat exchangers, each of the plurality of heat exchanges configured to be collocated with respective servers of one of the server racks in the server cluster, each of the plurality of heat exchangers comprising an inner volume, a vapor-permeable membrane dimensioned and configured to divide the inner volume of the heat exchanger into at least a first portion and a second portion, a liquid fluid inlet, and a vapor fluid outlet. In some embodiments, the liquid fluid inlet is configured to allow a liquid volume of the heat exchange fluid to be communicated into the first portion of the inner volume of the heat exchanger. In some embodiments, in response to the liquid volume of the heat exchange fluid being exposed to heat from one or more computing entities in one or more server racks of the server cluster collocated with the heat exchanger, at least a portion of the liquid volume of the heat exchange fluid phase changes into a vapor volume of the heat exchange fluid. In some embodiments, the vapor-permeable membrane is configured to allow heat exchange fluid in a vapor phase to be communicated therethrough from the first portion of the inner volume of the heat exchanger to the second portion of the inner volume of the heat exchanger and disallow heat exchange fluid in a liquid phase to be communicated therethrough from the first portion of the inner volume of the heat exchanger to the second portion of the inner volume of the heat exchanger. In some embodiments, the vapor outlet is configured to allow communication of some or all of the vapor volume of the heat exchange fluid out of the heat exchanger following the communication of vapor volume of the heat exchange fluid through the vapor-permeable membrane and into the second portion of the inner volume of the heat exchange fluid following the phase change.

According to another embodiment, a heat exchanger device can be provided that comprises: a heat exchange fluid reservoir configured to store a replenishing supply of a heat exchange fluid in a liquid phase; a heat exchanger in fluidic communication with the heat exchange fluid reservoir, the heat exchanger being configured to receive a liquid volume of the heat exchange fluid, expose the liquid volume of the heat exchange fluid to waste heat from one or more collocated computing devices such that at least some of the liquid volume of the heat exchange fluid undergoes a phase change from a liquid phase to a vapor change, and allow communication of a vapor volume of the heat exchange fluid out of the heat exchanger; and a heat exchange fluid recovery unit in fluidic communication with the heat exchanger, the heat exchange fluid recovery unit being configured to cause a further phase change of the vapor volume of the heat exchange fluid from the vapor phase to the liquid phase. In some embodiments, the heat exchanger comprises a vapor-permeable membrane interposed between a first portion of the inner volume of the heat exchanger and a second portion of the inner volume of the heat exchanger.

In some embodiments, the heat exchanger further comprises: a bottom structure defining a first portion of an inner volume of the heat exchanger, the bottom structure comprising a liquid inlet at least partially defined by an aperture through the bottom structure, the liquid inlet being configured to allow the liquid volume of the heat exchange fluid to be communicated from the heat exchange fluid reservoir into the first portion of the inner volume of the heat exchanger. In some embodiments, the heat exchanger further comprises: a top structure defining a second portion of the inner volume of the heat exchanger, the top structure comprising a vapor outlet at least partially defined by an aperture through the top structure, the vapor outlet being configured to allow a volume of the heat exchange fluid in a fluid phase to be communicated out of the second portion of the inner volume of the heat exchanger.

In some embodiments, a portion of a first surface of the vapor-permeable membrane is sealably joined to an inside surface of the bottom structure and a portion of a second surface of the vapor-permeable membrane is sealably joined to an inside surface of the top structure. In some embodiments, the bottom structure of the heat exchanger is configured to allow said exposure of the liquid volume of the heat exchange fluid to said waste heat from the one or more collocated computing devices. In some embodiments, the vapor outlet is configured to allow communication of some or all of the vapor volume of the heat exchange fluid to be communicated out of the heat exchange following the communication of vapor volume of the heat exchange fluid through the vapor-permeable membrane and into the second portion of the inner volume of the heat exchange fluid following the phase change. In some embodiments, the vapor-permeable membrane is configured to prevent communication therethrough of the heat exchange fluid in the liquid phase, thereby protecting said heat-generating component from liquid-related damage. In some embodiments, the heat exchanger device is configured to efficiently dissipate said waste heat generated by the one or more collocated computing devices, thereby increasing an overall thermal performance of said one or more collocated computing devices.

Some embodiments of the present disclosure describe two-phase heat sinks that utilize nucleate boiling at a predefined liquid-vapor interface as the primary mode of heat transfer. In one embodiment, liquid and vapor microchannels are separated by arrays of evenly spaced posts, which enhance liquid inflow to the surface structures through wicking action. Bubbles and vapor columns form at the interface and are rapidly expelled to the vapor space above the membrane. This configuration helps mitigate instability issues commonly associated with randomly expanding evaporative interfaces during boiling. While not bound to any specific theory, this improved stability may result from the rapid removal of vapor following the phase change and its flux through the vapor-permeable membrane

Some embodiments of the present disclosure are directed to two-phase heat sinks that utilize thin film evaporation over a predefined liquid-vapor interface as the main mode of heat transfer. In one embodiment, liquid and vapor microchannels are separated with arrays of equi-spaced posts, which act as capillary forced valves and limit mixing of liquid and vapor phases. The location and shape of the meniscus can be altered by the device geometry, surface characteristics, and liquid pressure at the interface. In this manner, instability issues associated with randomly-moving evaporative interface in boiling can be significantly reduced. Without wishing to be bound by any particular theory, this may be due, at least in part, to the vapor rapidly exiting the heat sink/heat exchange following the phase change of the heat exchange fluid and the flux of the vapor through the vapor-permeable membrane.

The proposed heat sink system addresses the challenges associated with traditional cooling methods by integrating a vapor-permeable membrane with each computing device in a server rack. This membrane, strategically positioned in proximity to the heat-generating components, enables efficient heat dissipation through the process of vapor transport. Simultaneously, it acts as a protective barrier against liquid ingress, safeguarding the computing devices from potential damage. In some embodiments, the membrane can serve as a mass controller, thereby reducing or eliminating the need for expensive mass controllers that are typically required if a heat sink allows liquid to exit the heat sink. Conversely, conventional heat sinks and heat exchange systems typically experience flow maldistribution, and therefore require mass flow control of heat exchange fluid through the system.

In some embodiments, such a heat sink can be operated at least partially using hydrostatic pressure. Without wishing to be bound by any particular theory, as heat exchange fluid in one of the disclosed heat exchangers experiences a phase change from a liquid state to a vapor state, bubbles of heat exchange fluid in the vapor phase are formed in the remaining liquid heat exchange fluid, and the bubbles (vapor heat exchange fluid) exit the heat exchanger by being communicated through a vapor-permeable membrane that disallows any heat exchange fluid in a liquid state to be communicated therethrough. Without wishing to be bound by any particular theory, this may result in a low pressure change (e.g., low pressure drop) between upstream heat exchange fluid in the liquid state, a first portion of the inner volume of the heat exchanger where the phase change occurs, a second portion of the inner volume of the heat exchanger separated from the first portion by the vapor-permeable membrane, and an outlet side of the second portion of the heat exchanger where heat exchange fluid in the vapor phase is communicated out of the heat exchanger. The pressure change experienced by the heat exchangers disclosed herein is lower—in some cases much lower-than the pressure change experienced by conventional heat exchangers where the partial pressure can often change drastically as an increasing percentage of liquid becomes vapor and the vapor is not able to quickly escape the heat exchanger.

According to some embodiments, a dual-phase membrane heat sink system can be provided that comprises: a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of a plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that phase changes from the liquid phase to the vapor phase to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the dual-phase membrane heat sink system further comprises: a heat exchange fluid recovery unit configured to cause a second phase change of the volume of the heat exchange fluid in the vapor phase back to the liquid phase. In some embodiments, the dual-phase membrane heat sink system further comprises: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydraulic pressure within a predetermined range.

According to another embodiment, a server cluster can be provided that comprises: a plurality of computing devices arranged in a plurality of server racks, each server rack of the plurality of server racks comprising two or more of the plurality of computing devices; a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of the plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that phase changes from the liquid phase to the vapor phase to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the server cluster can further comprise: a heat exchange fluid recovery unit configured to cause a second phase change of the volume of the heat exchange fluid in the vapor phase back to the liquid phase. In some embodiments, the server cluster can further comprise: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydrostatic pressure within a predetermined range, sufficient to overcome the heat sink pressure drop without significantly impacting the heat sink saturation pressure and temperature. For example, in an example system, a pressure drop across the heat exchanger(s) may be less than or equal to about 5 kpa. As such, the hydrostatic pressure of liquid phase heat exchange fluid upstream of the heat exchanger(s) can be maintained between about 0.5 kpa and about 5 kpa such that a consistent supply of liquid phase heat exchange fluid is provided to the liquid inlet of the heat exchanger(s). The predetermined range may be based on predetermined hydrostatic pressure values above a mean or average pressure drop across the heat exchangers, a minimum pressure drop across the heat exchangers, a maximum pressure drop across the heat exchangers, a median pressure drop across the heat exchangers, and/or the like.

Heat exchange fluid demand will vary between different heat exchangers based on the heat generated at each of the collocated computing devices (e.g., GPUs, CPUs, chipsets, servers, racks, etc.). Since the hydrostatic pressure of the liquid phase heat exchange fluid upstream of the heat exchanger(s) should be maintained within a predetermined range above the pressure drop experienced across the heat exchanger(s) (e.g., maximum pressure drop), decreasing the maximum pressure drop experienced across the heat exchangers may result in a decrease in the predetermined range for hydrostatic pressure of the liquid phase heat exchange fluid that must be maintained upstream of the heat exchangers.

For example, a conventional heat exchanger may have a maximum pressure drop across the heat exchanger of about 5 kpa, such that a good rule of thumb would be to maintain the upstream liquid phase heat exchange fluid at a hydrostatic pressure of between about 0.5 kpa and about 5 kpa. Conversely, an example heat exchanger as disclosed herein may experience a maximum pressure drop across the heat exchanger of about 2 kpa, meaning that the upstream liquid phase heat exchange fluid should be maintained at a hydrostatic pressure of between about 3 kpa and about 5 kpa. The benefits of the disclosed systems are numerous, including that a lower range of hydrostatic pressure for the upstream liquid phase heat exchange fluid may mean that the system could/can work passively, as a thermosyphon, and/or smaller scale infrastructure and components, such as pumps, meters, and the like, may be required. Further, a lower range of hydrostatic pressure for the upstream liquid phase heat exchange fluid may mean that less mechanically durable, and therefore less expensive, materials can be used for the heat exchanger, the inlet piping, the vapor-permeable membrane, and other components and materials that directly or indirectly contact the heat exchange fluid. Also, a lower range of hydrostatic pressure for the upstream liquid phase heat exchange fluid may result in a lower probability of material/component failures, heat exchange fluid leaks and spills, and the like. This can improve the safety of the system for human operators, reduce detrimental environmental impacts from undesirable release of heat exchange fluid, reduce operating costs, reduce system downtime, reduce preventative maintenance and repairs, and/or the like.

According to another embodiment, a heat sink array can be provided that is configured for cooling a server cluster comprising a plurality of server racks, the heat sink array being configured to be collocated with the server cluster. In some embodiments, the heat sink array comprises: a heat exchange fluid reservoir configured to store a supply of a heat exchange fluid in a liquid phase; a plurality of heat exchangers, each of the plurality of heat exchanges configured to be collocated with respective servers of one of the server racks in the server cluster, each of the plurality of heat exchangers comprising an inner volume, a vapor-permeable membrane dimensioned and configured to divide the inner volume of the heat exchanger into at least a first portion and a second portion, a liquid fluid inlet, and a vapor fluid outlet. In some embodiments, the liquid inlet is configured to allow a liquid volume of the heat exchange fluid to be communicated into the first portion of the inner volume of the heat exchanger. In some embodiments, in response to the liquid volume of the heat exchange fluid being exposed to heat from one or more computing entities in one or more server racks of the server cluster collocated with the heat exchanger, at least a portion of the liquid volume of the heat exchange fluid phase changes into a vapor volume of the heat exchange fluid. In some embodiments, the vapor-permeable membrane is configured to allow heat exchange fluid in a vapor phase to be communicated therethrough from the first portion of the inner volume of the heat exchanger to the second portion of the inner volume of the heat exchanger and disallow heat exchange fluid in a liquid phase to be communicated therethrough from the first portion of the inner volume of the heat exchanger to the second portion of the inner volume of the heat exchanger. In some embodiments, the vapor outlet is configured to allow communication of some or all of the vapor volume of the heat exchange fluid to be communicated out of the heat exchange following the communication of vapor volume of the heat exchange fluid through the vapor-permeable membrane and into the second portion of the inner volume of the heat exchange fluid following the phase change.

According to another embodiment, a heat exchanger device can be provided that comprises: a heat exchange fluid reservoir configured to store a replenishing supply of a heat exchange fluid in a liquid phase; a heat exchanger in fluidic communication with the heat exchange fluid reservoir, the heat exchange being configured to receive a liquid volume of the heat exchange fluid, expose the liquid volume of the heat exchange fluid to waste heat from one or more collocated computing devices such that at least some of the liquid volume of the heat exchange fluid undergoes a phase change from a liquid phase to a vapor change, and allow communication of a vapor volume of the heat exchange fluid out of the heat exchanger; and a heat exchange fluid recovery unit in fluidic communication with the heat exchanger, the heat exchange fluid recovery unit being configured to cause a further phase change of the vapor volume of the heat exchange fluid from the vapor phase to the liquid phase. In some embodiments, the heat exchanger comprises a vapor-permeable membrane interposed between a first portion of the inner volume of the heat exchanger and a second portion of the inner volume of the heat exchanger.

In some embodiments, the heat exchanger further comprises: a bottom structure defining a first portion of an inner volume of the heat exchanger, the bottom structure comprising a liquid inlet at least partially defined by an aperture through the bottom structure, the liquid inlet being configured to allow the liquid volume of the heat exchange fluid to be communicated from the heat exchange fluid reservoir into the first portion of the inner volume of the heat exchanger; a top structure defining a second portion of the inner volume of the heat exchanger, the top structure comprising a vapor outlet at least partially defined by an aperture through the top structure, the vapor outlet being configured to allow a volume of the heat exchange fluid in a fluid phase to be communicated out of the second portion of the inner volume of the heat exchanger.

In some embodiments, a portion of a first surface of the vapor-permeable membrane is sealably joined to an inside surface of the bottom structure and a portion of a second surface of the vapor-permeable membrane is sealably joined to an inside surface of the top structure.

In some embodiments, the bottom structure of the heat exchanger is configured to allow said exposure of the liquid volume of the heat exchange fluid to said waste heat from the one or more collocated computing devices.

In some embodiments, the vapor outlet is configured to allow communication of some or all of the vapor volume of the heat exchange fluid to be communicated out of the heat exchange following the communication of vapor volume of the heat exchange fluid through the vapor-permeable membrane and into the second portion of the inner volume of the heat exchange fluid following the phase change.

In some embodiments, the vapor-permeable membrane is configured to prevent communication therethrough of the heat exchange fluid in the liquid phase, thereby protecting said heat-generating component from liquid-related damage.

In some embodiments, the heat exchanger device is configured to efficiently dissipate said waste heat generated by the one or more collocated computing devices, thereby increasing an overall thermal performance of said one or more collocated computing devices.

### BRIEF DESCRIPTION OF THE DRAWINGS

Having thus described the invention in general terms, reference will now be made to the accompanying drawings. The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 illustrates a conventional heat exchanger system for a server array, according to an embodiment of the present disclosure.

FIG. 2 illustrates several possible regimes for vapor fluid formation and flow within a heat exchanger, according to embodiments of the present disclosure.

FIG. 3 illustrates several possible regimes for vapor fluid formation and flow within a heat exchanger, according to embodiments of the present disclosure.

FIG. 4 illustrates vapor bubble formation and vapor bubble transport through the vapor-permeable membrane, according to an embodiment of the present disclosure.

FIG. 5 illustrates vapor bubble formation and vapor bubble transport through the vapor-permeable membrane, according to an embodiment of the present disclosure.

FIG. 6 illustrates the heat flow pathway for conventional versus phase change heat exchange systems, according to an embodiment of the present disclosure.

FIG. 7 is a graph illustrating heat transfer coefficients (HTC) versus heat flux for a variety of heat exchange fluids contemplated, in accordance with an embodiment of the present disclosure.

FIG. 8 illustrates a phase-changing heat exchange system to maintain sufficiently low operating temperatures for computing devices of a membrane heat sink (MHS)-enabled rack for a data center, in accordance with an embodiment of the present disclosure.

FIG. 9 illustrates an MHS-enabled rack for a data center, in accordance with an embodiment of the present disclosure.

FIG. 10 illustrates an example of a membrane heat sink device, in accordance with an embodiment of the present disclosure.

FIG. 11 illustrates a server rack collocated with a heat exchange system provisioned with volumes of heat exchange fluid, in accordance with an embodiment of the present disclosure.

FIG. 12 illustrates a server array configured into server racks that each are provisioned with volumes of heat exchange fluid, in accordance with an embodiment of the present disclosure.

FIG. 13 illustrates a server array configured into server racks that each are provisioned with volumes of heat exchange fluid, in accordance with an embodiment of the present disclosure.

FIG. 14 is an example chip including heaters to simulate chip hot spots, according to an embodiment of the present disclosure.

FIG. 15 is a heat map of a chip collocated with a heat exchanger, according to an embodiment of the present disclosure.

FIG. 16 is a side-view of a heat sink, in accordance with an embodiment of the present disclosure.

FIG. 17 is a side-view of a heat sink, in accordance with an embodiment of the present disclosure.

FIG. 18 is a schematic illustrating heat transfer through a heat sink, in accordance with an embodiment of the present disclosure.

FIG. 19 illustrates a mesh heat sink, in accordance with an embodiment of the present disclosure.

FIG. 20 illustrates a mesh heat sink, in accordance with an embodiment of the present disclosure.

FIG. 21 illustrates a mesh heat sink, in accordance with an embodiment of the present disclosure.

FIG. 22 illustrates a mesh heat sink, in accordance with an embodiment of the present disclosure.

FIG. 23 illustrates a mesh heat sink, in accordance with an embodiment of the present disclosure.

FIG. 24 illustrates a mesh heat sink, in accordance with an embodiment of the present disclosure.

FIG. 25 illustrates a mesh heat sink, in accordance with an embodiment of the present disclosure.

FIG. 26 is a graph of mesh sizing versus temperature for different mesh types.

FIG. 27 is a heat map illustrating surface temperatures in various portions of a heat sink, in accordance with an embodiment of the present disclosure.

FIG. 28 is a mechanical stress map illustrating stress-based strain exerted on various portions of a heat sink, in accordance with an embodiment of the present disclosure.

FIG. 29 illustrates a schematic of an example computing device according to any of the approaches or methods of the present disclosure.

FIG. 30 is a block flow diagram of a method for forming a membrane heat sink, in accordance with embodiments of the present disclosure.

FIG. 31 is a block flow diagram of a method for forming a membrane heat sink, in accordance with embodiments of the present disclosure.

FIG. 32 is a block flow diagram of a method for forming a membrane heat sink, in accordance with embodiments of the present disclosure.

FIG. 33 is a block flow diagram of a method for forming a membrane heat sink, in accordance with embodiments of the present disclosure.

FIG. 34 is a block flow diagram of a method for forming a membrane heat sink, in accordance with embodiments of the present disclosure.

FIG. 35 is a block flow diagram of a method for forming a membrane heat sink, in accordance with embodiments of the present disclosure.

FIG. 36 is a block flow diagram of a method for forming a membrane heat sink, in accordance with embodiments of the present disclosure.

FIG. 37 is a block flow diagram of a method for forming a membrane heat sink, in accordance with embodiments of the present disclosure.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments of the present disclosure will now be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated.

The terms “illustrative” and “exemplary” are used to be examples with no indication of quality level. Like numbers refer to like elements throughout.

As used herein, the terms “instructions,” “file,” “designs,” “data,” “content,” “information,” and similar terms may be used interchangeably, according to some example embodiments of the present invention, to refer to data capable of being transmitted, received, operated on, displayed, and/or stored. Thus, use of any such terms should not be taken to limit the spirit and scope of the disclosure. Further, where a computing device is described herein to receive data from another computing device, it will be appreciated that the data may be received directly from the other computing device or may be received indirectly via one or more computing devices, such as, for example, one or more servers, relays, routers, network access points, base stations, and/or the like.

As used herein, the term “computer-readable medium” refers to any medium configured to participate in providing information to a processor, including instructions for execution. Such a medium may take many forms, including, but not limited to a non-transitory computer-readable storage medium (for example, non-volatile media, volatile media), and transmission media. Transmission media include, for example, coaxial cables, copper wire, fiber optic cables, and carrier waves that travel through space without wires or cables, such as acoustic waves and electromagnetic waves, including radio, optical, and infrared waves. Signals include man-made transient variations in amplitude, frequency, phase, polarization, or other physical properties transmitted through the transmission media. Examples of non-transitory computer-readable media include a floppy disk, a flexible disk, hard disk, magnetic tape, any other non-transitory magnetic medium, a compact disc read only memory (CD-ROM), compact disc compact disc-rewritable (CD-RW), digital versatile disc (DVD), Blu-Ray, any other non-transitory optical medium, punch cards, paper tape, optical mark sheets, any other physical medium with patterns of holes or other optically recognizable indicia, a random access memory (RAM), a programmable read only memory (PROM), an erasable programmable read only memory (EPROM), a FLASH-EPROM, any other memory chip or cartridge, a carrier wave, or any other non-transitory medium from which a computer can read. The term computer-readable storage medium is used herein to refer to any computer-readable medium except transmission media. However, it will be appreciated that where embodiments are described to use a computer-readable storage medium, other types of computer-readable mediums may be substituted for or used in addition to the computer-readable storage medium in alternative embodiments.

As used herein, the term “circuitry” refers to all of the following: (a) hardware-only circuit implementations (such as implementations in only analog and/or digital circuitry); (b) to combinations of circuits and computer program product(s) comprising software (and/or firmware instructions stored on one or more computer readable memories), such as (as applicable): (i) to a combination of processor(s) or (ii) to portions of processor(s)/software (including digital signal processor(s)), software, and memory(ies) that work together to cause an apparatus, such as a mobile phone or server, to perform various functions described herein); and (c) to circuits, such as, for example, a microprocessor(s) or a portion of a microprocessor(s), that require software or firmware for operation, even if the software or firmware is not physically present. This definition of “circuitry” applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in a server, a cellular network device, other network device, and/or other computing device.

As used herein, the term “computing device” refers to a specialized, centralized device, network, or system, comprising at least a processor and a memory device including computer program code, and configured to provide guidance or direction related to the charge transactions carried out in one or more charging networks.

As used herein, the terms “about,” “substantially,” and “approximately” generally mean plus or minus 10% of the value stated, e.g., about 250 μm would include 225 μm to 275 μm, about 1,000 μm would include 900 μm to 1,100 μm. Any provided value, whether or not it is modified by terms such as “about,” “substantially,” or “approximately,” all refer to and hereby disclose associated values or ranges of values thereabout, as described above.

Heat sink systems can be designed for use within a server farm, server rack, or the like, which can house a plurality of computing devices. These computing devices may include, but are not limited to, servers, processors, graphics processing units (GPUs), or any other heat-generating components commonly found in data center environments.

The short and long-term operability and reliability of these GPUs/CPUs may rely, at least in part, on the temperature being maintained at a sufficiently low level. In some embodiments, a heat sink/heat exchange system can be provided that comprises one or more vapor-permeable membranes. The membrane is constructed from materials with inherent vapor-permeability characteristics, such as nanostructures, microstructures, hydrophobicity/hydrophilicity, surface textures, or the like. The membrane can be configured to allow the passage of vapor molecules while effectively blocking the entry of liquid molecules. Examples of suitable materials include advanced polymers, ceramics, or composite materials designed to withstand the environmental conditions within a server rack.

The vapor-permeable membrane is strategically collocated with the heat-generating components of each computing device. This positioning optimizes the heat transfer process, ensuring that generated heat is efficiently conducted through the membrane and dissipated into the external environment.

In some embodiments, a primary function of the vapor-permeable membrane is to facilitate the transfer of heat from the heat-generating components to the surrounding environment through the process of vapor transport. As heat is generated, liquid molecules undergo a phase change to vapor molecules, and vapor molecules pass through the membrane, carrying thermal energy away from the computing device. This mechanism enhances the overall thermal performance of the server rack.

Described herein are vapor-permeable heat sink systems that offer several advantages over traditional cooling methods, including: enhanced heat dissipation efficiency and/or improved reliability and longevity of computing devices.

In some embodiments, an advanced thermal management system meticulously crafted for server rack environments, addressing the incessant challenges posed by escalating heat generation. The innovative heat sink system integrates vapor-permeable membranes with computing devices within a server rack, marking a paradigm shift in thermal performance optimization.

The relentless drive for increased computational capabilities in data centers has led to a concurrent surge in heat generation, necessitating advanced thermal management solutions. This heat sink system transcends conventional cooling methods, offering a holistic approach that efficiently dissipates heat while concurrently safeguarding computing devices from mechanical stress-related threats. The evolving landscape of high-performance computing environments demands not only enhanced thermal efficiency but also the prevention of downtime, a critical consideration in the context of mission-critical server operations.

Described is a highly sophisticated heat sink system designed to efficiently dissipate heat and protect computing devices from liquid-related incidents, overheating, and/or other issues. The integration of vapor-permeable membranes enables precise thermal management.

In some embodiments, a heat sink system accommodates a diverse array of computing devices commonly found in modern server racks, including servers, central processing units (CPUs), graphics processing units (GPUs), accelerators, and other computing elements.

In some embodiments, strategic placement of the vapor-permeable membrane can help improve thermal transfer efficiency. In many instances, simple collocation of each phase change heat sink/heat rack is a suitable or even an optimal placement approach with regard to latent heat removal efficiency.

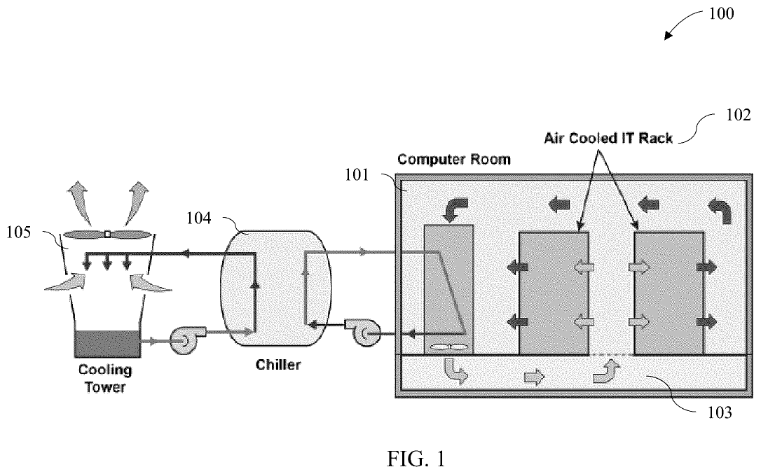

Referring now to FIG. 1, a vapor-permeable membrane-based heat sink system 100 is illustrated which comprises a computer room 101. In the computer room 101 is one or more computing devices (not shown) and one or more heat exchangers 102 comprising one or more vapor-permeable membranes collocated with the one or more computing devices. A heat exchange fluid 103 is configured to absorb waste heat generated by collocated computing devices when in a heat exchanger 102. The heat exchange fluid 103 undergoes a phase change from a liquid phase to a vapor phase due to the resulting temperature change upon absorbing the waste heat. The heat exchanges 102 are configured to separate a vapor volume of the heat exchange fluid 103 from a liquid phase to a vapor phase such that a vapor volume of the heat exchange fluid is configured to be transported through a respective vapor-permeable membrane in each heat exchanger.

The vapor-permeable membrane-based heat sink system 100 represents a pioneering and comprehensive solution to the evolving challenges in server rack thermal management. The intricate integration of vapor-permeable membranes, advanced materials, and innovative coolants provides a holistic and efficient approach to dissipating heat while ensuring the longevity and reliability of critical infrastructure within data centers. The vapor-permeable membrane-based heat sink system 100 disclosed herein stands as a testament to the continuous innovation required to meet the demands of contemporary data center architectures, offering a robust and scalable solution for the evolving landscape of high-performance computing environments. The incorporation of advanced thermal management systems, redundancies, downtime prevention mechanisms, and meticulous coolant mass flow management further solidifies its position as a transformative technology in the field of server rack optimization.

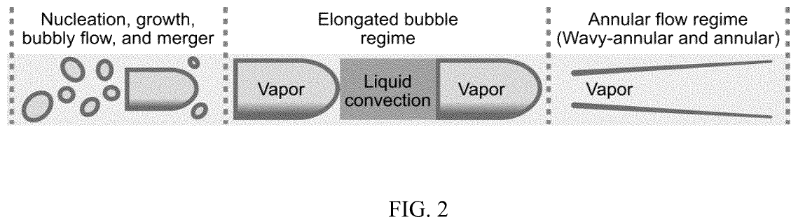

FIG. 2 illustrates several vapor formation regimes, according to several embodiments disclosed herein. Nucleation of microbubbles in the liquid phase heat exchange fluid can occur in the heat exchanger due to heat transfer from a collocated computing device/rack into the liquid phase heat exchange fluid. The microbubbles can grow through bubble combination, and a flow of bubbles can merge into an elongated bubble, according to an elongated bubble regime. Bubbles can be elongated due to several different factors, such as the turbulence caused by bubble flow, can be elongated in the direction of liquid flow due to the flow of liquid phase heat exchange fluid and/or along an inner surface of a heat exchanger. Elongated bubbles of vapor phase heat exchange fluid can be formed via convection of heat through liquid phase heat exchange fluid in the heat exchanger. In some embodiments, in an annular flow regime, two-phase gas-liquid flow can occur when high-gas and low-liquid superficial velocities occur. The flow regime can be annular or wavy-annular. The vapor bubbles can flow in a variety of states or according to a variety of regimes, which can change as gas flow rate or liquid-gas flow rate increases. The regimes can include, e.g., a truly bubbly state, as one or more slugs through channels or apertures, in a churn state, as wispy-annular or wavy-annular, and/or as truly annular.

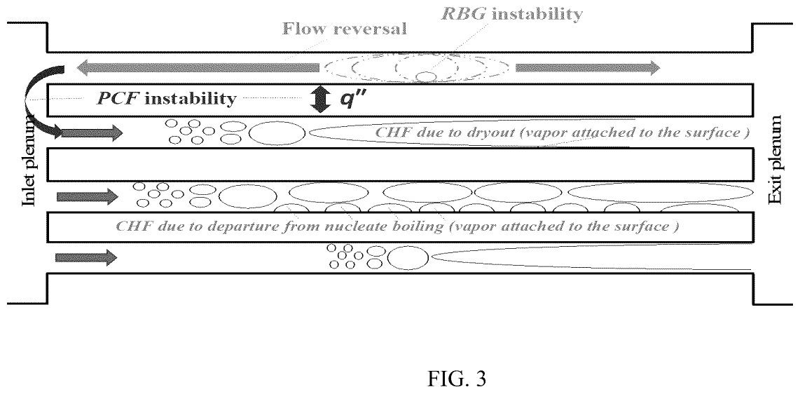

FIG. 3 further illustrates several flow regimes through internal channels of a heat exchanger between an inlet plenum and an exit plenum. The heat convection/absorption by the liquid phase heat exchanger fluid in the channels can be impacted by surface area and material type, channel diameter or height (q″). Flow instability or reversal may occur in some cases due to liquid to vapor pressure drop, incrustation, scaling, biological growth, sediment, fluid flow turbulence, surface adhesion, fluid flow velocity changes, fluid temperature changes, and/or the like. The plane Poiseuille-Couette flow (PCF) of the fluid in the channels, which can be stable to small disturbances for various values of Reynolds number in the absence of vertical throughflow, may become unstable owing to the change in the sign of growth rate depending on the magnitude of throughflow, such as when mixing of vapor and liquid phases of the fluids occur in turbulent stratified flows.

In some embodiments, the critical heat flux (CHF) of liquid phase fluid to vapor phase fluid in a channel can change due to vapor being attached to an inner surface of a channel, due to the departure of nucleated/boiling fluid due to vapor being attached to the surface, or otherwise.

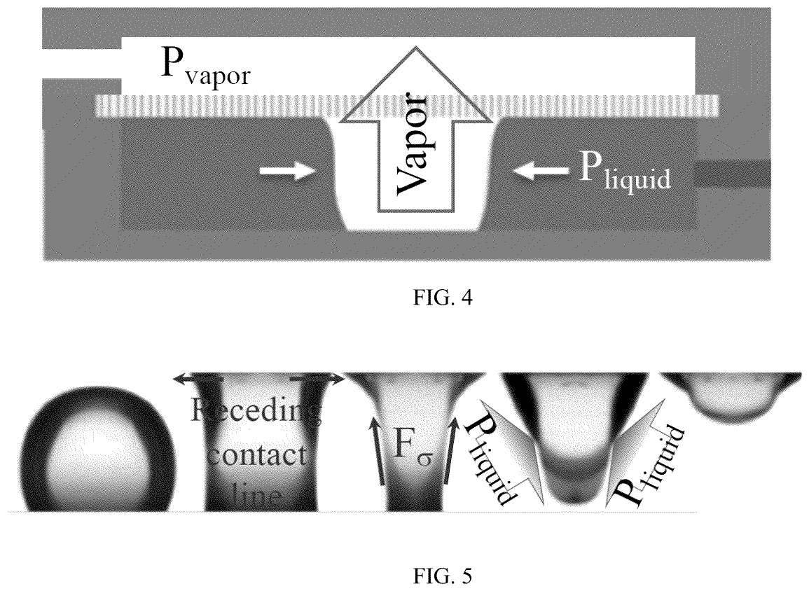

Referring now to FIG. 4, a side-view of a vapor-permeable membrane-based heat sink is shown. According to some embodiments, liquid enters the vapor-permeable membrane-based heat sink at a constant temperature and pressure (P_{liquid}). The vapor-permeable membrane-based heat sink can be separated into a liquid region and a vapor region. The fluid under the membrane is in mixed phase under saturation conditions, while the only vapor exists on top of the membrane, at a pressure slightly less than the two-phase pool below the membrane.

As shown in FIG. 5, the impact of vapor-permeable membrane structure and material use on heat exchange fluid flow through microchannels is shown. As shown, when a bubble forms on the heated surface and expands, it reaches the hydrophobic membrane, and its contact line with the membrane recedes since the membrane is hydrophobic. The receding contact line generates a force on the bubble pulling it away from the heated surface. Hence, the bubble takes a cylindrical shape as opposed to spherical favored by the surface tension forces. As the vapor within the bubble passes through the membrane, it detaches from the heater and discharges from the liquid pool. The higher pressure of the liquid pool relative to that of the vapor space assists with the vapor discharge. This passive bubble departure action results in rapid re-wetting of the heater resulting in an extraordinary high heat transfer performance compare to other two-phase heat sinks. When the pressure reaches a critical value, beyond the membrane liquid breakthrough pressure, liquid penetrates the membrane i.e., leaks through, rendering the operation of the heat sink ineffective.

In some embodiments, discrete fluid accumulation on a free convection wall, such as with the bubble formation in FIG. 5, can have a steep contact line relative to the wall in an adiabatic state. The liquid phase of the heat exchange fluid can have a convexity relative to the vapor-permeable membrane that becomes a receding contact line (more concave) upon phase change to the vapor phase, such that liquid recedes from the contact line and vapor is communicated through the vapor-permeable membrane to be replaced by liquid phase heat exchange fluid thereafter.

In some embodiments, such a heat exchanger can be scaled up to cool a collocated CPU or GPU, such as in a server rack of a server array, e.g., in a data center or the like. In other embodiments, the heat exchanger can be scaled down/miniaturized to be collocated with a single chip or chipset, or a collection of electronic components that are part of a computing device.

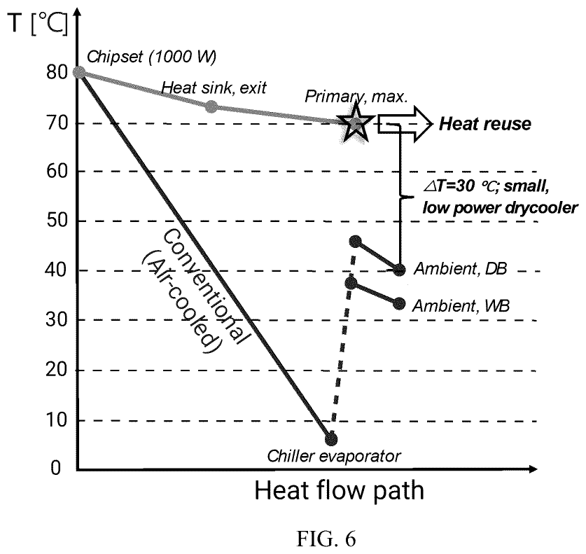

FIG. 6 is a graph illustrating a conventional (air-cooled) heat flow pathway of non-phase-change heat exchangers relative to a phase-change heat exchanger heat flow pathway. As illustrated, the conventional (air-cooled) heat flow pathway starts at a chipset (e.g., a 1,000 W chipset in, e.g., a computing device/server/server rack/server array) that emits waste heat that is absorbed by the conventional heat exchange fluid, raising the temperature to, e.g., about 80° C. To recycle the conventional heat exchange fluid, a conventional air-cooled chiller system is used to reduce the temperature of the conventional heat exchange fluid sufficiently such that the conventional heat exchange fluid can be used again for heat exchange with the chipset. However, since the conventional heat sinks and single-phase fluid do not establish a high heat transfer coefficient similar to what the membrane-based heat sink does, a large, costly, and energy inefficient conventional chiller and associated system is required to properly discharge the chips heat to the ambient environment.

By using a heat exchange system that includes a vapor-permeable membrane, heat exchange fluid can be used at different rates by different portions of the heat exchange system or by different heat exchangers collocated at the different portions of the chip/chipset, computing device, rack, server array, etc. The differing use is controlled by vapor generation, which is based on heat emitted, such that a mass flow controller is not needed to control how much liquid phase heat exchange fluid is communicated to which portion of a collocated computing device/array. Instead, the vapor is quickly communicated through the vapor-permeable membrane, leaving a volume in the heat exchanger to be filled by liquid phase heat exchanger fluid from the upstream supply/reservoir. As long as a somewhat consistent pressure of liquid phase heat exchange fluid is maintained in the system, the upstream supply will replace demand across the various portions of the chip/chipset, computing device, rack, or array based upon heat generation. As such, liquid phase heat exchange fluid supply to each of the heat exchanger(s) will change over time based on changes in vapor phase heat exchange fluid generation in each of the heat exchanger(s) collocated with the chip/chipset, computing device, rack, or array being served by the heat exchanger(s).

Conversely, systems, devices, methods, and approaches described herein can absorb a much larger amount of waste heat from the chipset, which is put to work due to the enthalpy (latent heat) of vaporization (ΔHᵥₐₚ) of the phase-changing heat exchange fluid. The enthalpy of waste heat from the chipset (at a given pressure) is sufficient to transform at least a portion of the heat exchange fluid from the liquid phase to the vapor phase, thereby storing that enthalpy of waste heat as the vapor state of the heat exchange fluid. However, vaporized heat exchange fluid is, typically, low quality/low value vapor from a cross-process-use or ‘work’ potential perspective. Said otherwise, the hot heat exchange fluid in the vapor phase is typically not of sufficient quality to, e.g., turn a turbine. Vapor quality often refers, at least in part, to the mass fraction in a saturated mixture that is vapor (e.g., at a given partial pressure). From a thermodynamics perspective, a fully saturated vapor has a vapor quality of 100%, while a saturated liquid has a vapor quality of zero.

In some instances, it may be helpful to increase the vapor quality of the hot heat exchange fluid in the vapor phase. Higher heat sink vapor quality reduces the flow rate required to remove heat from the chips. A lower flow rate reduces the size of plumbing as well. Also, 100% vapor quality, as opposed to a liquid-vapor mixture, simplifies the design of the system condenser and reduces its size, enabling integration with the server rack. In the present disclosure, the use of a vapor-permeable membrane is described for separating vapor-phase heat exchange fluid from liquid-phase heat exchange fluid. There are several benefits of doing such a separation, whether as a batchwise process, semi-continuously, or continuously. For example, by removing only the vapor-phase heat exchange fluid from an admixture of liquid-phase heat exchange fluid and vapor-phase heat exchange fluid, there is no incidental, unwanted passthrough of liquid-phase heat exchange fluid through the heat exchanger/vapor-permeable membrane, meaning that the rate of replenishment of the liquid-phase heat exchange fluid to the heat exchanger is reduced/minimized.

Also, by allowing communication of only vapor-phase heat exchange fluid through a vapor permeable membrane, the concentration and fluidic pressure or force of the liquid-phase heat exchange fluid remaining on the other side (e.g., upstream side) of the vapor-permeable membrane may stay the same or substantially the same over time. This can be helpful because, in phase change heat exchange processes, oftentimes an increasing concentration/volume of vapor-phase heat exchange fluid in or above the remaining liquid-phase heat exchange fluid in a closed space will reduce the rate of phase change of the remaining liquid-phase heat exchange fluid in that closed space. In some embodiments, the vapor-phase heat exchange fluid is condensed in a condenser unit (e.g., CDU) within the rack. Hence, the system pressure may be dictated or controlled by the operating conditions/settings of the condenser unit in some embodiments. If, for example, the vapor-phase heat exchange fluid in the condenser unit is sufficiently cooled (e.g., using a data center primary loop or the like), the system pressure may remain constant or substantially constant over time. In some embodiments, the condenser unit's primary loop coolant, which may be single-phase water for example, directly impacts the condenser pressure.

Further, in phase-change heat exchanging systems, a rate of phase change of a given volume of liquid-phase heat exchange fluid may affect or even control how rapidly/efficiently the enthalpy of waste heat is exchanged between a chipset and the phase-change heat exchanger. In some embodiments, since the components of the phase-change heat exchange system have a relatively larger thermal mass, the rate of phase-change is low and typically (e.g., always or nearly always) within thermodynamic equilibrium conditions. As such, by allowing vapor-phase heat exchange fluid to escape through the vapor-permeable membrane while disallowing communication of the liquid-phase heat exchange fluid through the vapor-permeable membrane such that the concentration/volume of vapor-phase heat exchange fluid in/above the liquid-phase heat exchange fluid does not increase appreciably over time, the rate of heat exchange can be increased relative to a scenario in which vapor-phase heat exchange fluid is removed from the liquid-phase heat exchange fluid less effectively/quickly. In some embodiments, the vapor-phase heat exchange fluid can be continuously condensed in the condenser unit.

During recycling of the vapor-phase heat exchange fluid, as the temperature of the vapor-phase heat exchange fluid drops to the boiling point of the liquid-phase heat exchange fluid, the vapor-phase heat exchange fluid condenses. Due to the phase change of the heat exchange fluid back from a vapor-phase heat exchange fluid to a liquid-phase heat exchange fluid and an associated enthalpy of condensation, the phase change of the vapor-phase heat exchange fluid back to a liquid-phase heat exchange fluid further cools the heat exchange fluid.

Conversely, conventional heat sink/heat exchange systems typically operate using a liquid-liquid exchange approach rather than utilizing the phase change of the heat exchange fluid to aid in heat sink/exchange operation. In many conventional systems, single phase water removes the heat from a heat source and then releases it into a primary loop, such as a process flow, water cycle, a plant heat exchanger, or the like. In the case of server racks/arrays, a sub-system called a coolant distribution system can be used to cool a number of racks and typically have capacity to cool between about 1 MW and about 2 MW, while current racks operate at about 100 kW.

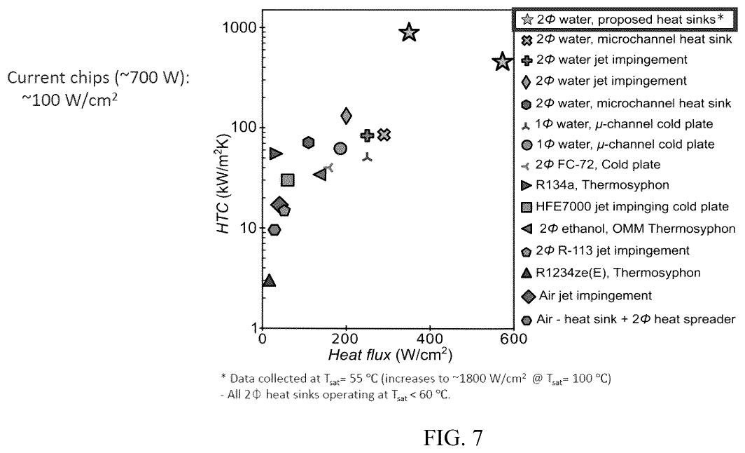

FIG. 7 is a graph of heat transfer coefficient (HTC), in kW/m²K, and heat flux, in W/cm², in accordance with several embodiments in which water is used as the heat exchange fluid. However, a variety of other heat exchange fluids are contemplated and were evaluated, including, e.g., FC-72, R134a, HFE70000, ethanol, R-113, R1234zeI, and air, among others. The heat exchange fluid having the highest HTC and highest heat flux was found to be water, when used in a vapor-permeable membrane heat sink. As such, in many of the embodiments disclosed herein, water is used as the heat exchange fluid. In contrast, other of the contemplated and evaluated heat exchange fluids other than water were found to have a relatively low surface tension and many were found to break through the vapor-permeable membrane in liquid form. For example, conventional micro-scale channel heat sinks (non-membrane heat sinks) were found to exhibit relatively poor performance in terms of cooling/heat sinking capacity. Other heat sink membrane material choices, arrangements, configurations, and embodiments were contemplated and examined which may support other heat exchange fluids other than water. As such, the present disclosure is not limited to embodiments in which water is used as the heat exchange fluid.

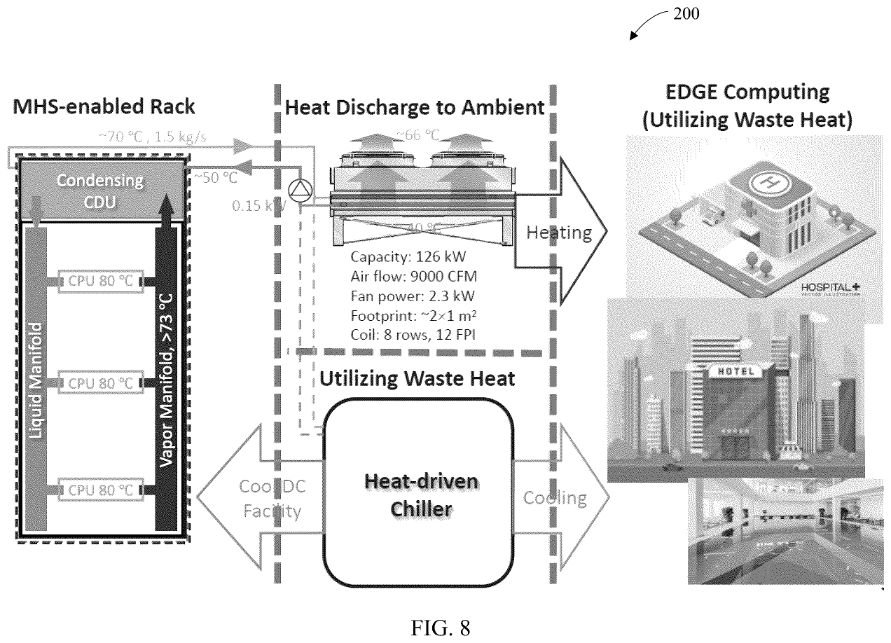

FIG. 8 illustrates a system 200 that can comprise a membrane heat sink (MHS)-enabled server rack, heat exchange system, and edge computing system. In some embodiments, a liquid-heat exchange fluid absorbs heat from a collocated chipset/rack, is routed to a heat-driven chiller where waste heat from the vapor-heat exchange fluid is utilized to drive cooling of the MHS-enabled server rack. In some embodiments, heat can be discharged from the system 200 to the ambient air or utilized in system heating in a nearby or collocated facility or factory, for example.

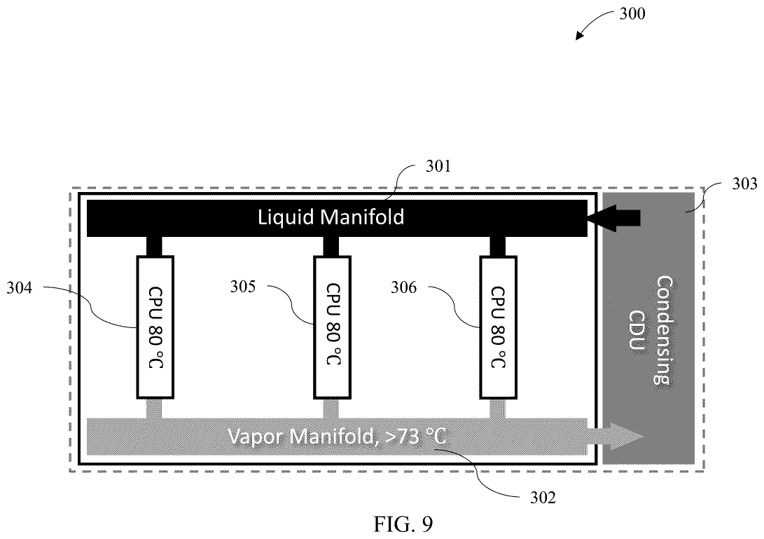

In some embodiments, the system 200 can comprise an MHS-enabled rack comprising a central liquid manifold located upstream of each of a plurality of different CPUs, each independently emitting heat. One or more heat exchangers comprising a vapor-permeable membrane can be collocated with each of the CPUs. As liquid phase heat exchange fluid in each heat exchanger absorbs heat from the collocated CPU(s), it turns to vapor and the vapor is communicated through the vapor-permeable membrane to a vapor manifold. According to one embodiment, the CPUs may operate at a temperature of about 80° C., and the vapor phase heat exchange fluid formed in the heat exchangers and communicated into the vapor manifold may be at a temperature of about 73° C. The vapor can then be condensed in a condenser unit (CDU), e.g., an in-rack CDU, and reused as liquid phase heat exchange liquid supplied to the liquid manifold. Depending on the heat exchange fluid used, the temperature of the vapor phase heat exchange fluid communicated through the vapor-permeable membrane of the heat exchanger(s) may be more or less than about 73° C. Depending on the application, the heat emitted from the CPU(s) or other collocated computing device(s) may be different than in the application shown in FIGS. 9 and/or 10, resulting in a CPU operating temperature that is higher or lower than about 70° C. to about 80° C. Nevertheless, as noted, the rate of liquid phase heat exchange fluid supplied to the liquid manifold can change automatically based on the downstream vapor generation rate, which will change automatically with changes in heat generated during use/operation of the heat source (e.g., chip, chipset, server, rack, array, etc.).

In some embodiments, the system 200 can be or comprise a phase change heat exchange system. In some embodiments, the system 200 can include one or more heat exchangers, such as a plurality of heat exchangers. In some embodiments, the system 200 can be or comprise of a self-balancing flow system in which the flow of liquid-heat exchange fluid through the heat exchange system is independent of CPU/GPU heat dissipation. In some embodiments, a plurality of heat exchangers can be collocated with servers/server racks of a server array/chipset. In some instances, the flow of liquid-heat exchange fluid through the heat exchange system can be driven by gravity or a pump. In some embodiments, the liquid-heat exchange fluid can flow from a liquid-heat exchange fluid reservoir to each of the plurality of heat exchangers, whether in parallel or in series. Oftentimes, a mass flow control system is used to balance flow of liquid-heat exchange fluid between the various heat exchangers/heat sinks. This can be important at least because some CPUs/GPUs will generate more waste heat than others such that the rate of phase change of the liquid-heat exchange fluid to the vapor-heat exchange fluid can vary between heat exchangers collocated with the different CPUs/GPUs, while the fluid delivery rate to each heat exchanger will not vary, meaning that the liquid-side pressure drop due to changes in operations of the heat source(s) is negligible.

FIG. 9 illustrates an MHS-enabled rack 300, in accordance with several example embodiments of the present disclosure. In some embodiments, the MHS-enabled rack 300 can comprise a central liquid manifold 301 that is configured to receive and retain a heat exchange fluid in liquid form. In some embodiments, the MHS-enabled rack 300 can further comprise a vapor manifold 302 configured to receive heat exchange fluid in vapor form from the central liquid manifold 301. In some embodiments, the MHS-enabled rack 300 can further comprise a condensing unit (CDU) 303 configured to receive the heat exchange fluid in vapor form from the vapor manifold 302 and perform or cause a phase change of the heat exchange fluid in vapor form to the heat exchange fluid in liquid form. The CDU 303 can be further configured to return the heat exchange fluid in liquid form to the central liquid manifold 301 of the MHS-enabled rack 300.

In some embodiments, the MHS-enabled rack 300 can be configured to remove heat emitted from a plurality of heat sources, such as a plurality of CPUs 304, 305, 306. In some embodiments, the plurality of CPUs 304, 305, 306 can be positioned about or nearby the central liquid manifold 301 such that the heat emitted from the plurality of CPUs 304, 305, 306 is communicated into the central liquid manifold 301 and absorbed by the heat exchange fluid in liquid form retained in the central liquid manifold 301 of the MHS-enabled rack 300. Absorption by the heat exchange fluid in liquid form retained in the central liquid manifold 301 of the MHS-enabled rack 300 causes at least a portion of the heat exchange fluid in liquid form to undergo a phase change from the liquid form to the vapor form.

In some embodiments, the MHS-enabled rack 300 can further comprise one or more vapor-permeable membranes (not shown) that is/are positioned between the central liquid manifold 301 and the vapor manifold 302 of the MHS-enabled rack 300. In some embodiments, the one or more vapor-permeable membranes are configured to allow communication therethrough of the heat exchange fluid in vapor form while disallowing communication therethrough of the heat exchange fluid in liquid form, such that any heat exchange fluid in liquid form in the central liquid manifold 301 that undergoes the phase change to form the heat exchange fluid in vapor phase can be communicated, in the vapor phase, through the one or more vapor-permeable membranes and into the vapor manifold 302, while any and all remaining heat exchange fluid in liquid form remains contained within the central liquid manifold 301.

In some embodiments, the central liquid manifold 301 can be located upstream of each of the plurality of CPUs 304, 305, 306, each of which are independently emitting heat. In some embodiments, the MHS-enabled rack 300 can further comprise one or more heat exchangers (not shown) comprising at least one of the one or more vapor-permeable membranes. The one or more heat exchangers can be collocated with each of the plurality of CPUs 304, 305, 306. As liquid phase heat exchange fluid in each heat exchanger absorbs heat from one or more of the plurality of CPU(s) 304, 305, 306 sufficiently collocated therewith, the liquid phase heat exchange fluid turns to vapor and the vapor is selectively communicated through the vapor-permeable membrane to the vapor manifold 302. According to some embodiments, the plurality of CPUs 304, 305, 306 may operate at a temperature of about 80° C., and the vapor phase heat exchange fluid formed in the heat exchangers and communicated into the vapor manifold 302 may be at a temperature of about 73° C. The vapor phase heat exchange fluid, once it is selectively communicated through the one or more vapor-permeable membranes and into the vapor manifold 302, can be communicated out of the vapor manifold 302 (e.g., based upon a pressure increase caused by continued ingress of additional vapor phase heat exchange fluid into the vapor manifold 302) and into the CDU 303, and the CDU 303 can condense the vapor phase heat exchange fluid to cause it to undergo another phase change back to the liquid phase heat exchange fluid, which can be reused in the MHS-enabled rack 300 as liquid phase heat exchange liquid supplied to the central liquid manifold 301. Depending on the heat exchange fluid used, the temperature of the vapor phase heat exchange fluid communicated through the vapor-permeable membrane of the heat exchanger(s) may be at a temperature of more or less than about 73° C.

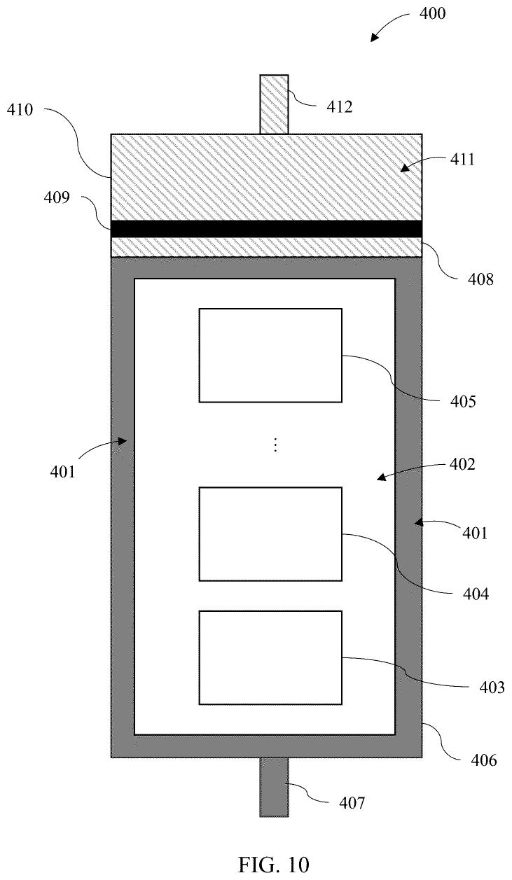

Referring now to FIG. 10, an example of an alternative configuration for a membrane heat sink 400 is illustrated which comprises a liquid region 401 defined at least partially about a heat source region 402. In some embodiments, the heat source region 402 can be dimensioned and configured to retain therewithin a plurality of heat sources 403, 404, 405, such as computing devices, servers, server sets, server racks, chips, computers, CPUs, GPUs, and/or the like.

In some embodiments, the liquid region 401 can be defined as a first portion of an inner volume within a first housing portion 406. The first housing portion 406 can comprise or define a liquid inlet 407 configured to communicate a liquid phase heat exchange fluid into the liquid region 401 of the membrane heat sink 400. The liquid phase heat exchange fluid can be retained within the liquid region 401 of the membrane heat sink 400. During retention of the liquid phase heat exchange fluid within the liquid region 401 of the membrane heat sink 400, heat emitted by the plurality of heat sources 403, 404, 405 may be communicated through a portion of the heat source region 402, through the first housing portion 406, and into the liquid phase heat exchange fluid in the liquid region 401, causing at least a portion of the liquid phase heat exchange fluid to undergo a phase change to form a vapor phase heat exchange fluid. In some embodiments, the inner volume of the first housing portion 406 can, at least temporarily, comprise a pre-flux vapor region 408. The pre-flux vapor region 408 can retain the vapor phase heat exchange fluid formed in response to the liquid phase heat exchange fluid receiving the heat emitted from the plurality of heat sources 403, 404, 405.

The membrane heat sink 400 further comprises a vapor-permeable membrane 409 dimensioned and configured to allow communication therethrough of the vapor phase heat exchange fluid while disallowing communication therethrough of the liquid phase heat exchange fluid.

In some embodiments, the vapor-permeable membrane 409 is coupled to the first housing portion 406 and configured to fluidically seal the liquid region 401. The membrane heat sink 400 further comprises a second housing portion 410 having an inner volume that defines a vapor region 411 of the membrane heat sink 400. While the first housing portion 406 is fluidically scaled against a bottom surface of the vapor-permeable membrane 409, the second housing portion 410 is fluidically sealed against a top surface (opposite the first housing portion 406) of the vapor-permeable membrane 409. The second housing portion 410 can further comprise or define a vapor outlet 412.

In some embodiments, the vapor phase heat exchange fluid in the pre-flux vapor region 408 can be freely or mostly freely communicated through the vapor-permeable membrane 409 into the vapor region 411. In some embodiments, the vapor phase heat exchange fluid in the vapor region 411 can be freely or mostly freely communicated through the vapor outlet 412. Therefore, as an amount of heat emitted by at least one or more of the plurality of heat sources 403, 404, 405 changes, an amount of heat absorbed by the liquid phase heat exchange fluid in the liquid region 401 can correspondingly change, and an amount of the liquid phase heat exchange fluid undergoing a phase change to the vapor phase heat exchange fluid can likewise correspondingly change. The vapor phase heat exchange fluid that is formed in the liquid region 401 can quickly accumulate in the pre-flux vapor region 408 and can freely or mostly freely be communicated through the vapor-permeable membrane 409 and into the vapor region 411 of the membrane heat sink 400. Based on the flux or communication of the vapor phase heat exchange fluid from the pre-flux vapor region 408, through the vapor-permeable membrane 409, and into the vapor region 411, a replenishing supply of the liquid phase heat exchange fluid can be drawn in/communicated through the liquid inlet 407 and into the liquid region 401 of the membrane heat sink. Therefore, the rate of communication of the replenishing supply of liquid phase heat exchange fluid into the liquid region 401 of the membrane heat sink 400 can change correspondingly (be controlled by) the rate of phase change of the liquid phase heat exchange fluid into the vapor phase heat exchange fluid, which changes correspondingly based upon changes in the heat emitted from the plurality of heat sources 403, 404, 405 in the heat generation region 402. In this way, overt or active management of mass transport/volumetric transport of liquid phase heat exchange fluid to and/or into the membrane heat sink 400 is not needed because the communication of liquid phase heat exchange fluid to and/or into the membrane heat sink 400 is demand-responsive (e.g., based directly on heat emitted by the heat sources 403, 404, 405). This may allow the membrane heat sink 400, and systems/devices comprising the same, to simply provide a minimal fluidic pressure of the replenishing supply of liquid phase heat exchange fluid against the liquid phase heat exchange fluid retained within the liquid region 401 of the membrane heat sink 400, without having to use excessive fluidic pressure, without requiring mass/fluidic transport measurements/sensors, without requiring fine actuation of actuatable valves or other flow control devices, and without requiring a complex piping and instrumentation (P&ID) arrangement incorporating feedback loops and control loops based on sensor inputs and predetermined or dynamic control ranges, or the like. Generally speaking, a system that requires less pumping, less mass/fluid transport monitoring and control, and a less complex P&ID/less feedback loops or otherwise reduced automation and oversight is a cheaper and more reliable system.

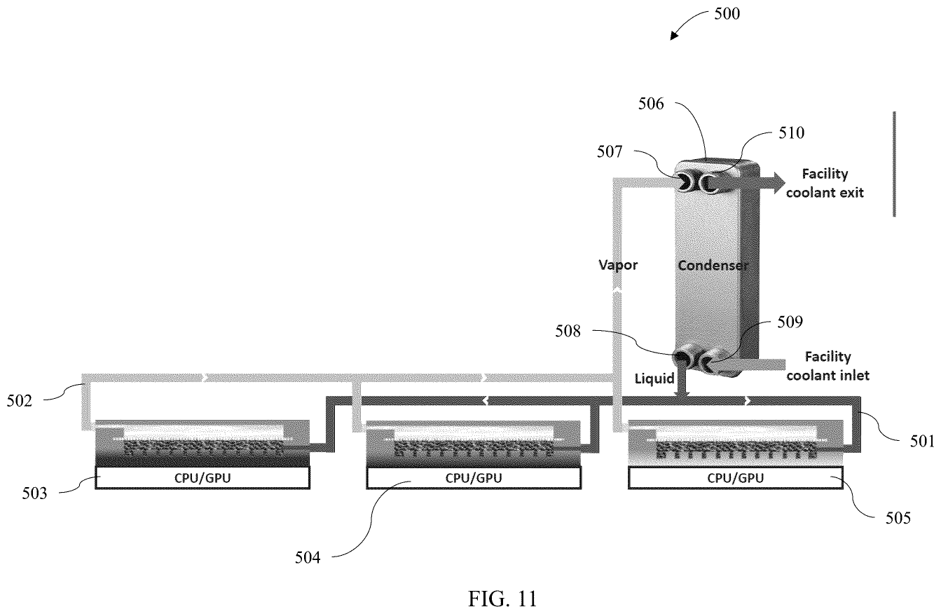

Referring now to FIG. 11, a phase change heat exchange system 500 is illustrated that comprises a liquid manifold 501 and a vapor manifold 502. The phase change heat exchange system 500 can comprise or be configured to be collocated with one or more heat sources, such as CPUs 503, 504, 505. In some embodiments, the phase change heat exchange system 500 can further comprise a condensing unit 506 configured to receive vapor phase heat exchange fluid from the vapor manifold 502. The condensing unit 506 can comprise a vapor inlet 507 configured to receive vapor phase heat exchange fluid from the vapor manifold 502. The condensing unit 506 can further comprise a liquid outlet 508. In some embodiments, the condensing unit 506 further comprises a coolant inlet 509 and a coolant outlet 510. Coolant can be communicated through the condensing unit 506 and exchange heat with the vapor phase heat exchange fluid, causing a second phase change of the heat exchange fluid back to the liquid phase heat exchange fluid.

In some embodiments, the phase change heat exchange system 500 can include one or more heat exchangers, such as a plurality of heat exchangers. In some embodiments, a self-balancing flow system can be provided in which the flow of liquid-heat exchange fluid through the heat exchange system is independent of CPU/GPU heat dissipation. In some embodiments, a plurality of heat exchangers can be collocated with servers/server racks of a server array/chipset. In some instances, the flow of liquid-heat exchange fluid through the heat exchange system can be driven by gravity or a pump. In some embodiments, the liquid-heat exchange fluid can flow from a liquid-heat exchange fluid reservoir to each of the plurality of heat exchangers, whether in parallel or in series. Oftentimes, a mass flow control system is used to balance flow of liquid-heat exchange fluid between the various heat exchangers/heat sinks. This can be important at least because some CPUs/GPUs will generate more waste heat than others such that the rate of phase change of the liquid-heat exchange fluid to the vapor-heat exchange fluid can vary between heat exchangers collocated with the different CPUs/GPUs, and some heat exchangers are located further from the liquid-heat exchange fluid reservoir such that the fluid flow rate will vary between the different collocated heat exchangers.

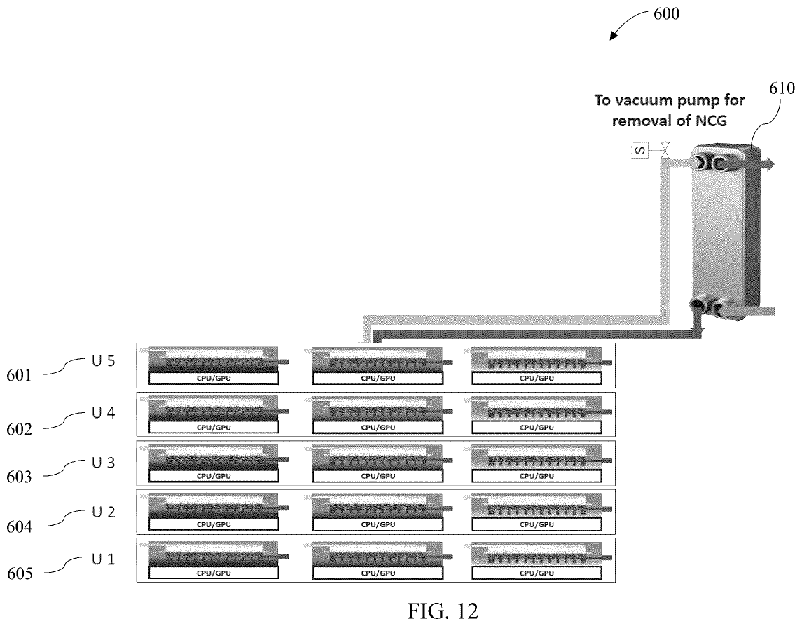

Referring now to FIG. 12, a system 600 is illustrated that can be or comprise a phase change heat exchange system. In some embodiments, the system 600 can include one or more heat exchangers, such as a plurality of heat exchangers 601, 602, 603. In some embodiments, a self-balancing flow system can be provided in which the flow of liquid heat exchange fluid through the heat exchange system is independent of CPU/GPU heat dissipation. In some embodiments, the plurality of heat exchangers 601, 602, 603 can be collocated with one or more of a plurality of CPUs/GPUs 604, 605, 606. In some instances, the flow of liquid heat exchange fluid through the heat exchange system can be driven by gravity or a pump. In some embodiments, the liquid heat exchange fluid can flow from a liquid heat exchange fluid reservoir to each of the plurality of heat exchangers, whether in parallel or in series. Oftentimes, a mass flow control system is used to balance flow of liquid heat exchange fluid between the various heat exchangers/heat sinks. This can be important at least because, at any one time, one or more of the plurality of CPUs/GPUs 604, 605, 606 will generate more waste heat than one or more remaining CPUs/GPUs from among the plurality of CPUs/GPUs 604, 605, 606. This may mean that the rate of phase change of the liquid heat exchange fluid to the vapor heat exchange fluid can vary between respective heat exchangers of the plurality of heat exchangers 601, 602, 603 collocated with the different CPUs/GPUs of the plurality of CPUs/GPUs 604, 605, 606. In some embodiments, one or more of the plurality of heat exchangers 601, 602, 603 are located further from the liquid heat exchange fluid reservoir such that the fluid flow rate will vary between the different collocated heat exchangers of the plurality of heat exchangers 601, 602, 603.

In some embodiments, the system 600 can comprise a condenser 607 configured to perform a second phase change to return the vapor heat exchange fluid to the liquid heat exchange fluid. In some embodiments, the condenser 607 can comprise a vapor inlet 608 by which the condenser 607 receives vapor heat exchange fluid from the plurality of heat exchangers 601, 602, 603. The condenser 607 can further comprise a liquid outlet 609 by which the liquid heat exchange fluid is communicated out of the condenser 607 and back to the plurality of heat exchangers 601, 602, 603. The condenser 607 can be configured to exchange heat from the vapor heat exchange fluid with a coolant or other such material that is communicated into and out of the condenser 607 via, respectively, a facility coolant inlet 610 and a facility coolant exit 611.

In some embodiments, a single CPU/GPU (e.g., 604) can be served by a single heat exchanger (e.g., 601) or a plurality of heat exchangers. In some embodiments, each CPU/GPU 604, 605, 606 can be served (cooled) by multiple heat exchangers 601, 602, 603. Different arrangements of the plurality of CPUs/GPUs 604, 605, 606 may be used to accommodate different numbers of the plurality of heat exchangers 601, 602, 603 serving each or a portion of the plurality of heat exchangers 601, 602, 603. For example, heat exchangers 601, 602, 603 can be collocated vertically or horizontally nearby a set or rack of CPUs/GPUs 604, 605, 606. In some embodiments, a heat exchanger (e.g., 601) may singlehandedly have sufficient heat exchange (cooling) capacity to maintain multiple CPUs/GPUs (e.g., 604, 605) within a range of suitable operating temperature simultaneously. In such a circumstance, the single heat exchanger (e.g., 601) can be collocated between the CPUs/GPUs 604, 605. In certain embodiments, such as when server uptime is a key priority for the operation of the system 600, e.g., when serving a server array/data center, redundant heat exchangers (e.g., 601, 602) can be collocated with each of the CPUs/GPUs (e.g., 604) such that the heat exchanger system 600 represents an excess cooling capacity relative to the minimum or maximum cooling needs calculated for the server rack/array/data center.

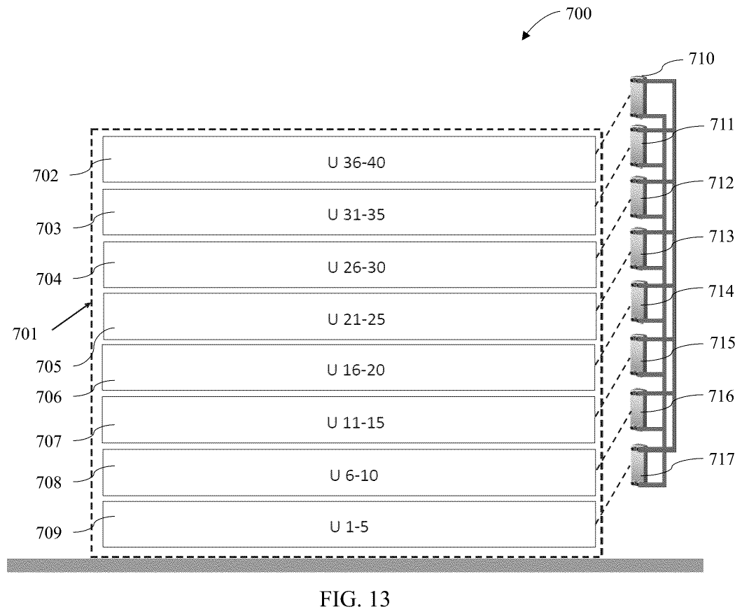

Referring now to FIG. 13, a system 700 is illustrated that comprises a server rack 701 comprising a plurality of server sets 702-709. The plurality of server sets 702-709 can be arranged vertically, horizontally, or in any other configuration within the sever rack 701. As illustrated in FIG. 13, the plurality of server sets 704-709 are marked, respectively, as server sets U 1-5, U 6-10, . . . , U 36-40.

In some embodiments, the system 700 further comprises a plurality of heat sinks 710-717. The plurality of heat sinks 710-717 can be located or positioned nearby or collocated with the plurality of server sets 702-709. In some embodiments, a single server set (e.g., 709) from among the plurality of server sets 702-709 in the server rack 701 can be served (cooled) by a single heat sink from among the plurality of heat sinks 710-717. In some embodiments, each CPU/GPU in a server set can be served (cooled) by one or more heat exchangers. The vertical arrangement/configuration of the plurality server sets 702-709 in the server rack 701 illustrated in FIG. 13 may be useful because the plurality of heat sinks 710-717 can be collocated vertically beside the vertically arranged plurality of server sets 702-709 in the server rack 701 or collocated horizontally beside each horizontally arranged server set from among the plurality of server sets 702-709 in the server rack 701, and/or can be arranged in any other suitable manner. In some instances, a heat sink or heat exchanger may have sufficient heat exchange (cooling) capacity to maintain one or more CPUs/GPUs in more than one server set (e.g., U 1-5 and U 6-10, or 709 and 708) within a range of suitable operating temperature simultaneously. In such a circumstance, a single heat sink (e.g., 717) can be collocated between two server sets (e.g., between 709 and 708) of the server rack 701. In certain embodiments, such as when server uptime is a key priority for the operation of the server array/data center, redundant heat sinks (e.g., 716 and 717) can be collocated with a single one of the server sets (e.g., 709) in a server rack 701. In such an arrangement or configuration, the system 700 may have an excess cooling capacity relative to the cooling needs calculated for the particular server set (e.g., 709) in the server rack 701, which can be helpful in circumstances in which the successful, ongoing operation (e.g., uptime reliability) of the particular server set (e.g., 709) is critical.

The heat exchangers and server array in the systems 500, 600, and 700, as illustrated in FIGS. 11-13, may therefore achieve/experience more ‘uptime’, which is calculated as the percentage of annual operational hours for which a server rack, CPU/GPU, and/or the entire server rack are already pending. Said otherwise, since only portions of the array of CPUs/GPUs are actually grouped into each server rack of the plurality of server racks, a single server rack of CPUs/GPUs can be removed from operation while the server rack/phase change system is evaluated and repaired, without the entire array of CPUs/GPUs being offline during the period of time required for evaluation and repair.

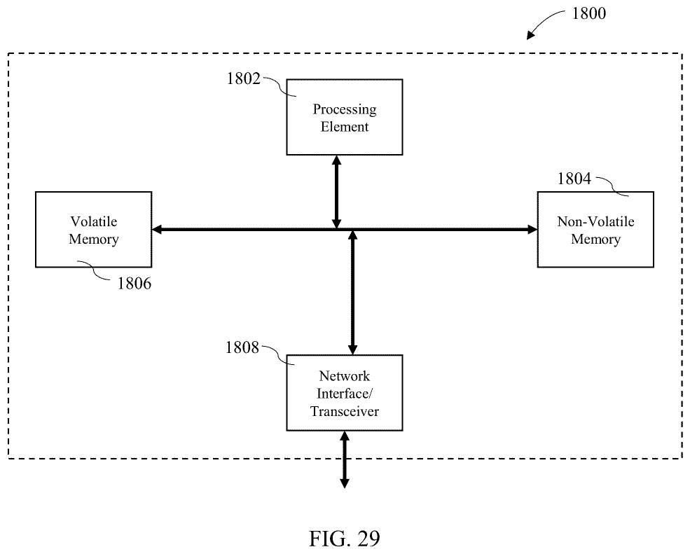

In some embodiments, the communication of liquid-heat exchange fluid to/through the plurality of different heat exchangers can be monitored and/or controlled by a computing device, which may comprise or be comprised in a mass flow control system. In other embodiments, the impermeability of the vapor-permeable membranes in the heat exchanger-fluid exchange approach allows for a constant or substantially constant pressure and/or flow rate of the liquid-heat exchange fluid to be maintained without cycling pumps and motors on and off, without having to actuate valves open and closed repeatedly, and without requiring that the rate of outflow of vapor-heat exchange fluid from each heat exchange fluid be controlled. Examples of such computing devices and entities are described below with regard, e.g., to FIG. 29.

Membrane heat sinks and membrane heat exchangers, such as those illustrated in the systems 200, 300, 400, 500, 600, 700, described above reflect several possible scales for use of such membrane heat sinks, such as when a heat exchanger/heat sink is scaled up to cool a collocated CPU or GPU, such as in a server rack of a server array, e.g., in a data center or the like. In other embodiments, the heat exchanger can be scaled down/miniaturized to be collocated with a single chip or chipset, or a collection of electronic components that are part of a computing device.

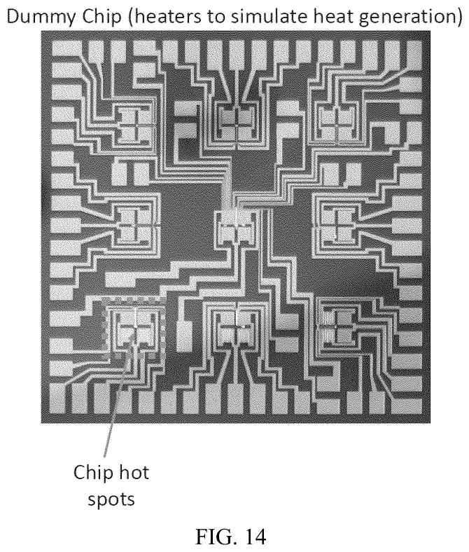

FIG. 14, for example, illustrates a dummy chip (also referred to herein as an integrated circuit, a microchip, a chip, and/or the like) comprising heaters configured to simulate chip hot spots in particular portions of the chip. The dummy chip illustrated is a silicon-based chip with multiple electrical components interconnected by copper leads created by removal of portions of a protective surface coating to expose a copper laminate layer beneath. The dummy chip illustrated includes a resistor (illustrated in the dotted box labeled “Chip hot spots”) that, upon receiving electrical charge, generates and emits thermal energy from the resistor. This resistor is used to illustrate a hot spot on the chip that, spatially, requires relatively more heat sink resources/capacity than other portions of the chip.

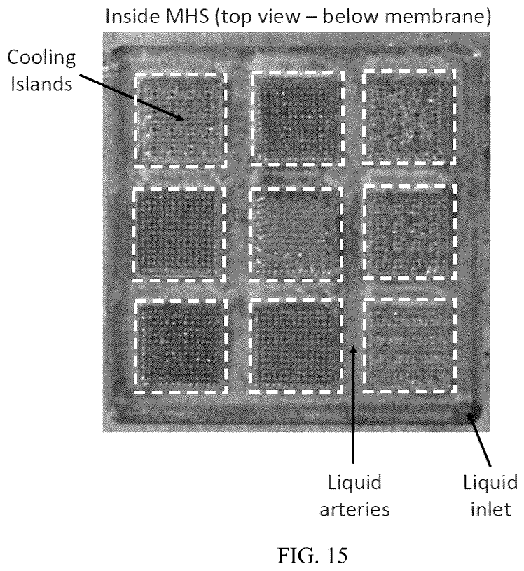

FIG. 15 is a heat map of an electrical component (such as that illustrated in FIG. 14) that emits more thermal energy/heat in some portions than in others. By using a heat exchange system that includes a vapor-permeable membrane, heat exchange fluid can be used at different rates by different portions of the heat exchange system or by different heat exchangers collocated at the different portions of the chip/chipset, computing device, rack, server array, etc. The differing use is controlled by vapor generation, which is based on heat emitted, such that a mass flow controller is not needed to control how much liquid phase heat exchange fluid is communicated to which portion of a collocated computing device/array. Instead, the vapor is quickly communicated through the vapor-permeable membrane, leaving a volume in the heat exchanger to be filled by liquid phase heat exchanger fluid from the upstream supply/reservoir. As long as a somewhat consistent pressure of liquid phase heat exchange fluid is maintained in the system, the upstream supply will replace demand across the various portions of the chip/chipset, computing device, rack, or array based upon heat generation. As such, liquid phase heat exchange fluid supply to each of the heat exchanger(s) will change over time based on changes in vapor phase heat exchange fluid generation in each of the heat exchanger(s) collocated with the chip/chipset, computing device, rack, or array being served by the heat exchanger(s).

Several issues and considerations arise, however, when miniaturizing or scaling down such a heat sink/heat exchanger for use at the scale of a single chipset or chip, for example. The difference between temperatures at different portions of a chip can be very different, meaning that a higher granularity of discrete cooling locations/regions may be needed. In some instances, the miniaturization of a heat sink leads channels/conduits to become microfluidic in scale, which can change the fluid hydrodynamics experienced within the heat sink. In some instances, the miniaturization of the heat sink requires the use of relatively thin components, meaning that the stress-strain experienced due to thermal expansion/contraction during use can make certain components less mechanically durable. Additionally, in terms of improving the survivability and lifespan of the heat source (e.g., silicone chip) collocated with the heat sink, the coefficient of thermal expansion (CTE) of the material used at the contacting surface with the heat source should be aligned with the CTE of the heat source such that as the heat source and heat sink are heated or cooled during the course of operation/use, the CTE differential between the heat source and the heat sink is minimized because a sufficiently high CTE differential at that interface was found to lead to deformation, delamination, and/or failure of the heat source and/or heat sink. However, the use of some materials for a contact surface between a heat sink and heat source may be undesirable for use, either in addition to a misalignment of CTE between the materials or despite a relatively good alignment of CTE between the materials, based upon, e.g., undesirable chemical or physical reactions of the material when exposed to the heat exchange fluid (e.g., water), undesirable costs or availability of the material, and/or an undesirably low mechanical durability, among other potential issues.

For example, the heat sink could be formed from a mechanically durable material such as titanium, but such a heat sink is prohibitively expensive, and furthermore titanium has a thermal conductivity of only about 10-20 w/K·m which results in a heat sink that performs poorly. Alternatively, at least a portion of the heat sink could be formed from a mechanically durable material such as stainless steel, however the resulting thermal conductivity through the stainless steel portion of the heat sink was found to be about 15 w/K·m, which results in a heat sink that performs poorly. Conversely, the heat sink could be formed from a relatively thermally conductive material, such as aluminum, which has a relatively high thermal conductivity of about 230 w/K·m, however aluminum erodes when exposed to water, which leads to a heat sink that is made from material which will fail over a relatively short period of time. Furthermore, the resulting heat sink would have a critical non-alignment of coefficients of thermal expansion (CTEs) between the heat source (e.g., silicone chip) and the heat sink material (e.g., aluminum), which would mean that any interface at which the heat sink is joined to the heat source would experience differences in thermal expansion, causing delamination or separation of the heat sink from the heat source.

In some embodiments, one or more materials is/are chosen for the contacting surface of the heat sink that can improve match the coefficient of thermal expansion of the chip or other heat source collocated therewith. In some embodiments, the one or more materials is/are chosen for the contacting surface of the heat sink that has/have a sufficiently high mechanical durability at the scale of a chip/chipset without unnecessarily inhibiting the heat sink capacity/efficiency of the heat sink. Described below are several such materials, devices/systems using such materials, and methods for forming/manufacturing a heat sink using such materials.

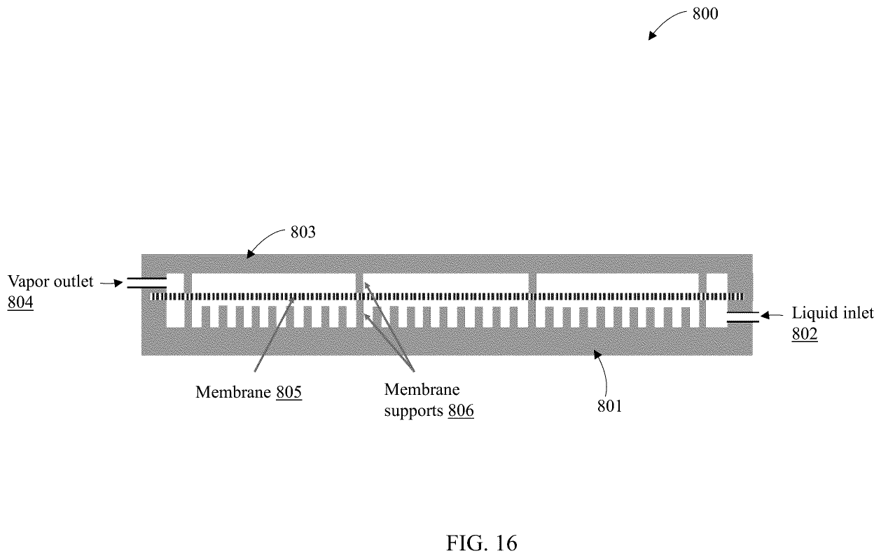

Referring now to FIG. 16, a side-view of a heat sink 800 for a chip assembly is illustrated. The heat sink 800 comprises a bottom portion 801. As viewed from a top-down perspective, the bottom portion 801 can be flat or have a slightly concave or convex form factor. In some embodiments the bottom portion 801 can have a generally planar surface and can comprise one or more raised portions (e.g., walls) formed about an outside edge of the generally planar surface of the bottom portion 801. An inner portion or inner volume of the bottom portion 801 of the heat sink 800 can be defined based at least in part on the generally planar surface and the one or more raised portions formed about the outside edge of the generally planar surface of the bottom portion 801 that stand proud of the generally planar surface in the direction of the top-down perspective. One or more apertures can be formed through a raised portion to form a liquid inlet 802. The liquid inlet 802 can be configured to allow a heat exchange fluid in a liquid phase to be communicated from outside the heat sink 800 to the inner portion or inner volume of the bottom portion 801 of the heat sink 800.

The heat sink 800 illustrated in FIG. 16 further comprises a top portion 803. As viewed from a top-down perspective, the top portion 803, like the bottom portion 801, can have a planar, flat, slightly convex, and/or slight concave form factor. In some embodiments, the top portion 803 can be defined by a generally planar surface and one or more raised portions (e.g., walls) being formed about an outside edge of the generally planar surface of the top portion 803. An inner portion or inner volume of the top portion 803 of the heat sink 800 can be defined based at least in part on the generally planar surface and the one or more raised portions formed about the outside edge of the generally planar surface of the top portion 803 that stand proud of the generally planar surface in a direction that is opposite the direction of the top-down perspective. One or more apertures can be formed through a raised portion to form a vapor outlet 804. The vapor outlet 804 can be configured to allow a heat exchange fluid in a vapor phase to be communicated from the inner portion or inner volume of the top portion 803 of the heat sink 800 to outside the heat sink 800.

The heat sink 800 illustrated in FIG. 16 further comprises a membrane 805 disposed at least partially between the bottom portion 801 of the heat sink 800 and the top portion 803 of the heat sink 800. The membrane 805 is a vapor-permeable membrane that allows for communication of heat exchange fluid in the vapor phase therethrough, while disallowing communication of heat exchange fluid in the liquid phase therethrough. The membrane 805 can be joined to or within part of the bottom portion 801, joined to or within part of the top portion 803, or both.

As illustrated in FIG. 16, for example, a portion of each edge of the membrane 805 is disposed within a groove or recess within the raised circumferential portion of the bottom portion 801 of the heat sink 800 at one or more locations that are above the liquid inlet 802 such that heat exchange fluid in the liquid phase will be retained within the inner portion or the inner volume of the bottom portion 801 that is further defined by an underside/bottom surface of the membrane 305.

Alternatively, a portion of each edge of the membrane 805 could instead be disposed within a groove or recess within the raised circumferential portion of the top portion 803 of the heat sink 800 at one or more locations that are below the vapor outlet 804. In such a configuration, heat exchange fluid in the liquid phase will be retained within the inner portion/volume of the bottom portion 801 that is further defined by the underside/bottom surface of the membrane 805 without being communicated out of the heat sink 800 by way of the vapor outlet 804.

Alternatively, a portion of the edges of the membrane 805 could be disposed between a top surface of the raised portions of the bottom portion 801 and a bottom surface of the raised portions of the top portion 803 and the bottom portion 801 and top portion 803 can be joined/scaled together. In such a configuration, the membrane 805 is fluidically sealed between the liquid inlet 802 and the vapor outlet 804 of the heat sink 800.

In some embodiments, the heat exchange fluid can be communicated through the liquid inlet 802 and into the inner portion/volume of the bottom portion 801 of the heat sink 800 at a hydrodynamic pressure that is sufficient to, whether acutely or chronically over time, deform or damage the membrane 805. As such, in some embodiments, the heat sink 800 can further comprise membrane supports 306 that are configured to disallow or reduce physical/mechanical deformation of the membrane 805 during use of the heat sink 800. Each membrane support 806 may include a single post or fin that spans from the top of the generally planar surface of the bottom portion 801 to the bottom of the generally planar surface of the top portion 803. Alternatively, each membrane support 806 may include a bottom portion of a post or fin that extends from the top of the generally planar surface of the bottom portion 801 to an underside of the membrane 805 and a second portion of the post or fin that extends from the bottom of the generally planar surface of the top portion 803 to a topside of the membrane 805, such that the bottom portion and the top portion meet at the membrane 805 and provide mechanical support thereto after fabrication of the heat sink 800 and during use of the heat sink 800.

Once joined together, the bottom portion 801 and the top portion 803 of the heat sink 800 create a single-direction fluidic pathway for heat exchange fluid. The single-direction fluidic pathway for heat exchange fluid begins by heat exchange fluid in the liquid phase being communicated through the liquid inlet 802 and into the inner portion/volume of the bottom portion 801. The heat exchange fluid in the liquid phase is disallowed from being communicated through the membrane 805, which is a vapor-permeable/liquid-impermeable membrane. As such, the heat exchange fluid in the liquid phase reaches an effective dead end in the inner portion/volume of the bottom portion 801 of the heat sink 800 and cannot progress further along the single-direction fluidic pathway for heat exchange fluid without first undergoing a phase change.

The heat sink 800 is configured to be collocated with a heat-generating computing element (not shown) that emits heat which causes phase change of the heat exchange fluid in the inner portion/volume of the bottom portion 801 of the heat sink 800. As the heat exchange fluid in the liquid phase begins the phase change, bubbles of the heat exchange fluid in a vapor phase can begin to form. The membrane 805 is configured to communicate the heat exchange fluid in the vapor phase (i.e., bubbles) therethrough from the inner portion/volume of the bottom portion 801 to the inner portion/volume of the top portion 803.

As heat exchange fluid in the vapor phase (i.e., bubbles) are communicated through the membrane 805, there is a corresponding temporary increase in capacity within the inner portion/volume of the bottom portion 801 of the heat sink 800 for additional heat exchange fluid in the liquid phase. According to some embodiments, this temporarily increased capacity for heat exchange fluid in the liquid phase in the inner portion/volume of the bottom portion 801 of the heat sink 800 hydrodynamically causes a partial vacuum to form within the inner portion/volume of the bottom portion 801 of the heat sink 800, causing additional heat exchange fluid in the liquid phase to be communicated through the liquid inlet 802 and into the inner portion/volume of the bottom portion 801 of the heat sink 800. According to other embodiments, a hydrodynamic pressure is continuously applied against heat exchange fluid in the liquid phase outside of the liquid inlet 802 which causes additional heat exchange fluid in the liquid phase to be communicated through the liquid inlet 802 and into the inner portion/volume of the bottom portion 801 of the heat sink 800. A volume of additional heat exchange fluid in the liquid phase that is communicated through the liquid inlet 802 and into the inner portion/volume of the bottom portion 801 of the heat sink 800 will be proportional to, and/or correlated with, a volume of heat exchange fluid in the vapor phase (i.e., bubbles) that are communicated through the membrane 805 following the phase change from the liquid phase to the vapor phase.

The single-direction fluidic pathway for heat exchange fluid through the heat sink 800 continues with an accumulation of heat exchange fluid in the vapor phase (i.e., bubbles) within an inner portion/volume of the top portion 803 of the heat sink 800 following the communication of the heat exchange fluid in the vapor phase through the membrane 805. The only outlet for heat exchange fluid from the heat sink (in any phase) is through the vapor outlet 804 defined by an aperture in the top portion 803 of the heat sink 800. Therefore, the volume of heat exchange fluid in the vapor phase that accumulates in the inner portion/volume of the top portion 803 of the heat sink 800 eventually (whether based on a partial pressure differential, vacuum forces, venturi forces, increasing vapor pressure due to continued vapor flux into the inner portion/volume of the top portion 803, or otherwise) is communicated out of the heat sink 800 by way of the vapor outlet 804.

In some embodiments, one or more other posts or fins may be formed on (or defined from) the bottom portion 801 of the heat sink 800. This may be done to increase surface area in the inner portion/volume of the bottom portion 801 of the heat sink 800. While increased fluid velocity can often increase heat transfer coefficient of the heat sink, the increase in surface area and reduction in unwanted hydrodynamic forces within the bottom portion 801 of the heat sink 800 during phase change may represent a net benefit above any incidental decrease in heat transfer coefficient due to reduced heat exchange fluid flow velocity. Also, in some embodiments, the heat sink 800 may operate in a largely static hydrodynamic environment, meaning that a nearly constant, relatively high hydrodynamic pressure may be applied via the heat exchange fluid in the liquid phase against the fluid inlet 802 while a flow velocity of that heat exchange fluid in the liquid phase into the heat sink 800 may be relatively low, depending on the waste heat being generated by the collocated heat emitting element and the heat transfer coefficient and heat sink cooling capacity of the heat sink 800. This may mean that the heat transfer coefficient and heat sink cooling capacity of the heat sink 800 may not be related at all (or very little) to the flow rate/velocity of the heat exchange fluid into the heat sink 800, e.g., at the scale of a single chip/chipset.

During use, the heat sink 800 will experience thermal expansion and material deformation due to temperature changes. Mechanically and structurally speaking, while the heat sink 800 includes several membrane supports 806 which will provide for some mechanical stability of the membrane 805, and which may provide for some increased durability of the heat sink 800 overall after initial fabrication of the heat sink 800, the thermal expansion and material deformation will still decrease the durability and life span of the heat sink and chip assembly 800.

According to some embodiments, several solutions to this are contemplated. For example, a material can be chosen for various components of the heat sink 800 which exhibit a lower coefficient of thermal expansion than copper or other conventional heat sink materials and which also achieve a sufficiently high (albeit lower than copper or other conventional heat sink materials) thermal conductivity. For example, a material such as copper tungsten, which has a lower coefficient of thermal expansion than copper while also having a sufficiently high thermal conductivity, can be used to form the bottom portion 801, where heat sink meets the silicon chip. Other materials are contemplated, and other tradeoffs between coefficient of thermal expansion, thermal conductivity, material costs, material usability/workability, and/or other material properties/characteristics were also examined. For example, a material such as stainless steel or titanium is highly durable, but has a low heat transfer coefficient, and also presents downsides such as workability, cost, and other factors.

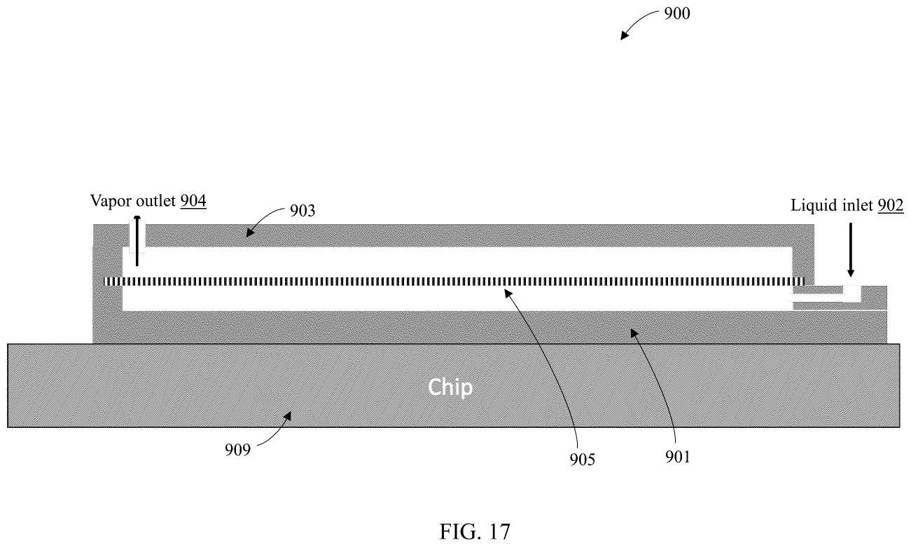

In many applications, such as for heat sinks that are collocated with a single chip or integrated circuit, there may be significant space limitations for collocating the heat sink on the chip within the device using the chip/integrated circuit. As such, in some cases, fluid inlets and outlets must be positioned on top of the heat sink, such as illustrated in FIG. 17.

FIG. 17 illustrates a side-view of a heat sink 900. The heat sink 900 comprises a bottom portion 901. As viewed from a top-down perspective, the bottom portion 901 can have a flat, slightly convex, or slightly concave shape defined by a generally planar surface and one or more raised portions (e.g., walls) being formed about an outside edge of the generally planar surface of the bottom portion 901. An inner portion or inner volume of the bottom portion 901 of the heat sink 900 can be defined based at least in part on the generally planar surface and the one or more raised portions formed about the outside edge of the generally planar surface of the bottom portion 901 that stand proud of the generally planar surface in the direction of the top-down perspective. One or more apertures can be formed through a raised portion to form a liquid inlet 902. The liquid inlet 902 can be configured to allow a heat exchange fluid in a liquid phase to be communicated from outside the heat sink 900 to the inner portion or inner volume of the bottom portion 901 of the heat sink 900.

The heat sink 900 illustrated in FIG. 17 further comprises a top portion 903. As viewed from a top-down perspective, the top portion 903 can have a flat, slightly convex, or slightly concave shape defined by a generally planar surface and one or more raised portions (e.g., walls) being formed about an outside edge of the generally planar surface of the top portion 903. An inner portion or inner volume of the top portion 903 of the heat sink 900 can be defined based at least in part on the generally planar surface and the one or more raised portions formed about the outside edge of the generally planar surface of the top portion 903 that stand proud of the generally planar surface in a direction that is opposite the direction of the top-down perspective. One or more apertures can be formed through a raised portion to form a vapor outlet 904. The vapor outlet 904 can be configured to allow a heat exchange fluid in a vapor phase to be communicated from the inner portion or inner volume of the top portion 903 of the heat sink 900 to outside the heat sink 900.

The heat sink 900 illustrated in FIG. 17 further comprises a membrane 905 disposed at least partially between the bottom portion 901 of the heat sink 900 and the top portion 903 of the heat sink 900. The membrane 905 is a vapor-permeable membrane that allows for communication of heat exchange fluid in the vapor phase therethrough, while disallowing communication of heat exchange fluid in the liquid phase therethrough. The membrane 905 can be joined to or within part of the bottom portion 901, joined to or within part of the top portion 903, or both.

As illustrated in FIG. 17, for example, a portion of each edge of the membrane 905 is disposed within a groove or recess within the raised circumferential portion of the bottom portion 901 of the heat sink 900 at one or more locations that are above the liquid inlet 902 such that heat exchange fluid in the liquid phase will be retained within the inner portion or the inner volume of the bottom portion 901 that is further defined by an underside/bottom surface of the membrane 905.

Alternatively, a portion of each edge of the membrane 905 could instead be disposed within a groove or recess within the raised circumferential portion of the top portion 903 of the heat sink 900 at one or more locations that are below the vapor outlet 904. In such a configuration, heat exchange fluid in the liquid phase will be retained within the inner portion/volume of the bottom portion 901 that is further defined by the underside/bottom surface of the membrane 905 without being communicated out of the heat sink 900 by way of the vapor outlet 904.

Alternatively, a portion of the edges of the membrane 905 could be disposed between a top surface of the raised portions of the bottom portion 901 and a bottom surface of the raised portions of the top portion 903 and the bottom portion 901 and top portion 903 can be joined/scaled together. In such a configuration, the membrane 405 is fluidically sealed between the liquid inlet 902 and the vapor outlet 904 of the heat sink 900.

In some embodiments, the heat exchange fluid can be communicated through the liquid inlet 902 and into the inner portion/volume of the bottom portion 901 of the heat sink 900 at a hydrodynamic pressure that is sufficient to, whether acutely or chronically over time, deform or damage the membrane 905.

While the heat sink 800 illustrated in FIG. 16 comprises membrane supports 806 that are configured to disallow or reduce physical/mechanical deformation of the membrane 805 during use of the heat sink 800, the heat sink 900 is not illustrated as including such membrane supports because such membrane supports are an optional feature in the heat sink 900 illustrated in FIG. 17.

Also, while the heat sink 800 illustrated in FIG. 16 includes a plurality of fins 806 that are formed on (or defined from) the bottom portion 801 of the heat sink 800. The heat sink 900 is not illustrated as including such fins because such fins are an optional feature in the heat sink 900 illustrated in FIG. 17.

In some embodiments, the heat sink 900 may operate in a largely static hydrodynamic environment, meaning that a nearly constant pressure may be applied via the heat exchange fluid in the liquid phase against the fluid inlet 902 while a flow velocity of that heat exchange fluid in the liquid phase into the heat sink 900 may be relatively low, depending on the waste heat being generated by the collocated heat emitting element. This may mean that the heat transfer coefficient and heat sink cooling capacity of the heat sink 900 may not be related at all (or very little) to the flow rate/velocity of the heat exchange fluid into the heat sink 900, e.g., at the scale of a single chip/chipset.

Once joined together, the bottom portion 901 and the top portion 903 of the heat sink 900 create a single-direction fluidic pathway for heat exchange fluid. The single-direction fluidic pathway for heat exchange fluid begins by heat exchange fluid in the liquid phase being communicated through the liquid inlet 902 and into the inner portion/volume of the bottom portion 901. The heat exchange fluid in the liquid phase is disallowed from being communicated through the membrane 905, which is a vapor-permeable/liquid-impermeable membrane. As such, the heat exchange fluid in the liquid phase reaches an effective dead end in the inner portion/volume of the bottom portion 901 of the heat sink 900 and cannot progress further along the single-direction fluidic pathway for heat exchange fluid without first undergoing a phase change.

The heat sink 900 is configured to be collocated with a heat-generating computing element (not shown) that emits heat within the inner portion/volume of the bottom portion 901 of the heat sink 900. Upon heating, phase change of the heat exchange fluid in the liquid phase begins and bubbles of heat exchange fluid in a vapor phase begin to form. The membrane 905 is configured to communicate the heat exchange fluid in the vapor phase (i.e., bubbles) therethrough from the inner portion/volume of the bottom portion 901 to the inner portion/volume of the top portion 903. As heat exchange fluid in the vapor phase (i.e., bubbles) are communicated through the membrane 905, there is a corresponding temporary increase in capacity within the inner portion/volume of the bottom portion 901 of the heat sink 900 for additional heat exchange fluid in the liquid phase. According to some embodiments, this temporarily increased capacity for heat exchange fluid in the liquid phase in the inner portion/volume of the bottom portion 901 of the heat sink 900 hydrodynamically causes a low pressure region to form within the inner portion/volume of the bottom portion 901 of the heat sink 900, causing additional heat exchange fluid in the liquid phase to be communicated through the liquid inlet 902 and into the inner portion/volume of the bottom portion 901 of the heat sink 900. According to other embodiments, a hydrodynamic pressure is continuously applied against heat exchange fluid in the liquid phase at an outside of the liquid inlet 902 which causes additional heat exchange fluid in the liquid phase to be communicated through the liquid inlet 902 and into the inner portion/volume of the bottom portion 901 of the heat sink 900. A volume of additional heat exchange fluid in the liquid phase that is communicated through the liquid inlet 902 and into the inner portion/volume of the bottom portion 901 of the heat sink 900 will be proportional to, and/or correlated with, a volume of heat exchange fluid in the vapor phase (i.e., bubbles) that are communicated through the membrane 905 following the phase change from the liquid phase to the vapor phase.

The single-direction fluidic pathway for heat exchange fluid through the heat sink 900 continues with the flow of heat exchange fluid in the vapor phase (i.e., bubbles) within an inner portion/volume of the top portion 903 of the heat sink 900 following the communication of the heat exchange fluid in the vapor phase through the membrane 905. The only outlet for heat exchange fluid from the heat sink (in any phase) is through the vapor outlet 904 defined by an aperture in the top portion 903 of the heat sink 900. Therefore, the volume of heat exchange fluid in the vapor phase that accumulates in the inner portion/volume of the top portion 903 of the heat sink 900 eventually (whether based on a partial pressure differential, vacuum forces, venturi forces, increasing vapor pressure due to continued vapor flux into the inner portion/volume of the top portion 903, or otherwise) is communicated out of the heat sink 900 by way of the vapor outlet 904.

During use, the heat sink 900 will experience relatively large hydrodynamic pressures and high temperatures, and will undergo unwanted thermal expansion and material deformation due to temperature changes.

A heat sink at standard temperature and pressure (such as a single phase, high flow rate heat exchanger/heat sink) can be manufactured out of less durable, more thermally conductive materials such as aluminum. However, when relatively higher hydrodynamic pressures and lower flow rates of heat exchange fluid are used, such as in the heat sink 900, more durable materials should be used to manufacture the heat sink/heat exchanger, such as materials that have a much lower coefficient of thermal expansion than conventional materials such as aluminum. However, many durable materials that have a significantly lower coefficient of thermal expansion also have a significantly lower thermal conductivity, leading to a heat sink/heat exchange that has a relatively lower cooling capacity. Typically, operating pressures within conventional heat sinks can be quite high, requiring more mechanically durable material use and/or the inclusion of internal structural supports or the like to withstand operating pressures. Conversely, in accordance with embodiments of the present disclosure, the disclosed approaches, methods, systems, and apparatuses have operating pressures that are materially lower than that of conventional heat sinks.

As noted above, conventional heat sinks are typically manufactured from aluminum due to its high thermal conductivity, lightness, and low cost. However, aluminum erodes in water. Hence, data center heat sink are made from copper. Copper is compatible with water while its thermal conductivity is twice that of aluminum. However, copper is more expensive.

To improve the life span of the heat sink 900, a material or materials other than aluminum and unalloyed copper were considered in order to better align the coefficient of thermal expansion (CTE) of the heat sink (e.g., the contact surface laminated onto or joined to a bottom surface of the heat sink) to that of the heat source/chip/chipset. For example, a laminate of one or more materials, an alloy of more than one material, or the like, can be used to manufacture one or more components of the heat sink. Several examples of such an approach are described below.

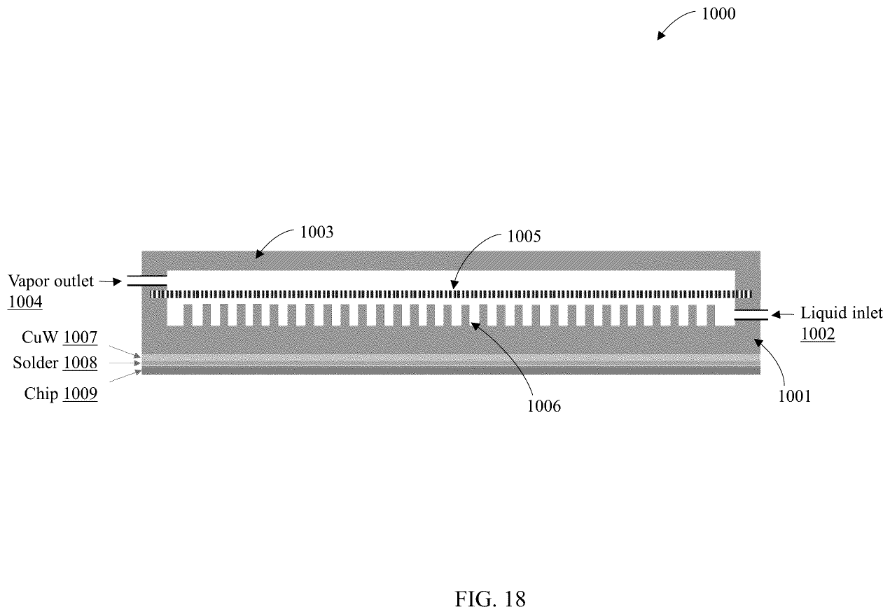

FIG. 18 illustrates a side-view of a heat sink 1000. The heat sink 1000 comprises a bottom portion 1001. As viewed from a top-down perspective, the bottom portion 1001 can have a flat, slightly convex, or slightly concave shape defined by a generally planar surface and one or more raised portions (e.g., walls) being formed about an outside edge of the generally planar surface of the bottom portion 1001. An inner portion or inner volume of the bottom portion 1001 of the heat sink 1000 can be defined based at least in part on the generally planar surface and the one or more raised portions formed about the outside edge of the generally planar surface of the bottom portion 1001 that stand proud of the generally planar surface in the direction of the top-down perspective. One or more apertures can be formed through a raised portion to form a liquid inlet 1002. The liquid inlet 1002 can be configured to allow a heat exchange fluid in a liquid phase to be communicated from outside the heat sink 1000 to the inner portion or inner volume of the bottom portion 1001 of the heat sink 1000.

The heat sink 1000 illustrated in FIG. 18 further comprises a top portion 1003. As viewed from a top-down perspective, the top portion 1003 can have a flat, slightly convex, or slightly concave shape defined by a generally planar surface and one or more raised portions (e.g., walls) being formed about an outside edge of the generally planar surface of the top portion 1003. An inner portion or inner volume of the top portion 1003 of the heat sink 1000 can be defined based at least in part on the generally planar surface and the one or more raised portions formed about the outside edge of the generally planar surface of the top portion 1003 that stand proud of the generally planar surface in a direction that is opposite the direction of the top-down perspective. One or more apertures can be formed through a raised portion to form a vapor outlet 1004. The vapor outlet 1004 can be configured to allow a heat exchange fluid in a vapor phase to be communicated from the inner portion or inner volume of the top portion 1003 of the heat sink 1000 to outside the heat sink 1000.

The heat sink 1000 illustrated in FIG. 18 further comprises a membrane 1005 disposed at least partially between the bottom portion 1001 of the heat sink 1000 and the top portion 1003 of the heat sink 1000. The membrane 1005 is a vapor-permeable membrane that allows for communication of heat exchange fluid in the vapor phase therethrough, while disallowing communication of heat exchange fluid in the liquid phase therethrough. The membrane 1005 can be joined to or within part of the bottom portion 1001, joined to or within part of the top portion 1003, or both.

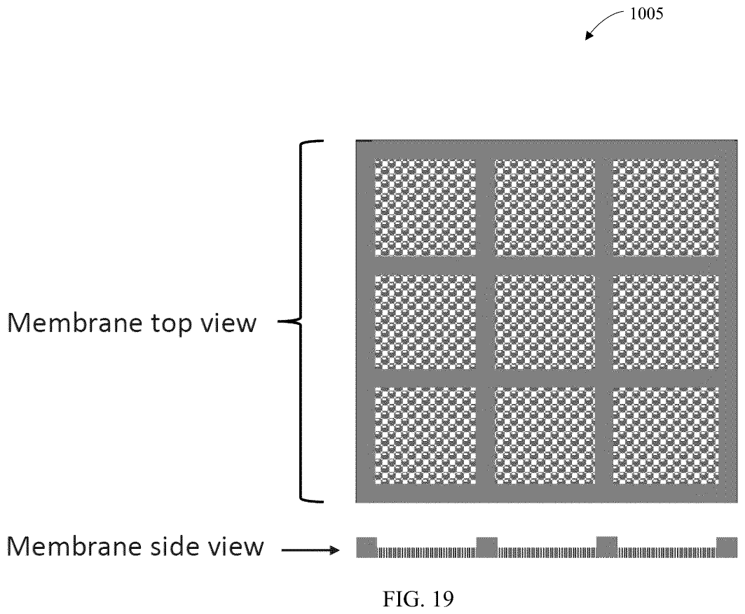

FIG. 19 provides a top view and a side view of the membrane 1005. The membrane 1005 can be made of a durable polymer, such as Teflon®, or metals treated to be hydrophobic. In some embodiments, if a durable polymer is used for the membrane 1005, the membrane 1005 may be thicker or require an increased density of structural supports in order to achieve sufficient structural integrity. In other embodiments, if a metal material is used for the membrane 1005, the membrane 1005 can be thinner and/or may require sparser structural supports to achieve sufficient structural integrity. In some embodiments, structural supports can be provided vertically from above/below the membrane 1005, such as with the structural supports 806 in the heat sink 800. However, in other embodiments, the structural supports can be horizontal structurally supporting strips, such as illustrated in FIG. 19, which reduces local vertical deformation within center portions of the membrane 1005 through tensile support in four directions to each edge of the membrane 1005.

Returning to FIG. 18, a portion of each edge of the membrane 1005 is disposed within a groove or recess within the raised circumferential portion of the bottom portion 1001 of the heat sink 1000 at one or more locations that are above the liquid inlet 1002 such that heat exchange fluid in the liquid phase will be retained within the inner portion or the inner volume of the bottom portion 1001 that is further defined by an underside/bottom surface of the membrane 1005.

Alternatively, a portion of each edge of the membrane 1005 could instead be disposed within a groove or recess within the raised circumferential portion of the top portion 1003 of the heat sink 1000 at one or more locations that are below the vapor outlet 1004. In such a configuration, heat exchange fluid in the liquid phase will be retained within the inner portion/volume of the bottom portion 1001 that is further defined by the underside/bottom surface of the membrane 1005 without being communicated out of the heat sink 1000 by way of the vapor outlet 1004.

Alternatively, a portion of the edges of the membrane 1005 could be disposed between a top surface of the raised portions of the bottom portion 1001 and a bottom surface of the raised portions of the top portion 1003 and the bottom portion 1001 and top portion 1003 can be joined/scaled together. In such a configuration, the membrane 1005 is fluidically sealed between the liquid inlet 1002 and the vapor outlet 1004 of the heat sink 1000.

In some embodiments, the heat exchange fluid can be communicated through the liquid inlet 1002 and into the inner portion/volume of the bottom portion 1001 of the heat sink 1000 at a hydrodynamic pressure that is sufficient to, whether acutely or chronically over time, deform or damage the membrane 1005. While the heat sink 800 illustrated in FIG. 16 comprises membrane supports 806 that are configured to disallow or reduce physical/mechanical deformation of the membrane 805 during use of the heat sink 800, the heat sink 1000 is not illustrated as including such membrane supports because the membrane supports are an optional feature for the heat sink 1000 illustrated in FIG. 18 and in the membrane 1005 illustrated in FIG. 19.

In some embodiments, the heat sink 1000 may operate in a largely static hydrodynamic environment, meaning that a nearly constant pressure may be applied via the heat exchange fluid in the liquid phase against the fluid inlet 1002 while a flow velocity of that heat exchange fluid in the liquid phase into the heat sink 1000 may be relatively low, depending on the waste heat being generated by the collocated heat emitting element. This may mean that the heat transfer coefficient and heat sink cooling capacity of the heat sink 1000 may not be related at all (or very little) to the flow rate/velocity of the heat exchange fluid into the heat sink 1000, e.g., at the scale of a single chip/chipset.

Once joined together, the bottom portion 1001 and the top portion 1003 of the heat sink 1000 create a single-direction fluidic pathway for heat exchange fluid. The single-direction fluidic pathway for heat exchange fluid begins by heat exchange fluid in the liquid phase being communicated through the liquid inlet 1002 and into the inner portion/volume of the bottom portion 1001. The heat exchange fluid in the liquid phase is disallowed from being communicated through the membrane 1005, which is a vapor-permeable/liquid-impermeable membrane. As such, the heat exchange fluid in the liquid phase reaches an effective dead end in the inner portion/volume of the bottom portion 1001 of the heat sink 1000 and cannot progress further along the single-direction fluidic pathway for heat exchange fluid without first undergoing a phase change.

The heat sink 1000 is configured to be collocated with a heat-generating computing element (not shown) that emits heat which raises the temperature of the heat exchange fluid in the inner portion/volume of the bottom portion 1001 of the heat sink 1000. As the temperature of the heat exchange fluid in the liquid phase rises, a phase change of the heat exchange fluid in the liquid phase begins and bubbles of heat exchange fluid in a vapor phase begin to form. The membrane 1005 is configured to communicate the heat exchange fluid in the vapor phase (i.e., bubbles) therethrough from the inner portion/volume of the bottom portion 1001 to the inner portion/volume of the top portion 1003.

As heat exchange fluid in the vapor phase (i.e., bubbles) are communicated through the membrane 1005, there is a corresponding temporary increase in capacity within the inner portion/volume of the bottom portion 1001 of the heat sink 1000 for additional heat exchange fluid in the liquid phase. According to some embodiments, this temporarily increased capacity for heat exchange fluid in the liquid phase in the inner portion/volume of the bottom portion 1001 of the heat sink 1000 hydrodynamically causes a low pressure region to form within the inner portion/volume of the bottom portion 1001 of the heat sink 1000, causing additional heat exchange fluid in the liquid phase to be communicated through the liquid inlet 1002 and into the inner portion/volume of the bottom portion 1001 of the heat sink 1000. According to other embodiments, a hydrodynamic pressure is continuously applied against heat exchange fluid in the liquid phase at an outside of the liquid inlet 1002 which causes additional heat exchange fluid in the liquid phase to be communicated through the liquid inlet 1002 and into the inner portion/volume of the bottom portion 1001 of the heat sink 1000. A volume of additional heat exchange fluid in the liquid phase that is communicated through the liquid inlet 1002 and into the inner portion/volume of the bottom portion 1001 of the heat sink 1000 will be proportional to, and/or correlated with, a volume of heat exchange fluid in the vapor phase (i.e., bubbles) that are communicated through the membrane 1005 following the phase change from the liquid phase to the vapor phase.

The single-direction fluidic pathway for heat exchange fluid through the heat sink 1000 continues with an accumulation of heat exchange fluid in the vapor phase (i.e., bubbles) within an inner portion/volume of the top portion 1003 of the heat sink 1000 following the communication of the heat exchange fluid in the vapor phase through the membrane 1005. The only outlet for heat exchange fluid from the heat sink (in any phase) is through the vapor outlet 1004 defined by an aperture in the top portion 1003 of the heat sink 1000. Therefore, the volume of heat exchange fluid in the vapor phase that accumulates in the inner portion/volume of the top portion 1003 of the heat sink 1000 eventually (based on pressure differential, increasing vapor pressure due to continued vapor flux into the inner portion/volume of the top portion 1003, or otherwise) is communicated out of the heat sink 1000 by way of the vapor outlet 1004.

During use, the heat sink 1000 will experience unwanted thermal expansion and material deformation due to temperature changes. In some embodiments thermal expansion and material deformation over time may decrease the durability and life span of the heat sink 1000. However, by aligning the CTE of the materials used at the contact surface between the heat sink and heat source, the mechanical stress and strain at the contact surface of the heat sink/source contact materials will be diminished, leading to improved material durability and improved lifespan for the heat source(s) in addition to the heat sink(s) collocated therewith.

To improve the life span of the heat sink 1000 and chip package, the heat sink 1000 can further comprise a copper-tungsten (CuW) base 1007. A top surface of the copper-tungsten base 1007 can be joined to a bottom surface of the bottom portion 1001 of the heat sink 1000. The copper-tungsten base 1007 can comprise a copper-tungsten alloy material that exhibits a reduced CTE differential relative to, e.g., a silicone chip or other heat source, leading to an increased lifespan of the heat source as well as the heat sink in variable temperatures.

The heat sink 1000 can be configured to be in thermal communication with a chip 1008 (such as an integrated circuit or the like). Since air is a thermal insulator and space within electronic devices and on a chip 1008 is typically scarce, the heat sink 1000 may be collocated with the chip 1008 by being physically coupled to the chip 1008. As illustrated, the heat sink 1000 is coupled to an underside of the copper-tungsten base 1007 via soldering, forming a solder interface 1008 between the heat sink 1000 and the copper-tungsten base 1007. The chip 1008 can comprise or be formed using silicone or a silicon-based material. The solder 1008 can comprise, e.g., Sn₆₀Pb₄₀, or another similar solder composition.

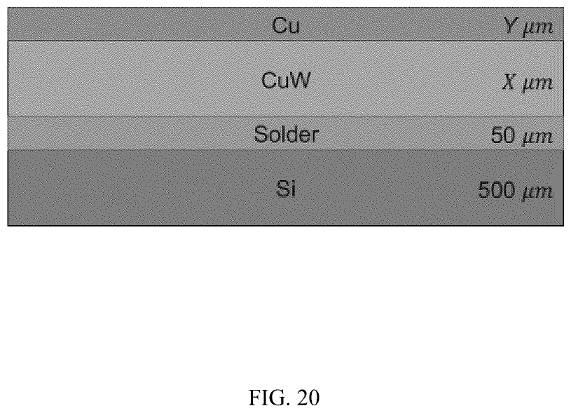

FIG. 20 illustrates an example of a material order and a relative material thickness for a hybrid membrane heat sink base design, according to one embodiment. Even once the materials are chosen, the thickness of each layer of the hybrid base design must be determined based on the thermal and mechanical properties of each material in order to achieve a sufficiently mechanically durable and thermally conductive hybrid base design. As illustrated, given a thickness of a silicon-based chip and a solder interface of, respectively, 500 μm and 50 μm, the thickness of the copper-tungsten layer can be given as X μm and the thickness of the copper-based bottom portion of the heat sink can be given as Y μm.

In some embodiments, a thickness of the copper-tungsten layer is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 80 μm, less than about 60 μm, less than about 40 μm, less than about 20 μm, less than about 10 μm, or less than about 5 μm, inclusive of all values and ranges therebetween.

In some embodiments, a thickness of the heat sink or the copper-based bottom portion of the heat sink is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 90 μm, less than about 80 μm, less than about 70 μm, less than about 60 μm, less than about 50 μm, less than about 40 μm, less than about 30 μm, less than about 20 μm, greater than about 20 μm, greater than about 40 μm, greater than about 60 μm, greater than about 80 μm, greater than about 100 μm, greater than about 200 μm, greater than about 300 μm, greater than about 400 μm, greater than about 500 μm, greater than about 600 μm, greater than about 700 μm, greater than about 800 μm, greater than about 900 μm, or greater than about 1.00 μm, inclusive of all values and ranges therebetween.

In some embodiments, the thickness of the copper-tungsten layer is between about 50 μm and about 500 μm and the thickness of the heat sink or the copper-based bottom portion of the heat sink is between about 50 μm and about 500 μm.

According to some embodiments, the copper-tungsten layer and the copper layer together provide for the desired mechanical strength since the heat sink is at a lower pressure than the ambient pressure about the heat sink. In some embodiments, the copper layer provides for better chemical stability of the heat sink with regard to the heat exchange fluid in the liquid phase since copper is mostly stable in water but tungsten is less stable in water. In some embodiments, the thickness of the copper-tungsten layer (X μm) can be adjusted such that the coefficient of thermal expansion of the laminate structure (X μm+Y μm) is approximately equal to the coefficient of thermal expansion of the silicon chip. This may cause the thermal expansion and contraction of materials to be approximately equal, meaning that there is minimal separation/delamination between the silicon chip, the solder, the copper-tungsten layer, and/or the copper layer. In some embodiments, the thickness of the copper-tungsten layer (X μm) can be reduced or minimized to reduce thermal resistance over the laminate structure (X μm+Y μm).

While other materials and material combinations were contemplated for heat sink configurations, select materials are highlighted below in Table 1 because they exhibit desired mechanical and thermal properties.

TABLE 1
Material Properties of Select Materials

| | | | | | | Coefficient |
|---|---|---|---|---|---|---|
| | | | | | Specific | of |
| | | Young's | Von mises | Thermal | heat | Thermal |
| | Density | modulus | stress | conductivity | capacity | Expansion |
| Material | kg/m³ | GPa | GPa | W/m · K | J/kg · K | ×10⁻⁶ K⁻¹ |
| Copper | 8,960 | 110 | 0.13 | 400 | 385 | 17 |
| Copper- | 16,400 | 310 | 0.10 | 196 | 175 | 5.8 |
| Tungsten | | | | | | |
| Solder | 9,000 | 10 | 0.04 | 50 | 150 | 21 |
| Silicon | 2,329 | 170 | 0.06 | 137 | 700 | 2.6 |

Evaluation of specific layer thicknesses and material choices can be carried out using the material characteristics in Table 1, and according to the tradeoffs and guidelines illustrated in FIG. 20. To evaluate the efficacy and durability of the heat sinks descried herein, thermal and mechanical modeling and testing were conducted.

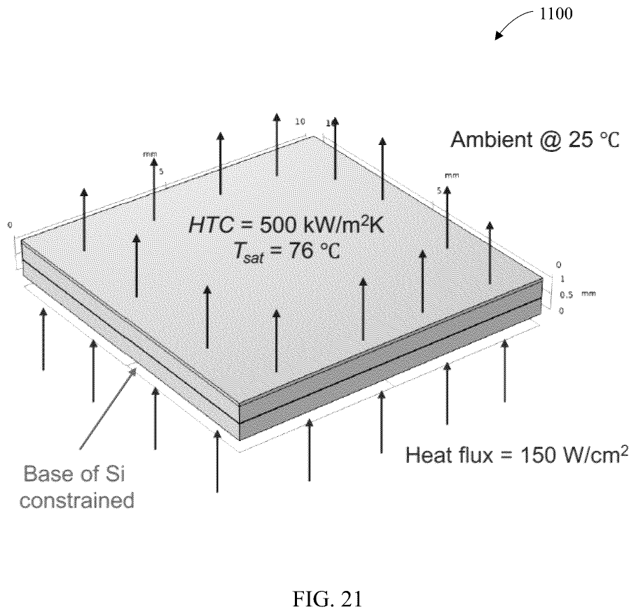

FIG. 21 illustrates representative boundary conditions for thermal and mechanical modeling of select material for a heat sink 1100. Assumptions for the thermal and mechanical modeling include:
Ambient temperature is 25° C.
Heat transfer coefficient of material for the heat sink 1100 is 500 kW/m²K
Tₛₐₜ is 76° C.
Heat flux is 150 W/cm²
Base of silicon (chip) is constrained
Tungsten-copper layer is 50 μm thick
Copper layer is 500 μm thick

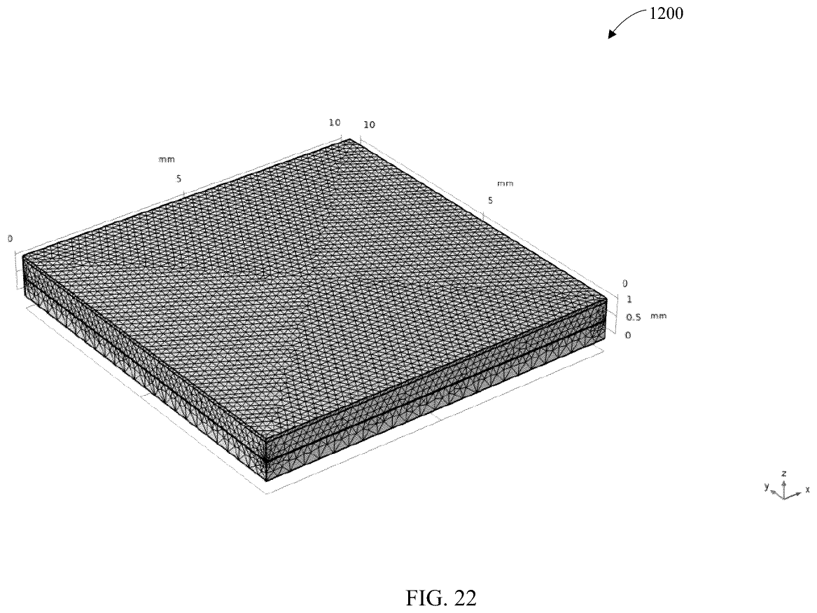

Referring now to FIGS. 22-25, several different mesh options are illustrated for improved mechanical performance of the heat sink membrane. In some embodiments, the mesh can be formed from a polymer. In some embodiments, the mesh can be woven, extruded, expanded, knitted, woven, or sintered.

In FIG. 22, a ‘normal’ mesh configuration 1200 is shown. In some embodiments, the ‘normal’ mesh configuration 1200 has a relatively uniform arrangement of strands oriented (e.g., woven) across the membrane. In some embodiments, the ‘normal’ mesh configuration 1200 can have a uniform warp to weft ratio. In some embodiments, the ‘normal’ mesh configuration 1200 can have a porosity within a particular range, which may be determined based on a number of openings or apertures in the mesh per unit area or over a unit of length of mesh. In some embodiments, the ‘normal’ mesh configuration 1200 can have a mesh size of between about 2 openings per linear millimeter to about 10 openings per linear millimeter.

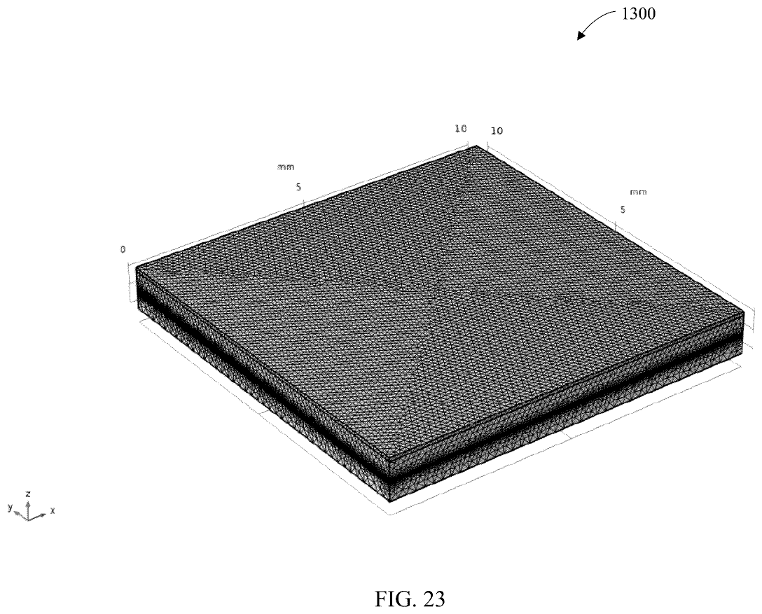

In FIG. 23, a ‘fine’ mesh configuration 1300 is shown. In some embodiments, the ‘fine’ mesh configuration 1300 has a relatively uniform arrangement of strands oriented (e.g., woven) across the membrane. In some embodiments, the ‘fine’ mesh configuration 1300 can have a uniform warp to weft ratio. In some embodiments, the ‘fine’ mesh configuration 1300 can have a porosity within a particular range, which may be determined based on a number of openings or apertures in the mesh per unit area or over a unit of length of mesh. In some embodiments, the ‘fine’ mesh configuration 1300 can have a mesh size of between about 10 openings per linear millimeter to about 100 openings per linear millimeter.

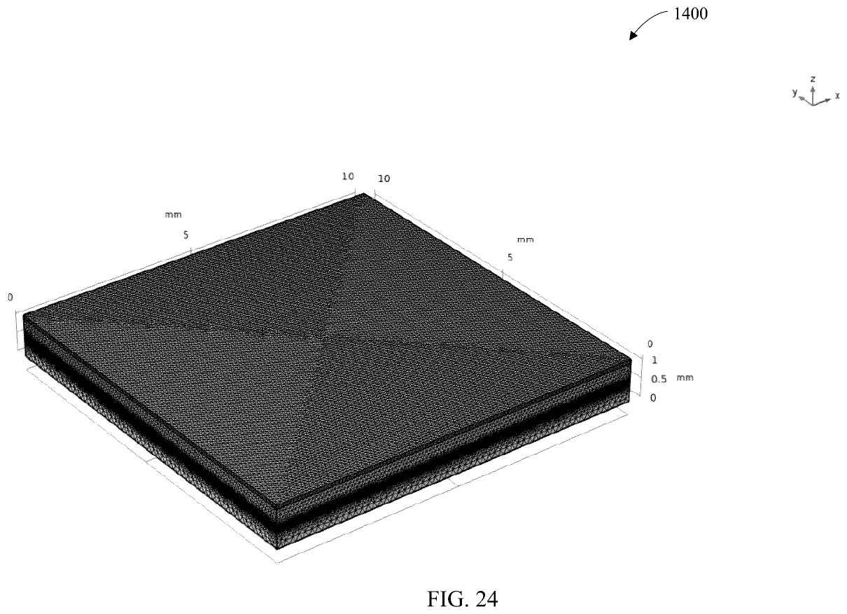

In FIG. 24, an ‘extremely fine’ mesh configuration 1400 is shown. In some embodiments, the ‘extremely fine’ mesh has a relatively uniform arrangement of strands oriented (e.g., woven) across the membrane. In some embodiments, the ‘extremely fine’ mesh configuration 1400 can have a uniform warp to weft ratio. In some embodiments, the ‘extremely fine’ mesh configuration 1400 can have a porosity within a particular range, which may be determined based on a number of openings or apertures in the mesh per unit area or over a unit of length of mesh. In some embodiments, the ‘extremely fine’ mesh configuration 1400 can have a mesh size of between about 100 openings per linear millimeter to about 1,000 openings per linear millimeter.

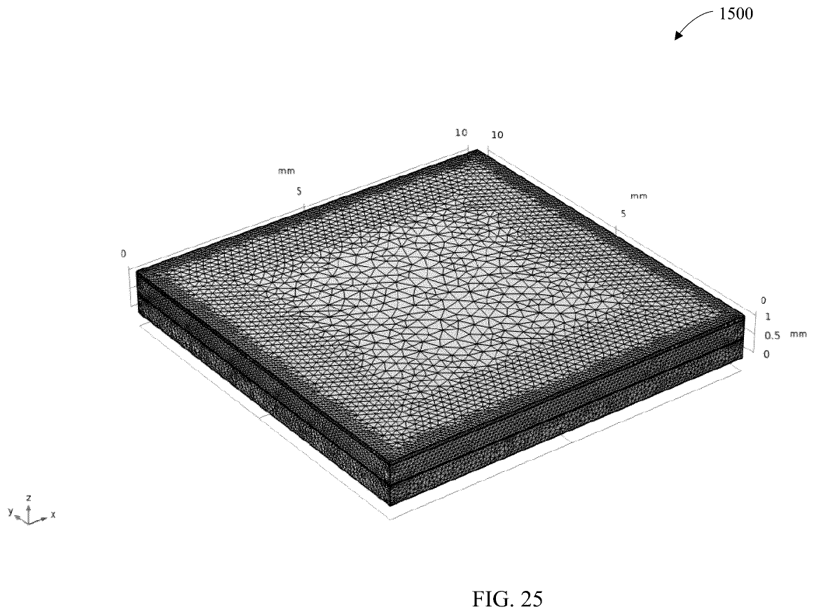

In FIG. 25, an ‘adaptive’ mesh configuration 1500 is shown. In some embodiments, the ‘adaptive’ mesh configuration 1500 has a non-uniform arrangements of strands oriented (e.g., woven) across the membrane. In some embodiments, the ‘adaptive’ mesh configuration 1500 can have a non-uniform warp to weft ratio. In some embodiments, the ‘adaptive’ mesh configuration 1500 can comprise a plurality of different portions or regions each having different porosities. For example, the ‘adaptive’ mesh configuration 1500 can comprise an inner portion or region having a first porosity, an outer portion or region having a second porosity, and a middle portion or region having a third porosity. According to some embodiments, the ‘adaptive’ mesh configuration 1500 shown in FIG. 25 can comprise an inner portion having a first porosity, a middle portion having a second porosity that is finer/smaller than the first porosity, and an outer portion having a third porosity that is finer/smaller than the second porosity. In some embodiments, an ‘adaptive’ mesh configuration 1500 may reduce hydrodynamic stress and strain in a center of the membrane where the mesh is less mechanically supported than at or near an edge of the membrane. In some embodiments, an ‘adaptive’ mesh configuration 1500 may be dimensioned and configured to align one or more regions of increased porosity of the mesh (resulting in increased vapor flux rate through the membrane) with one or more locations/regions in the liquid side of the heat sink where phase change of the heat exchange fluid from liquid phase to vapor phase occurs more/most.

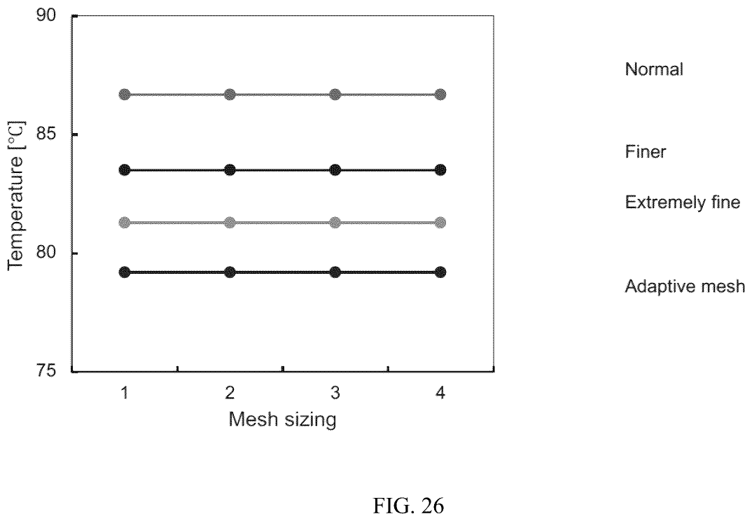

Referring now to FIG. 26, a graph is provided that illustrates the temperature achieved at different mesh sizes for different mesh configurations at a constant heat output. As shown, a heat sink using a ‘normal’ mesh configuration at the different mesh sizes achieved a nearly constant temperature of about 87° C. A heat sink using an ‘fine’ mesh configuration achieved a nearly constant temperature of about 84° C. A heat sink using an ‘extremely fine’ mesh configuration achieved a nearly constant temperature of about 82° C. A heat sink using an ‘adaptive’ mesh configuration achieved a nearly constant temperature of about 79° C.

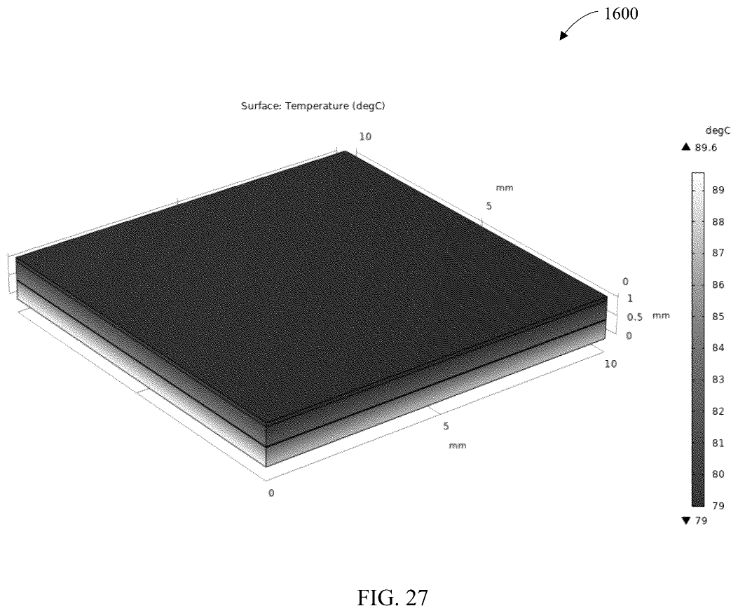

Referring now to FIG. 27, surface temperature modeling was conducted of a heat sink 1600 comprising a hybrid tungsten-copper base collocated on a chip. During operation, the heat sink 1600 maintained a temperature at the hybrid tungsten-copper base of between about 87° C. and about 90° C. However, during operation, the heat sink 1600 maintained a temperature at the top of the heat sink 1600 of between about 84° C. and about 79° C.

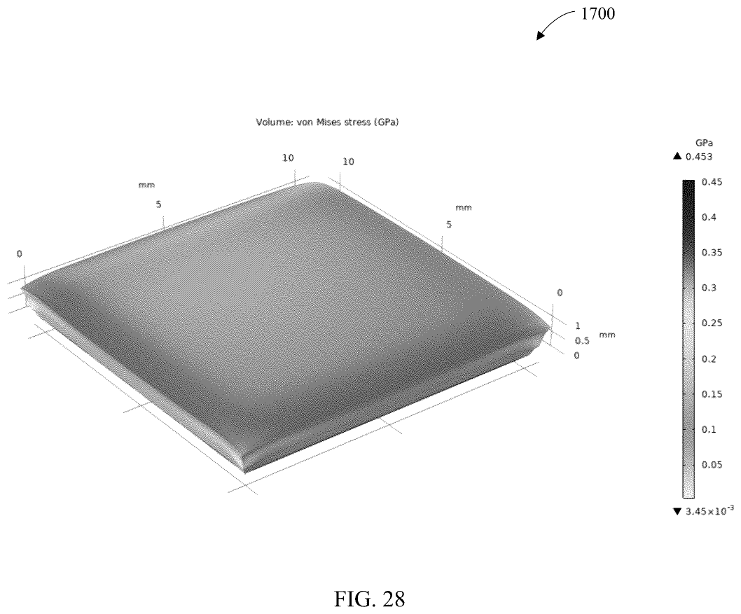

Referring now to FIG. 28, von Mises stress/yield modeling was conducted of a heat sink 1700 comprising a hybrid tungsten-copper base collocated on a chip. It is assumed that the yielding of a ductile material begins when the second invariant of deviatoric stress reaches a critical value, while prior to yielding, the material exhibits an elastic response to the stress. The von Mises stress is used to predict yielding of materials under complex loading from the results of uniaxial tensile tests. The von Mises stress satisfies the property where two stress states with equal distortion energy have an equal von Mises stress.

During operation, the heat sink 1700 exhibited a minimum von Mises stress of about 0.01 GPa along the edges of the heat sink 1700 and a maximum von Mises stress of about 0.15 GPa in a center region of the heat sink 1700.

The thermal and mechanical modeling, as well as fabrication/manufacturing of heat sinks (e.g., 1700) can be carried out by a computing device, such as computing device 1800 illustrated in FIG. 29. As such, embodiments of the present invention may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language, such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present invention may also be implemented as methods, apparatus, systems, computing devices, computing entities, and/or the like. As such, embodiments of the present invention may take the form of an apparatus, system, computing device, computing entity, and/or the like executing instructions stored on a computer-readable storage medium to perform certain steps or operations. Thus, embodiments of the present invention may also take the form of an entirely hardware embodiment, an entirely computer program product embodiment, and/or an embodiment that comprises combination of computer program products and hardware performing certain steps or operations.

Embodiments of the present invention are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some embodiments, retrieval, loading, and/or execution may be performed in parallel such that multiple instructions are retrieved, loaded, and/or executed together. Thus, such embodiments can produce specifically-configured machines performing the steps or operations specified in the block diagrams and flowchart illustrations. Accordingly, the block diagrams and flowchart illustrations support various combinations of embodiments for performing the specified instructions, operations, or steps.

### Example Computing Device

FIG. 29 provides a schematic of a computing device 1800 that can be configured to monitor and manage a cooling system, such as a vapor-membrane heat sink cooling system (e.g., 200, 300, 400, 500, 600, 700) for a server farm. Alternatively, the computing device 1800 can be configured to manufacture and/or operate a heat sink, such as those described herein. The computing device 1800 may comprise one or more processing elements 1802, one or more non-volatile memories 1804, one or more volatile memories 1806, and/or one or more transmitter/receivers 1808 (e.g., “transceivers 1808”). In some embodiments, the computing device 1800 is configured to store one or more computer program products, computer program code, a computer-readable media comprising instructions, and/or the like. In some embodiments, the computing device 1800 is configured to determine or receive information regarding a current temperature of one or more portions of the server farm, a current pressure within one or more portions of the heat sink cooling system, and/or other information regarding a current status of the system. In some embodiments, the computing device 1800 is configured to carry out at least a part of one of the methods described herein. Information can be received by the computing device 1800 from a manual input, one or more sensors, via an external computing device, and/or the like.

In some embodiments, the computing device 1800 is configured, using any suitable means, to be in wired or wireless communication, such as via the transceivers 1808, with one or more motors, valves, actuators, pumps, sensors, and/or the like (not shown) that are configured to cause communication of liquid heat exchange fluid into one or more of the vapor-barrier heat sinks and/or allow communication of vapor heat exchange fluid out of one or more of the vapor-barrier heat sinks. In some embodiments, the computing device 1800 can be configured to communicate a set of instructions to one or more motors, actuators, sensors, valves, pumps, and/or the like, for one or a series of actions to be carried out. In some embodiments, the computing device 1800 can provide flow rate instructions, e.g., in conjunction with other instructions, to one or more of motors, actuators, sensors, valves, pumps, and/or the like in order for the proper flow rate or discrete volume of liquid heat exchange fluid to be communicated throughout the heat exchange system or to one or more particular vapor-membrane heat exchangers within an array of vapor-membrane heat exchangers, as desired.

In general, the terms computing device, computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As shown in FIG. 29, in one embodiment, the computing device 1800 may include or be in communication with one or more processing elements 1802 (also referred to as processors, processing circuitry, and/or similar terms used herein interchangeably) that communicate with other elements within the computing device 1800 via a bus, for example. As will be understood, the processing element 1802 may be embodied in a number of different ways. For example, the processing element 1802 may be embodied as one or more complex programmable logic devices (CPLDs), microprocessors, multi-core processors, coprocessing entities, application-specific instruction-set processors (ASIPs), microcontrollers, and/or controllers. Further, the processing element 1802 may be embodied as one or more other processing devices or circuitry. The term circuitry may refer to an entirely hardware embodiment or a combination of hardware and computer program products. Thus, the processing element 1802 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processing element 1802 may be configured for a particular use or configured to execute instructions stored in volatile or non-volatile media or otherwise accessible to the processing element 1802. As such, whether configured by hardware or computer program products, or by a combination thereof, the processing element 1802 may be capable of performing steps or operations according to embodiments of the present invention when configured accordingly.

In some embodiments, the computing device 1800 may further include or be in communication with non-volatile media (also referred to as non-volatile storage, memory, memory storage, memory circuitry, and/or similar terms used herein interchangeably). In one embodiment, the non-volatile storage or memory may include the one or more non-volatile memories 1804, including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In some embodiments, the computing device 1800 may further include or be in communication with volatile media (also referred to as volatile storage, memory, memory storage, memory circuitry, and/or similar terms used herein interchangeably). In one embodiment, the volatile storage or memory may also include one or more volatile memories 1806, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 1802. Thus, the databases, database instances, database management systems, data, applications, programs, program modules, scripts, source code, object code, byte code, compiled code, interpreted code, machine code, executable instructions, and/or the like may be used to control certain aspects of the operation of the computing device 1800 with the assistance of the processing element 1802 and operating system.

In some embodiments, the computing device 1800 may also include one or more network interfaces, such as a transceiver 1808 for communicating with various computing entities, such as by communicating data, content, information, and/or similar terms used herein interchangeably that can be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing device 1800 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing device 1800 may include or be in communication with one or more input elements, such as a keyboard input, a mouse input, a touch screen/display input, motion input, movement input, audio input, pointing device input, joystick input, keypad input, and/or the like. The computing device 1800 may also include or be in communication with one or more output elements (not shown), such as audio output, video output, screen/display output, motion output, movement output, and/or the like.

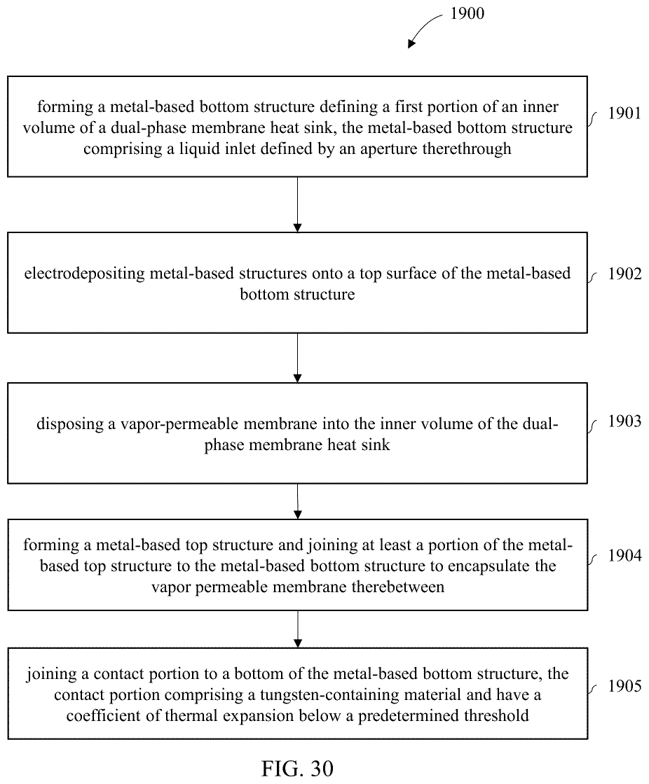

As noted, the computing device 1800 can be configured to carry out one or more portions/steps of a method such as that described herein. Several of the methods contemplated include methods for manufacturing/forming a heat sink such as described herein. Other methods contemplated include methods for operating a heat sink such as described herein. Still other methods contemplated include methods for operating a heat sink system comprising a plurality of heat sinks or heat exchangers. Yet other methods contemplated include methods for operating a chip or chipset having collocated therewith a heat sink, such as described herein. Other methods contemplated include methods for operating a data center or server rack/array having collocated therewith one or more heat sinks or heat exchangers. Some of these methods are described below with regard to FIGS. 30-37.

FIG. 30 illustrates a method 1900 for forming a heat sink. The method 1900 can comprise forming a metal-based bottom structure defining a first portion of an inner volume of a dual-phase membrane heat sink, the metal-based bottom structure comprising a liquid inlet defined by an aperture therethrough, at 1901. The method 1900 can further comprise electrodepositing metal-based structures onto a top surface of the metal-based bottom structure, at 1902. The method 1900 can further comprise disposing a vapor-permeable membrane into the inner volume of the dual-phase membrane heat sink, at 1903. The method 1900 can further comprise forming a metal-based top structure and joining at least a portion of the metal-based top structure to the metal-based bottom structure to encapsulate the vapor permeable membrane therebetween, at 1904. The method 1900 can further comprise joining a contact portion to a bottom of the metal-based bottom structure, the contact portion comprising a tungsten-containing material and have a coefficient of thermal expansion below a predetermined threshold, at 1905.

Some or all of the elements of the method 1900 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 1900 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 1900, whether in part or in full.

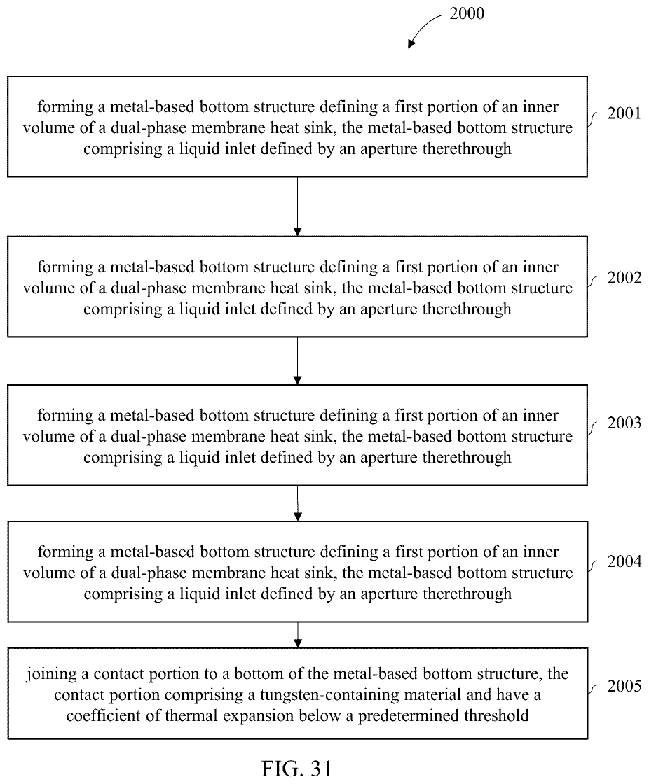

FIG. 31 illustrates a method 2000 for forming a heat sink. The method 2000 can comprise forming a metal-based bottom structure defining a first portion of an inner volume of a dual-phase membrane heat sink, the metal-based bottom structure comprising a liquid inlet defined by an aperture therethrough, at 2001. The method 2000 can further comprise forming a metal-based bottom structure defining a first portion of an inner volume of a dual-phase membrane heat sink, the metal-based bottom structure comprising a liquid inlet defined by an aperture therethrough, at 2002. The method 2000 can further comprise forming a metal-based bottom structure defining a first portion of an inner volume of a dual-phase membrane heat sink, the metal-based bottom structure comprising a liquid inlet defined by an aperture therethrough, at 2003. The method 2000 can further comprise forming a metal-based bottom structure defining a first portion of an inner volume of a dual-phase membrane heat sink, the metal-based bottom structure comprising a liquid inlet defined by an aperture therethrough, at 2004. The method 2000 can further comprise joining a contact portion to a bottom of the metal-based bottom structure, the contact portion comprising a tungsten-containing material and have a coefficient of thermal expansion below a predetermined threshold, at 2005.

Some or all of the elements of the method 2000 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2000 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2000, whether in part or in full.

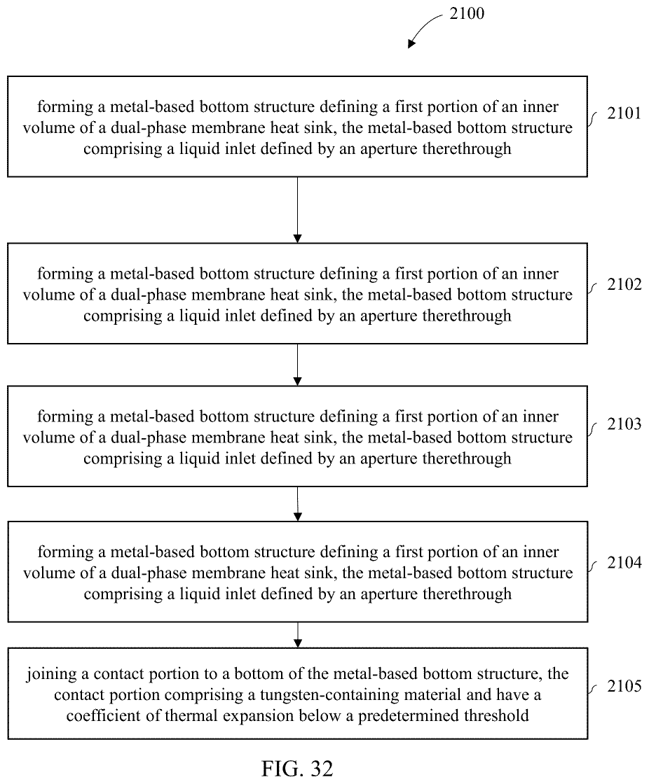

FIG. 32 illustrates a method 2100 for forming a heat sink. The method 2100 can comprise forming a metal-based bottom structure defining a first portion of an inner volume of a dual-phase membrane heat sink, the metal-based bottom structure comprising a liquid inlet defined by an aperture therethrough, at 2101. The method 2100 can further comprise forming a metal-based bottom structure defining a first portion of an inner volume of a dual-phase membrane heat sink, the metal-based bottom structure comprising a liquid inlet defined by an aperture therethrough, at 2102. The method 2100 can further comprise forming a metal-based bottom structure defining a first portion of an inner volume of a dual-phase membrane heat sink, the metal-based bottom structure comprising a liquid inlet defined by an aperture therethrough, at 2103. The method 2100 can further comprise forming a metal-based bottom structure defining a first portion of an inner volume of a dual-phase membrane heat sink, the metal-based bottom structure comprising a liquid inlet defined by an aperture therethrough, at 2104. The method 2100 can further comprise joining a contact portion to a bottom of the metal-based bottom structure, the contact portion comprising a tungsten-containing material and have a coefficient of thermal expansion below a predetermined threshold, at 2105.

Some or all of the elements of the method 2100 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2100 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2100, whether in part or in full.

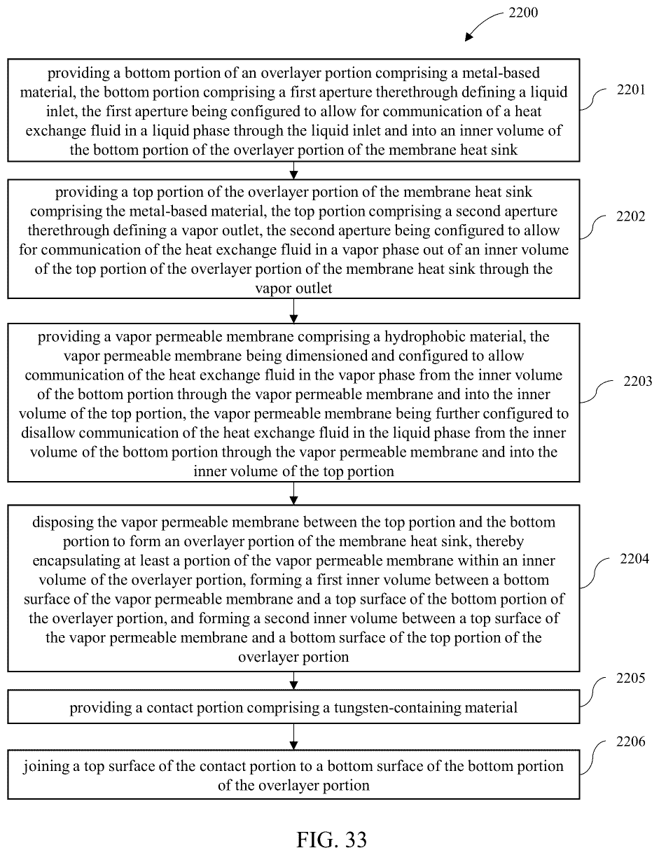

FIG. 33 illustrates a method 2200 for forming a heat sink. The method 2200 can comprise providing a bottom portion of an overlay portion comprising a metal-based material, the bottom portion comprising a first aperture therethrough defining a liquid inlet, the first aperture being configured to allow for communication of a heat exchange fluid in a liquid phase through the liquid inlet and into an inner volume of the bottom portion of the overlay portion of the membrane heat sink, at 2201. The method 2200 can further comprise providing a top portion of the overlay portion of the membrane heat sink comprising the metal-based material, the top portion comprising a second aperture therethrough defining a vapor outlet, the second aperture being configured to allow for communication of the heat exchange fluid in a vapor phase out of an inner volume of the top portion of the overlay portion of the membrane heat sink through the vapor outlet, at 2202. The method 2200 can further comprise providing a vapor permeable membrane comprising a hydrophobic material, the vapor permeable membrane being dimensioned and configured to allow communication of the heat exchange fluid in the vapor phase from the inner volume of the bottom portion through the vapor permeable membrane and into the inner volume of the top portion, the vapor permeable membrane being further configured to disallow communication of the heat exchange fluid in the liquid phase from the inner volume of the bottom portion through the vapor permeable membrane and into the inner volume of the top portion, at 2203. The method 2200 can further comprise disposing the vapor permeable membrane between the top portion and the bottom portion to form an overlay portion of the membrane heat sink, thereby encapsulating at least a portion of the vapor permeable membrane within an inner volume of the overlay portion, forming a first inner volume between a bottom surface of the vapor permeable membrane and a top surface of the bottom portion of the overlay portion, and forming a second inner volume between a top surface of the vapor permeable membrane and a bottom surface of the top portion of the overlay portion, at 2204. The method 2200 can further comprise providing a contact portion comprising a tungsten-containing material, at 2205. The method 2200 can further comprise joining a top surface of the contact portion to a bottom surface of the bottom portion of the overlay portion, at 2206.

In some embodiments, the tungsten-containing material comprises a copper-tungsten alloy. In some embodiments, the overlay portion comprises a copper-based material. In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the membrane heat sink further comprises a solder interface joining a bottom surface of the contact portion to a top portion of the heat generating element.

In some embodiments, a thickness of the overlay portion is less than a thickness of the contact portion. In some embodiments, a thickness of the contact portion is greater than a thickness of the heat generating element. In some embodiments, a thickness of the contact portion is between about 20 μm and about 80 μm. In some embodiments, a thickness of the bottom portion of the overlay portion is between about 200 μm and about 800 μm. In some embodiments, the thickness of the contact portion is about 50 μm and the thickness of the bottom portion of the overlay portion is about 450 μm.

In some embodiments, a thickness of the contact portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 80 μm, less than about 60 μm, less than about 40 μm, less than about 20 μm, less than about 10 μm, or less than about 5 μm, inclusive of all values and ranges therebetween.

In some embodiments, a thickness of the overlay portion or the bottom portion of the overlay portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 90 μm, less than about 80 μm, less than about 70 μm, less than about 60 μm, less than about 50 μm, less than about 40 μm, less than about 30 μm, less than about 20 μm, greater than about 20 μm, greater than about 40 μm, greater than about 60 μm, greater than about 80 μm, greater than about 100 μm, greater than about 200 μm, greater than about 300 μm, greater than about 400 μm, greater than about 500 μm, greater than about 600 μm, greater than about 700 μm, greater than about 800 μm, greater than about 900 μm, or greater than about 1.00 μm, inclusive of all values and ranges therebetween.

In some embodiments, the thickness of the contact portion is between about 50 μm and about 500 μm and the thickness of the overlay portion or the bottom portion of the overlay portion is between about 50 μm and about 500 μm.

In some embodiments, the predetermined threshold for the coefficient of thermal expansion of the tungsten-containing material can be between about 1.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

In some embodiments, the tungsten-containing material has a coefficient of thermal expansion below a predetermined threshold. In some embodiments, the tungsten-containing material comprises a copper-tungsten alloy. In some embodiments, the overlay portion comprises a copper-based material. In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the method 2200 can, optionally, further comprise: providing the heat generating element; and soldering a bottom surface of the contact portion of the membrane heat sink to a top portion of the heat generating element (not shown).

In some embodiments, a thickness of the overlay portion is less than a thickness of the contact portion. In some embodiments, a thickness of the contact portion is greater than a thickness of the heat generating element. In some embodiments, a thickness of the contact portion is between about 20 μm and about 80 μm. In some embodiments, a thickness of the bottom portion of the overlay portion is between about 200 μm and about 800 μm. In some embodiments, the thickness of the contact portion is about 50 μm and the thickness of the bottom portion of the overlay portion is about 450 μm.

In some embodiments, a thickness of the contact portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 80 μm, less than about 60 μm, less than about 40 μm, less than about 20 μm, less than about 10 μm, or less than about 5 μm, inclusive of all values and ranges therebetween.

In some embodiments, a thickness of the overlay portion or the bottom portion of the overlay portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 90 μm, less than about 80 μm, less than about 70 μm, less than about 60 μm, less than about 50 μm, less than about 40 μm, less than about 30 μm, less than about 20 μm, greater than about 20 μm, greater than about 40 μm, greater than about 60 μm, greater than about 80 μm, greater than about 100 μm, greater than about 200 μm, greater than about 300 μm, greater than about 400 μm, greater than about 500 μm, greater than about 600 μm, greater than about 700 μm, greater than about 800 μm, greater than about 900 μm, or greater than about 1.00 μm, inclusive of all values and ranges therebetween.

In some embodiments, the thickness of the contact portion is between about 50 μm and about 500 μm and the thickness of the overlay portion or the bottom portion of the overlay portion is between about 50 μm and about 500 μm.

In some embodiments, the predetermined threshold for the coefficient of thermal expansion of the tungsten-containing material can be between about 1.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

In some embodiments, the coefficient of thermal expansion of the bottom portion of the overlay portion is between about 10×10⁻⁶ K⁻¹ and about 25×10⁻⁶ K⁻¹. In some embodiments, a density of the bottom portion of the overlay portion is between about 5,000 kg/m³ and about 10,000 kg/m³. In some embodiments, a Young's modulus of the bottom portion of the overlay portion is between about 75 GPa and about 150 GPa. In some embodiments, a thermal conductivity of the bottom portion of the overlay portion is between about 300 W/m·K and about 500 W/m·K. In some embodiments, a specific heat capacity of the bottom portion of the overlay portion is between about 300 J/kg·K and about 500 J/kg·K. In some embodiments, a copper concentration of the bottom portion of the overlay portion is between about 50 wt. % and about 99 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

In some embodiments, the method 2200 can, optionally, further comprise: forming the bottom portion of the overlay portion comprising the metal-based material (not shown). In some embodiments, this can be carried out by die pressing, additive metal manufacturing, casting, or any other suitable approach. The first aperture defining the liquid inlet can be formed during casting by way of mold configuration or the like, or can be formed by material removal according to various techniques. The method 2200 can, optionally, further comprise: forming the top portion of the overlay portion of the membrane heat sink comprising the metal-based material (not shown). This can also be carried out by die pressing, additive metal manufacturing, casting, or the like. The second aperture defining the vapor outlet can also be formed during manufacturing or by material removal afterwards. The bottom and/or top portion(s), forming the overlay portion of the membrane heat sink can comprise a copper-containing material or a copper-based material.

The method 2200 can, optionally, further comprise: forming the vapor permeable membrane comprising the hydrophobic material (not shown). This can be carried out by forming a sheet of metal-containing material, removing portions of that material from the sheet to form a mesh having an average aperture density and an average mesh size/diameter as needed. The mesh can then be treated with (e.g., sprayed, dipped, or otherwise exposed to) a hydrophobic material to form a hydrophobic surface coating on at least a portion of the mesh. Conversely, the sheet can initially be treated with a hydrophobic material to form a hydrophobic surface coating on the sheet before material is removed to form the mesh. Either way, the mesh can be formed and can comprise a hydrophobic surface coating that makes the mesh impermeable to a desired heat exchange fluid when that heat exchange fluid is in a liquid phase, while being permeable (e.g., via vapor wicking) to the desired heat exchange fluid when that heat exchange fluid is in a vapor phase.

In some embodiments, said disposing the vapor permeable membrane between the top portion and the bottom portion to form the overlay portion of the membrane heat sink, at 2204, can be carried out by joining a first side (e.g., along two or more edges) of the vapor permeable membrane to the top portion or the bottom portion of the overlay portion, and then joining the other of the top portion or the bottom portion of the overlay portion to a second side (e.g., along two or more edges) of the vapor permeable membrane, thereby encapsulating at least a portion of the vapor permeable membrane within the inner volume of the overlay portion.

In some embodiments, the method 2200 can, optionally, further comprise: forming the contact portion comprising the tungsten-containing material (not shown). This can be carried out by mixing tungsten with one or more other materials, such as metals or the like (e.g., copper), and then casting, smelting, rolling, milling, and/or sintering processes are used to form a thin sheet of the tungsten-containing material. In some embodiments, the tungsten-containing material is a sheet comprising a tungsten-copper alloy that is formed by missing tungsten powder and copper powder in suitable mass or volume concentrations until mechanically alloyed and sintered, then annealing/sintering the alloyed material, then rolling the alloy into a sheet/roll having the desired thickness and cutting out a portion of that sheet suitable for the contact portion of the membrane heat sink.

In some embodiments, said joining the top surface of the contact portion to the bottom surface of the bottom portion of the overlay portion, at 2206, can be carried out by any suitable thermal approach, chemical approach, radiative approach, and/or combinations thereof. For example, welding, brazing, friction bonding, and/or soldering can be used to join the contact portion to the overlay portion to form the membrane heat sink.

In some embodiments, the tungsten-containing material has a coefficient of thermal expansion below a predetermined threshold. In some embodiments, the tungsten-containing material comprises a copper-tungsten alloy. In some embodiments, the overlay portion comprises a copper-based material.

In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the method 2200 can, optionally, further comprise: providing the heat generating element (not shown); and soldering a bottom surface of the contact portion of the membrane heat sink to a top portion of the heat generating element (not shown).

In some embodiments, a thickness of the overlay portion is less than a thickness of the contact portion. In some embodiments, a thickness of the contact portion is greater than a thickness of the heat generating element. In some embodiments, a thickness of the contact portion is between about 20 μm and about 80 μm. In some embodiments, a thickness of the bottom portion of the overlay portion is between about 200 μm and about 800 μm. In some embodiments, the thickness of the contact portion is about 50 μm and the thickness of the bottom portion of the overlay portion is about 450 μm.

In some embodiments, a thickness of the contact portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 80 μm, less than about 60 μm, less than about 40 μm, less than about 20 μm, less than about 10 μm, or less than about 5 μm, inclusive of all values and ranges therebetween.

In some embodiments, a thickness of the overlay portion or the bottom portion of the overlay portion is between about 5 μm and about 1,000 μm, between about 10 μm and about 900 μm, between about 20 μm and about 800 μm, between about 30 μm and about 700 μm, between about 40 μm and about 600 μm, between about 50 μm and about 500 μm, between about 60 μm and about 400 μm, between about 70 μm and about 300 μm, between about 80 μm and about 200 μm, less than about 1,000 μm, less than about 900 μm, less than about 800 μm, less than about 700 μm, less than about 600 μm, less than about 500 μm, less than about 400 μm, less than about 300 μm, less than about 200 μm, less than about 100 μm, less than about 90 μm, less than about 80 μm, less than about 70 μm, less than about 60 μm, less than about 50 μm, less than about 40 μm, less than about 30 μm, less than about 20 μm, greater than about 20 μm, greater than about 40 μm, greater than about 60 μm, greater than about 80 μm, greater than about 100 μm, greater than about 200 μm, greater than about 300 μm, greater than about 400 μm, greater than about 500 μm, greater than about 600 μm, greater than about 700 μm, greater than about 800 μm, greater than about 900 μm, or greater than about 1.00 μm, inclusive of all values and ranges therebetween.

In some embodiments, the thickness of the contact portion is between about 50 μm and about 500 μm and the thickness of the overlay portion or the bottom portion of the overlay portion is between about 50 μm and about 500 μm.

In some embodiments, the predetermined threshold for the coefficient of thermal expansion of the tungsten-containing material is between about 1.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %. In some embodiments, a copper concentration of the tungsten-containing material is between about 50 wt. % and about 99 wt. %.

In some embodiments, the coefficient of thermal expansion of the bottom portion of the overlay portion is between about 10×10⁻⁶ K⁻¹ and about 25×10⁻⁶ K⁻¹. In some embodiments, a density of the bottom portion of the overlay portion is between about 5,000 kg/m³ and about 10,000 kg/m³. In some embodiments, a Young's modulus of the bottom portion of the overlay portion is between about 75 GPa and about 150 GPa. In some embodiments, a thermal conductivity of the bottom portion of the overlay portion is between about 300 W/m·K and about 500 W/m·K. In some embodiments, a specific heat capacity of the bottom portion of the overlay portion is between about 300 J/kg·K and about 500 J/kg·K. In some embodiments, a copper concentration of the bottom portion of the overlay portion is between about 50 wt. % and about 99 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

Some or all of the elements of the method 2200 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2200 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2200, whether in part or in full.

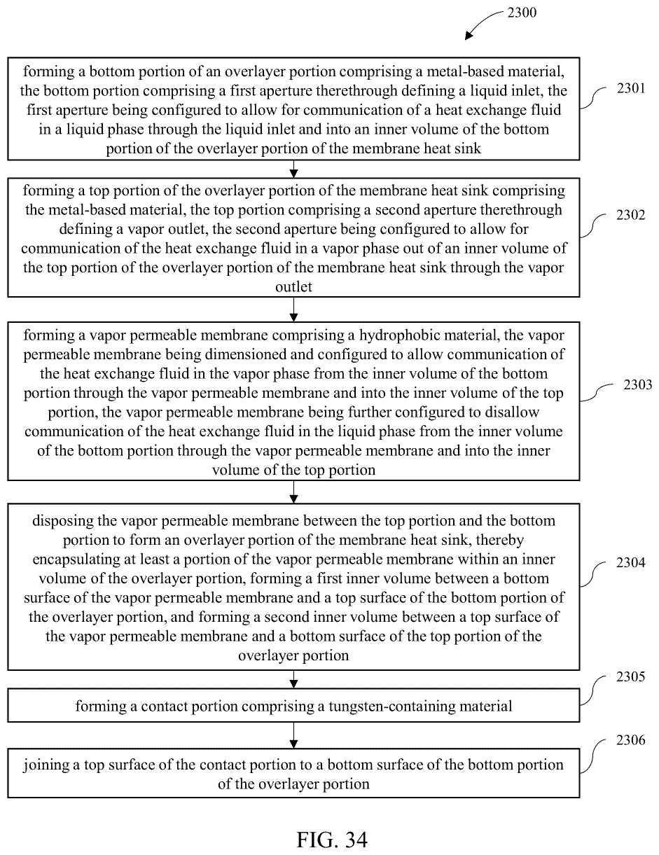

FIG. 34 illustrates a method 2300 for forming a heat sink. The method 2300 can comprise forming a bottom portion of an overlay portion comprising a metal-based material, the bottom portion comprising a first aperture therethrough defining a liquid inlet, the first aperture being configured to allow for communication of a heat exchange fluid in a liquid phase through the liquid inlet and into an inner volume of the bottom portion of the overlay portion of the membrane heat sink, at 2301. The method 2300 can further comprise forming a top portion of the overlay portion of the membrane heat sink comprising the metal-based material, the top portion comprising a second aperture therethrough defining a vapor outlet, the second aperture being configured to allow for communication of the heat exchange fluid in a vapor phase out of an inner volume of the top portion of the overlay portion of the membrane heat sink through the vapor outlet, at 2302. The method 2300 can further comprise forming a vapor permeable membrane comprising a hydrophobic material, the vapor permeable membrane being dimensioned and configured to allow communication of the heat exchange fluid in the vapor phase from the inner volume of the bottom portion through the vapor permeable membrane and into the inner volume of the top portion, the vapor permeable membrane being further configured to disallow communication of the heat exchange fluid in the liquid phase from the inner volume of the bottom portion through the vapor permeable membrane and into the inner volume of the top portion, at 2303. The method 2300 can further comprise disposing the vapor permeable membrane between the top portion and the bottom portion to form an overlay portion of the membrane heat sink, thereby encapsulating at least a portion of the vapor permeable membrane within an inner volume of the overlay portion, forming a first inner volume between a bottom surface of the vapor permeable membrane and a top surface of the bottom portion of the overlay portion, and forming a second inner volume between a top surface of the vapor permeable membrane and a bottom surface of the top portion of the overlay portion, at 2304. The method 2300 can further comprise forming a contact portion comprising a tungsten-containing material, at 2305. The method 2300 can further comprise joining a top surface of the contact portion to a bottom surface of the bottom portion of the overlay portion, at 2306.

In some embodiments, the tungsten-containing material comprises a copper-tungsten alloy. In some embodiments, the overlay portion comprises a copper-based material. In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the membrane heat sink further comprises a solder interface joining a bottom surface of the contact portion to a top portion of the heat generating element.

In some embodiments, a thickness of the overlay portion is less than a thickness of the contact portion. In some embodiments, a thickness of the contact portion is greater than a thickness of the heat generating element. In some embodiments, a thickness of the contact portion is between about 20 μm and about 80 μm. In some embodiments, a thickness of the bottom portion of the overlay portion is between about 200 μm and about 800 μm. In some embodiments, the thickness of the contact portion is about 50 μm and the thickness of the bottom portion of the overlay portion is about 450 μm.

In some embodiments, the predetermined threshold for the coefficient of thermal expansion of the tungsten-containing material is between about 1.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

In some embodiments, the tungsten-containing material has a coefficient of thermal expansion below a predetermined threshold. In some embodiments, the tungsten-containing material comprises a copper-tungsten alloy. In some embodiments, the overlay portion comprises a copper-based material. In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the method 2300 can, optionally, further comprise: providing the heat generating element; and soldering a bottom surface of the contact portion of the membrane heat sink to a top portion of the heat generating element (not shown).

In some embodiments, a thickness of the overlay portion is less than a thickness of the contact portion. In some embodiments, a thickness of the contact portion is greater than a thickness of the heat generating element. In some embodiments, a thickness of the contact portion is between about 20 μm and about 80 μm. In some embodiments, a thickness of the bottom portion of the overlay portion is between about 200 μm and about 800 μm. In some embodiments, the thickness of the contact portion is about 50 μm and the thickness of the bottom portion of the overlay portion is about 450 μm.

In some embodiments, the predetermined threshold for the coefficient of thermal expansion of the tungsten-containing material is between about 1.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

In some embodiments, the coefficient of thermal expansion of the bottom portion of the overlay portion is between about 10×10⁻⁶ K⁻¹ and about 25×10⁻⁶ K⁻¹. In some embodiments, a density of the bottom portion of the overlay portion is between about 5,000 kg/m³ and about 10,000 kg/m³. In some embodiments, a Young's modulus of the bottom portion of the overlay portion is between about 75 GPa and about 150 GPa. In some embodiments, a thermal conductivity of the bottom portion of the overlay portion is between about 300 W/m·K and about 500 W/m·K. In some embodiments, a specific heat capacity of the bottom portion of the overlay portion is between about 300 J/kg·K and about 500 J/kg·K. In some embodiments, a copper concentration of the bottom portion of the overlay portion is between about 50 wt. % and about 99 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

In some embodiments, the method 2300 can, optionally, further comprise: forming the bottom portion of the overlay portion comprising the metal-based material by die pressing, additive metal manufacturing, casting, or any other suitable approach (not shown). The first aperture defining the liquid inlet can be formed during casting by way of mold configuration or the like, or can be formed by material removal according to various techniques. The method 2300 can, optionally, further comprise: forming the top portion of the overlay portion of the membrane heat sink comprising the metal-based material by die pressing, additive metal manufacturing, casting, or any other suitable approach (not shown). The second aperture defining the vapor outlet can also be formed during manufacturing or by material removal afterwards. The bottom and/or top portion(s), forming the overlay portion of the membrane heat sink can comprise a copper-containing material or a copper-based material.

The method 2300 can, optionally, further comprise: forming the vapor permeable membrane comprising the hydrophobic material by forming a sheet of metal-containing material, removing portions of that material from the sheet to form a mesh having an average aperture density and an average mesh size/diameter as needed (not shown). The mesh can then be treated with (e.g., sprayed, dipped, or otherwise exposed to) a hydrophobic material to form a hydrophobic surface coating on at least a portion of the mesh. Conversely, the sheet can initially be treated with a hydrophobic material to form a hydrophobic surface coating on the sheet before material is removed to form the mesh. Either way, the mesh can be formed and can comprise a hydrophobic surface coating that makes the mesh impermeable to a desired heat exchange fluid when that heat exchange fluid is in a liquid phase, while being permeable (e.g., via vapor wicking) to the desired heat exchange fluid when that heat exchange fluid is in a vapor phase.

In some embodiments, said disposing the vapor permeable membrane between the top portion and the bottom portion to form the overlay portion of the membrane heat sink, at 2304, can be carried out by joining a first side (e.g., along two or more edges) of the vapor permeable membrane to the top portion or the bottom portion of the overlay portion, and then joining the other of the top portion or the bottom portion of the overlay portion to a second side (e.g., along two or more edges) of the vapor permeable membrane, thereby encapsulating at least a portion of the vapor permeable membrane within the inner volume of the overlay portion.

In some embodiments, the method 2300 can, optionally, further comprise: forming the contact portion comprising the tungsten-containing material by mixing tungsten with one or more other materials, such as metals or the like (e.g., copper), (not shown), and then casting, smelting, rolling, milling, and/or sintering processes are used to form a thin sheet of the tungsten-containing material (not shown). In some embodiments, the tungsten-containing material is a sheet comprising a tungsten-copper alloy that is formed by missing tungsten powder and copper powder in suitable mass or volume concentrations until mechanically alloyed and sintered, then annealing/sintering the alloyed material, then rolling the alloy into a sheet/roll having the desired thickness, and cutting out a portion of that sheet suitable for the contact portion of the membrane heat sink.

In some embodiments, said joining the top surface of the contact portion to the bottom surface of the bottom portion of the overlay portion, at 2306, can be carried out by any suitable thermal approach, chemical approach, radiative approach, and/or combinations thereof. For example, welding, brazing, friction bonding, and/or soldering can be used to join the contact portion to the overlay portion to form the membrane heat sink.

In some embodiments, the tungsten-containing material has a coefficient of thermal expansion below a predetermined threshold. In some embodiments, the tungsten-containing material comprises a copper-tungsten alloy. In some embodiments, the overlay portion comprises a copper-based material.

In some embodiments, the membrane heat sink is configured to be collocated with a heat generating element comprising one of: a chip, an integrated circuit, a silicon chip, a semiconductor, a transistor, a capacitor, a resistor, a computing device, a microcontroller, a digital memory chip, an application-specific integrated chip, a programmable logic controller, a field-programmable gate array, a mixed-signal integrated circuit, or a radio frequency circuit. In some embodiments, the method 2300 can, optionally, further comprise: providing the heat generating element; and soldering a bottom surface of the contact portion of the membrane heat sink to a top portion of the heat generating element (not shown).

In some embodiments, a thickness of the overlay portion is less than a thickness of the contact portion. In some embodiments, a thickness of the contact portion is greater than a thickness of the heat generating element. In some embodiments, a thickness of the contact portion is between about 20 μm and about 80 μm. In some embodiments, a thickness of the bottom portion of the overlay portion is between about 200 μm and about 800 μm. In some embodiments, the thickness of the contact portion is about 50 μm and the thickness of the bottom portion of the overlay portion is about 450 μm.

In some embodiments, the predetermined threshold for the coefficient of thermal expansion of the tungsten-containing material is between about 1.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %. In some embodiments, a copper concentration of the tungsten-containing material is between about 50 wt. % and about 99 wt. %.

In some embodiments, the coefficient of thermal expansion of the bottom portion of the overlay portion is between about 10×10⁻⁶ K⁻¹ and about 25×10⁻⁶ K⁻¹. In some embodiments, a density of the bottom portion of the overlay portion is between about 5,000 kg/m³ and about 10,000 kg/m³. In some embodiments, a Young's modulus of the bottom portion of the overlay portion is between about 75 GPa and about 150 GPa. In some embodiments, a thermal conductivity of the bottom portion of the overlay portion is between about 300 W/m·K and about 500 W/m·K. In some embodiments, a specific heat capacity of the bottom portion of the overlay portion is between about 300 J/kg·K and about 500 J/kg·K. In some embodiments, a copper concentration of the bottom portion of the overlay portion is between about 50 wt. % and about 99 wt. %.

In some embodiments, the vapor permeable membrane comprises a mesh formed from a hydrophobic material. In some embodiments, the hydrophobic material is one of: a polymer, a treated metal, or the like. In some embodiments, the vapor permeable membrane comprises polytetrafluoroethylene (PTFE), polyvinylidene fluoride (PVDF), other such polymeric materials, a hydrophobic treated metal material, such as copper coated with a hydrophobic material, copper treated with a material/chemical so as to be hydrophobic, any other suitable materials, or combinations thereof. In some embodiments, one or more materials for the vapor permeable membrane can be chosen based on what material or combination of materials achieves a water contact angle of greater than about 90 degrees, meaning that the material or combination of materials is hydrophobic.

In some embodiments, the bottom portion of the overlay portion comprises a plurality of structures that stand proud of a top surface of the bottom portion of the overlay portion, wherein one or more of the plurality of structures are configured to support the vapor permeable membrane at one or more locations across a bottom surface of the vapor permeable membrane. In some embodiments, the top portion of the overlay portion comprises a second plurality of structures that stand proud of a bottom surface of the top portion of the overlay portion, wherein one or more of the second plurality of structures are configured to support the vapor permeable membrane at one or more locations across a top surface of the vapor permeable membrane, the one or more locations across the top surface of the vapor permeable membrane corresponding to the one or more locations across the bottom surface of the vapor permeable membrane.

Some or all of the elements of the method 2300 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2300 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2300, whether in part or in full.

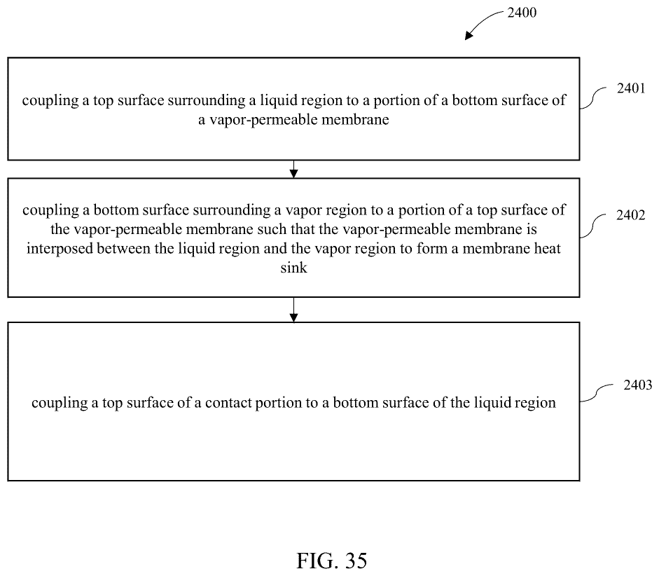

FIG. 35 illustrates a method 2400 for forming a device, e.g., a device comprising a heat sink such as a membrane heat sink. The method 2400 can comprise: coupling a top surface surrounding a liquid region to a portion of a bottom surface of a vapor-permeable membrane, at 2401. In some embodiments, the method 2400 can further comprise: coupling a bottom surface surrounding a vapor region to a portion of a top surface of the vapor-permeable membrane such that the vapor-permeable membrane is interposed between the liquid region and the vapor region to form a membrane heat sink, at 2402. In some embodiments, the method 2400 can further comprise: coupling a top surface of a contact portion to a bottom surface of the liquid region, at 2403.

In some embodiments, the liquid region comprises an inlet port configured to communicate a liquid phase heat exchange fluid into the liquid region. In some embodiments, the vapor region comprises an outlet port configured to communicate a vapor phase heat exchange fluid out of the membrane heat sink. In some embodiments, the vapor-permeable membrane is configured to allow communication therethrough of the vapor phase heat exchange fluid and disallow communication therethrough of the liquid phase heat exchange fluid. In some embodiments, a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region. In some embodiments, a rate of communication of the liquid phase heat exchange fluid through the inlet port and into the liquid region is based on the rate of communication of the vapor phase heat exchange fluid through vapor-permeable membrane from the liquid region to the vapor region. In some embodiments, the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid. In some embodiments, the rate at which the liquid phase heat exchange fluid undergoes the phase change to the vapor phase heat exchange fluid is based upon a quantity of the heat absorbed by the liquid phase heat exchange fluid.

In some embodiments, the quantity of the heat absorbed by the liquid phase heat exchange fluid is based upon a quantity of heat communicated through the contact portion. In some embodiments, the membrane heat sink is further configured, during a first time, to absorb a first quantity of heat emitted by a collocated heat source, causing the liquid phase heat exchange fluid in the liquid region to undergo a phase change to the vapor phase heat exchange fluid at a first rate. In some embodiments, the volume of the liquid phase heat exchange fluid that undergoes the phase change to the vapor phase heat exchange fluid during the first time is based upon a first quantity of the heat absorbed by the liquid phase heat exchange fluid during the first time. In some embodiments, the membrane heat sink is further configured, during a second time, to absorb a second quantity of heat emitted by the collocated heat source, causing the liquid phase heat exchange fluid in the liquid region to undergo the phase change to the vapor phase heat exchange fluid at a second rate. In some embodiments, the volume of the liquid phase heat exchange fluid that undergoes the phase change to the vapor phase heat exchange fluid during the second time is based upon a second quantity of the heat absorbed by the liquid phase heat exchange fluid during the second time.

In some embodiments, the contact portion comprises a tungsten-containing material having a coefficient of thermal expansion below a predetermined threshold. In some embodiments, the tungsten-containing material comprises a copper-tungsten alloy. In some embodiments, one or more of: the liquid region, the vapor region, or the vapor-permeable membrane comprises a copper-based material. In some embodiments, the predetermined threshold for the coefficient of thermal expansion of the tungsten-containing material is between about 4.0×10⁻⁶ K⁻¹ and about 10×10⁻⁶ K⁻¹. In some embodiments, the tungsten-containing material has a density of between about 15,000 kg/m³ and about 18,000 kg/m³. In some embodiments, the tungsten-containing material has a Young's modulus of between about 200 GPa and about 400 GPa. In some embodiments, the tungsten-containing material has a thermal conductivity of between about 100 W/m·K and about 300 W/m·K. In some embodiments, the tungsten-containing material has a specific heat capacity of between about 100 J/kg·K and about 300 J/kg·K. In some embodiments, the tungsten-containing material has a tungsten concentration between about 0.5 wt. % and about 20 wt. %.

Some or all of the elements of the method 2400 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2400 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2400, whether in part or in full.

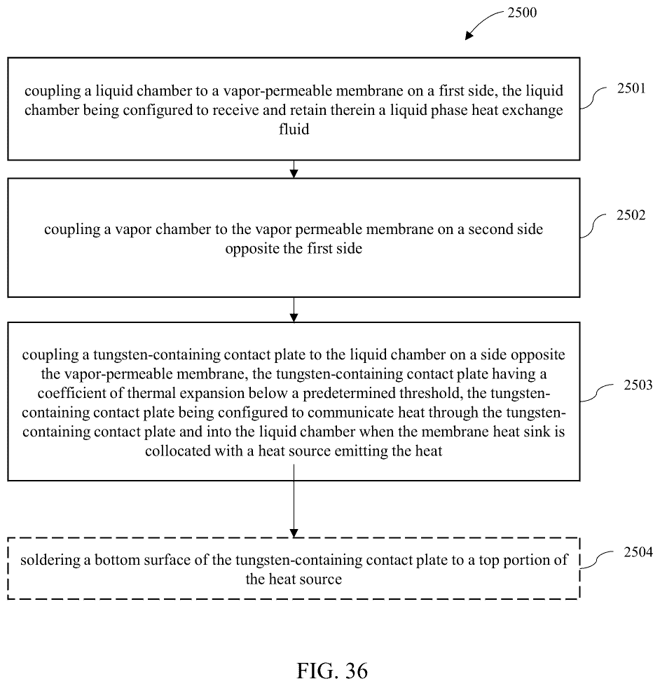

FIG. 36 illustrates a method 2500 for forming a device, e.g., a device comprising a heat sink such as a membrane heat sink. The method 2500 can comprise: coupling a liquid chamber to a vapor-permeable membrane on a first side, the liquid chamber being configured to receive and retain therein a liquid phase heat exchange fluid, at 2501. In some embodiments, the method 2500 can further comprise: coupling a vapor chamber to the vapor permeable membrane on a second side opposite the first side, at 2502. In some embodiments, the method 2500 can further comprise: coupling a tungsten-containing contact plate to the liquid chamber on a side opposite the vapor-permeable membrane, the tungsten-containing contact plate having a coefficient of thermal expansion below a predetermined threshold, the tungsten-containing contact plate being configured to communicate heat through the tungsten-containing contact plate and into the liquid chamber when the membrane heat sink is collocated with a heat source emitting the heat, at 2503.

In some embodiments, the method 2500 can, optionally, further comprise: soldering a bottom surface of the tungsten-containing contact plate to a top portion of the heat source, at 2504.

In some embodiments, the liquid phase heat exchange fluid in the liquid chamber is configured to absorb the heat emitted by the heat source and communicated through the tungsten-containing contact plate and into the liquid chamber such that at least a portion of the liquid phase heat exchange fluid experiences a phase change to form the vapor phase heat exchange fluid. In some embodiments, the vapor-permeable membrane is configured to allow the vapor phase heat exchange fluid formed in the liquid chamber to be communicated through the vapor-permeable membrane and into the vapor chamber while disallowing a remaining portion of the liquid phase heat exchange fluid in the liquid chamber from being communicated through the vapor-permeable membrane and into the vapor chamber.

Some or all of the elements of the method 2500 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2500 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2500, whether in part or in full.

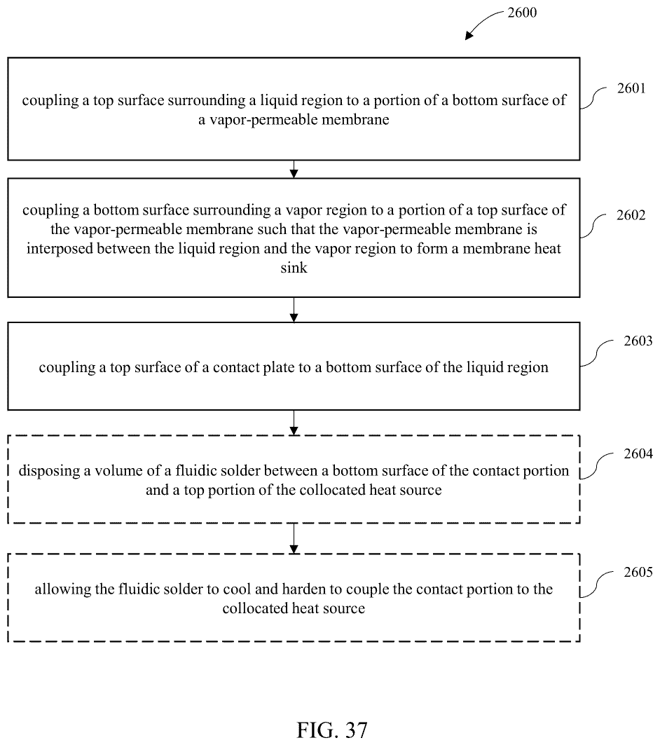

FIG. 37 illustrates a method 2600 for forming a device, e.g., a device comprising a heat sink such as a membrane heat sink. The method 2600 can comprise: coupling a top surface surrounding a liquid region to a portion of a bottom surface of a vapor-permeable membrane, at 2601. In some embodiments, the method 2600 can further comprise: coupling a bottom surface surrounding a vapor region to a portion of a top surface of the vapor-permeable membrane such that the vapor-permeable membrane is interposed between the liquid region and the vapor region to form a membrane heat sink, at 2602. In some embodiments, the method 2600 can further comprise: coupling a top surface of a contact plate to a bottom surface of the liquid region, at 2603. In some embodiments, the method 2600 can, optionally, further comprise: disposing a volume of a fluidic solder between a bottom surface of the contact portion and a top portion of the collocated heat source, at 2604. In some embodiments, the method 2600 can, optionally, further comprise: allowing the fluidic solder to cool and harden to couple the contact portion to the collocated heat source, at 2605.

In some embodiments, the contact portion comprises a tungsten-containing material having a coefficient of thermal expansion below a predetermined threshold. In some embodiments, the liquid region comprises an inlet port configured to communicate a liquid phase heat exchange fluid into the liquid region. In some embodiments, the vapor region comprises an outlet port configured to communicate a vapor phase heat exchange fluid out of the membrane heat sink. In some embodiments, the vapor-permeable membrane is configured to allow communication therethrough of the vapor phase heat exchange fluid and disallow communication therethrough of the liquid phase heat exchange fluid. In some embodiments, a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region. In some embodiments, a rate of communication of the liquid phase heat exchange fluid through the inlet port and into the liquid region is based on the rate of communication of the vapor phase heat exchange fluid through vapor-permeable membrane from the liquid region to the vapor region. In some embodiments, the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid. In some embodiments, the rate at which the liquid phase heat exchange fluid undergoes the phase change to the vapor phase heat exchange fluid is based upon a quantity of heat absorbed by the liquid phase heat exchange fluid. In some embodiments, the quantity of heat absorbed by the liquid phase heat exchange fluid is based upon a quantity of heat communicated through the contact plate.

Some or all of the elements of the method 2600 can be carried out by or controlled by a computing device, such as computing device 1800. For example, the processing element 1802 of the computing device 1800 can, based upon instructions/program code stored in the volatile memory 1806 and/or the non-volatile memory 1804, cause and control operation of another component or element of a system/device, such as a robotic arm, a conveyor belt, a furnace, a mill, a saw, a plasma cutter, a laser emitter, a brazing device, a soldering iron, a welder, and/or the like. By causing and controlling operation of another component or element, the computing device 1800 can cause one or more elements of the method 2600 to be carried out in part or in full. In some embodiments, the computing device 1800 can comprise the other component or element for which the processing element 1802 is causing and controlling operation thereof. In other embodiments, the computing device 1800 can be configured to communicate with another apparatus, device, system, or the like, to cause control of the other component or element in accordance with one or more elements of the method 2600, whether in part or in full.

All publications referred to or cited herein are incorporated by reference in their entirety, including all FIGs. and tables, to the extent they are not inconsistent with the explicit teachings of this specification. It should be understood that the examples and embodiments described herein are for illustrative purposes only and that various modifications or changes in light thereof will be suggested to persons skilled in the art and are to be included within the spirit and purview of this application.

1. A method comprising:
coupling a top surface surrounding a liquid region to a portion of a bottom surface of a vapor-permeable membrane;
coupling a bottom surface surrounding a vapor region to a portion of a top surface of the vapor-permeable membrane such that the vapor-permeable membrane is interposed between the liquid region and the vapor region to form a membrane heat sink; and
coupling a top surface of a contact portion to a bottom surface of the liquid region,
wherein the liquid region comprises an inlet port configured to communicate a liquid phase heat exchange fluid into the liquid region,
wherein the vapor region comprises an outlet port configured to communicate a vapor phase heat exchange fluid out of the membrane heat sink, and
wherein the vapor-permeable membrane is configured to allow communication therethrough of the vapor phase heat exchange fluid and disallow communication therethrough of the liquid phase heat exchange fluid.

2. The method of claim 1, wherein a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region.

3. The method of claim 2, wherein a rate of communication of the liquid phase heat exchange fluid through the inlet port and into the liquid region is based on the rate of communication of the vapor phase heat exchange fluid through vapor-permeable membrane from the liquid region to the vapor region.

4. The method of claim 3, wherein the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid.

5. The method of claim 4, wherein the rate at which the liquid phase heat exchange fluid undergoes the phase change to the vapor phase heat exchange fluid is based upon a quantity of the heat absorbed by the liquid phase heat exchange fluid.

6. The method of claim 5, wherein the quantity of the heat absorbed by the liquid phase heat exchange fluid is based upon a quantity of heat communicated through the contact portion.

7. The method of claim 6, wherein the membrane heat sink is further configured, during a first time, to absorb a first quantity of heat emitted by a collocated heat source, causing the liquid phase heat exchange fluid in the liquid region to undergo a phase change to the vapor phase heat exchange fluid at a first rate.

8. The method of claim 7, wherein the volume of the liquid phase heat exchange fluid that undergoes the phase change to the vapor phase heat exchange fluid during the first time is based upon a first quantity of the heat absorbed by the liquid phase heat exchange fluid during the first time.

9. The method of claim 8, wherein the membrane heat sink is further configured, during a second time, to absorb a second quantity of heat emitted by the collocated heat source, causing the liquid phase heat exchange fluid in the liquid region to undergo the phase change to the vapor phase heat exchange fluid at a second rate.

10. The method of claim 9, wherein the volume of the liquid phase heat exchange fluid that undergoes the phase change to the vapor phase heat exchange fluid during the second time is based upon a second quantity of the heat absorbed by the liquid phase heat exchange fluid during the second time.

11. The method of claim 1, wherein the contact portion comprises a tungsten-containing material having a coefficient of thermal expansion below a predetermined threshold.

12. The method of claim 11, wherein the tungsten-containing material comprises a copper-tungsten alloy.

13. The method of claim 11, wherein one or more of: the liquid region, the vapor region, or the vapor-permeable membrane comprises a copper-based material.

14. The method of claim 11, wherein the predetermined threshold for the coefficient of thermal expansion of the tungsten-containing material is between about 4.0×10⁻⁶ K⁻¹ and about 10×10⁻⁶ K⁻¹.

15. The method of claim 11, wherein the tungsten-containing material has:
a density of between about 15,000 kg/m³ and about 18,000 kg/m³,
a Young's modulus of between about 200 GPa and about 400 GPa,
a thermal conductivity of between about 100 W/m·K and about 300 W/m·K, and
a specific heat capacity of between about 100 J/kg·K and about 300 J/kg·K.

16. The method of claim 11, wherein the tungsten-containing material has a tungsten concentration between about 0.5 wt. % and about 20 wt. %.

17. A method of forming a membrane heat sink, the method comprising:
coupling a liquid chamber to a vapor-permeable membrane on a first side, the liquid chamber being configured to receive and retain therein a liquid phase heat exchange fluid;
coupling a vapor chamber to the vapor permeable membrane on a second side opposite the first side; and
coupling a tungsten-containing contact plate to the liquid chamber on a side opposite the vapor-permeable membrane, the tungsten-containing contact plate having a coefficient of thermal expansion below a predetermined threshold, the tungsten-containing contact plate being configured to communicate heat through the tungsten-containing contact plate and into the liquid chamber when the membrane heat sink is collocated with a heat source emitting the heat,
wherein the liquid phase heat exchange fluid in the liquid chamber is configured to absorb the heat emitted by the heat source and communicated through the tungsten-containing contact plate and into the liquid chamber such that at least a portion of the liquid phase heat exchange fluid experiences a phase change to form the vapor phase heat exchange fluid, and
wherein the vapor-permeable membrane is configured to allow the vapor phase heat exchange fluid formed in the liquid chamber to be communicated through the vapor-permeable membrane and into the vapor chamber while disallowing a remaining portion of the liquid phase heat exchange fluid in the liquid chamber from being communicated through the vapor-permeable membrane and into the vapor chamber.

18. The method of claim 17, further comprising:
soldering a bottom surface of the tungsten-containing contact plate to a top portion of the heat source.

19. A method comprising:
coupling a top surface surrounding a liquid region to a portion of a bottom surface of a vapor-permeable membrane;
coupling a bottom surface surrounding a vapor region to a portion of a top surface of the vapor-permeable membrane such that the vapor-permeable membrane is interposed between the liquid region and the vapor region to form a membrane heat sink; and
coupling a top surface of a contact plate to a bottom surface of the liquid region,
wherein the contact portion comprises a tungsten-containing material having a coefficient of thermal expansion below a predetermined threshold,
wherein the liquid region comprises an inlet port configured to communicate a liquid phase heat exchange fluid into the liquid region,
wherein the vapor region comprises an outlet port configured to communicate a vapor phase heat exchange fluid out of the membrane heat sink,
wherein the vapor-permeable membrane is configured to allow communication therethrough of the vapor phase heat exchange fluid and disallow communication therethrough of the liquid phase heat exchange fluid,
wherein a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region,
wherein a rate of communication of the liquid phase heat exchange fluid through the inlet port and into the liquid region is based on the rate of communication of the vapor phase heat exchange fluid through vapor-permeable membrane from the liquid region to the vapor region,
wherein the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid,
wherein the rate at which the liquid phase heat exchange fluid undergoes the phase change to the vapor phase heat exchange fluid is based upon a quantity of the heat absorbed by the liquid phase heat exchange fluid, and
wherein the quantity of the heat absorbed by the liquid phase heat exchange fluid is based upon a quantity of heat communicated through the contact plate.

20. The method of claim 19, further comprising:
disposing a volume of a fluidic solder between a bottom surface of the contact portion and a top portion of the collocated heat source; and
allowing the fluidic solder to cool and harden to couple the contact portion to the collocated heat source.
